(19) United States
(12) Patent Application Publication
(10) Pub. No.: US 2026/0324186 A1
(43) Pub. Date: Oct. 15, 2026

(54) BLUE LUMINESCENT COMPOUND CONTAINING CYCLOHEXYL-FUSED DIBENZOFURANYL STRUCTURE AND ORGANIC ELECTROLUMINESCENT DEVICE COMPRISING BLUE LUMINESCENT COMPOUND

(71) Applicant: SHIJIAZHUANG CHENGZHI YONGHUA DISPLAY MATERIAL CO., LTD., Shijiazhuang (CN)

(72) Inventors: Jian ZHANG, Shijiazhuang (CN); Bin WANG, Shijiazhuang (CN); Jiacheng ZHANG, Shijiazhuang (CN); Jing ZHANG, Shijiazhuang (CN); Xiaonan YIN, Shijiazhuang (CN); Feng LIANG, Shijiazhuang (CN); Zaihao ZHENG, Shijiazhuang (CN)

(73) Assignee: SHIJIAZHUANG CHENGZHI YONGHUA DISPLAY MATERIAL CO., LTD., Shijiazhuang (CN)

(21) Appl. No.: 19/642,052

(22) Filed: Apr. 8, 2026

(30) Foreign Application Priority Data
Apr. 11, 2025 (CN) 20251045089.95

(51) Int. Cl. H10K 50/12; C07F 5/02; C09K 11/06; H10K 50/15; H10K 50/16; H10K 85/40; H10K 85/60; H10K 102/00

(52) U.S. Cl. CPC H10K 50/12; C07F 5/027; C09K 11/06; H10K 50/15; H10K 50/16; H10K 85/40; H10K 85/626; H10K 85/633; H10K 85/636; H10K 85/654; H10K 85/656; H10K 85/6572; H10K 85/6574; H10K 85/6576; H10K 85/658; C09K 2211/1022; C09K 2211/1029; C09K 2211/1088; C09K 2211/1092; H10K 2102/351

(57) ABSTRACT

The present invention discloses a blue luminescent compound containing a cyclohexyl-fused dibenzofuranyl structure and an organic electroluminescent device comprising the blue luminescent compound. The general structural formula of the blue luminescent compound is as shown in Formula I or II, wherein Ar₁ represents cyclohexyl-fused dibenzofuranyl. By introducing the cyclohexyl-fused dibenzofuranyl group into the structure of the compound, the intermolecular distance is increased due to the action of mutual repulsion of lone-pair electrons of the oxygen atom, thereby improving the fluorescence quantum yield, facilitating enhanced device efficiency and prolonged lifetime. In addition, the compound of the present invention exhibits good thermal stability and also enhanced rigidity, thus indirectly reducing the problem of device performance degradation caused by heat generation and facilitating further improving the efficiency and lifetime of the device.

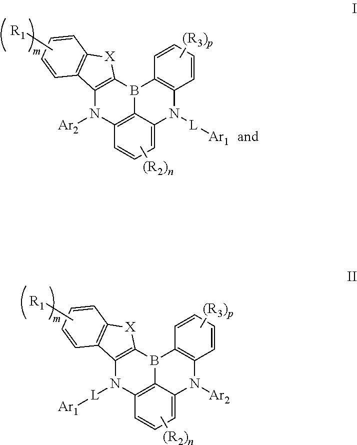

### TECHNICAL FIELD

The present invention belongs to the technical field of OLEDs and in particular comprises a blue luminescent compound containing a cyclohexyl-fused dibenzofuranyl structure and an organic electroluminescent device comprising the blue luminescent compound.

### BACKGROUND ART

Since Academician TANG Benzhong and his research group discovered the phenomenon of aggregation-induced emission for the first time in 2001, people have begun to show great interest in this unique phenomenon. Compared with traditional display technologies, OLEDs have the advantages of self-luminescence, wide viewing angle, high brightness, high contrast, low power consumption, low driving voltage, flexible display, fast response, etc. With the progress of the times and the continuous innovation of internet technologies, the OLED industry, as an indispensable smart interface, is about to embrace a vast space for growth.

OLED devices can be classified into fluorescent emission, phosphorescent emission, thermally activated delayed fluorescence (TADF), and thermally activated sensitized fluorescence according to their luminescence mechanisms. At present, research on the active layer of OLEDs is mainly focused on fluorescent materials, for which the internal quantum efficiency (defined as the ratio of the number of radiated photons in the device to the number of injected carriers) is at most 25%. This is because the ratio of singlet excitons to triplet excitons generated under electrical excitation is 1:3. Therefore, only 25% of singlet excitons undergo radiative transition, while triplet excitons undergo non-radiative decay due to spin-forbidden transitions. Among OLED fluorescent materials, blue-light materials have advantages such as low driving voltage, slow decay, high repeatability, and tunable color purity. Therefore, the development of OLED blue-light materials with high efficiency, long lifetime, and good thermal stability and the research of related devices have become a challenging issue in the current OLED research field.

Thermal stability is a key factor affecting the service life and performance of OLEDs. Especially in high-temperature environments, efficiency roll-off, metal migration, material degradation, etc. easily occur. In previous studies, it has been found that introducing dibenzofuran-based substituents into guest materials can increase the electron cloud density of compounds. The rigid dibenzofuranyl structure helps to enhance the structural stability of the compounds and can improve the device efficiency. With the continuous deepening of research, in order to further improve the efficiency and lifetime of OLED devices, attempts have been made to introduce other substituents adjacent to dibenzofuran. For example, the introduction of tetramethylcyclohexyl increases the electron cloud density of the dibenzofuran core. However, excessive methyl groups lead to tight molecular stacking, which is detrimental to the thermal stability of guest materials, ultimately the improvement of device efficiency and lifetime has not achieved the expected results.

### SUMMARY OF THE INVENTION

In view of the above problems existing in the prior art, the present invention provides a blue luminescent compound containing a cyclohexyl-fused dibenzofuranyl structure and an organic electroluminescent device comprising the blue luminescent compound.

In order to achieve the above object, the technical solution used by the present invention comprises the following content:

In a first aspect, the present invention provides a blue luminescent compound containing a cyclohexyl-fused dibenzofuranyl structure, wherein the general structural formula of the blue luminescent compound is as shown in Formula I or II:

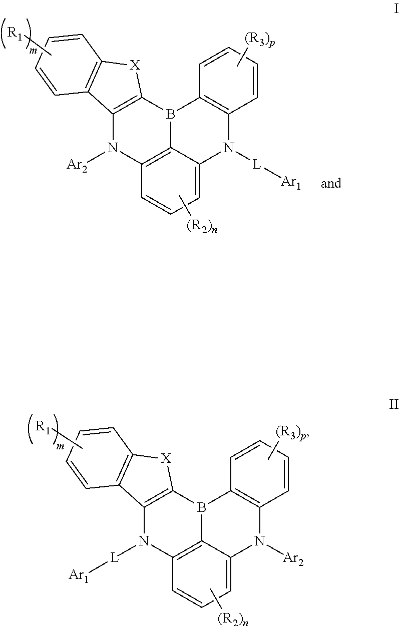

wherein
X represents O or S;
Ar₁ represents cyclohexyl-fused dibenzofuranyl;
Ar₂ represents any one of a substituted or unsubstituted aryl group having a carbon atom number of C6-C60, a substituted or unsubstituted heteroaryl group having a carbon atom number of C5-C60, a substituted or unsubstituted fused aryl group having a carbon atom number of C6-C60, and a substituted or unsubstituted heterocyclic fused aryl group having a carbon atom number of C5-C60;
L represents any one of a single bond and a substituted or unsubstituted arylene group having a carbon atom number of C6-C12;
R₁, R₂, and R₃ each independently represent any one of hydrogen, deuterium, halogen, a substituted or unsubstituted alkyl group having a carbon atom number of C1-C30, a substituted or unsubstituted alkenyl group having a carbon atom number of C2-C30, a substituted or unsubstituted cycloalkyl group having a carbon atom number of C3-C30, a substituted or unsubstituted aryl group having a carbon atom number of C6-C60, a substituted or unsubstituted heteroaryl group having a carbon atom number of C5-C60, a substituted or unsubstituted fused aryl group having a carbon atom number of C6-C60, and a substituted or unsubstituted heterocyclic fused aryl group having a carbon atom number of C5-C60, wherein two or more R₁, R₂, or R₃ can be connected to each other to form an aliphatic ring, an aromatic ring, or a fused ring;
when Ar₂, R₁, R₂, and R₃ contain a substituent, the substituent is selected from any one of an alkyl group having a carbon atom number of C1-C10, a cycloalkyl group having a carbon atom number of C3-C10, an aryl group having a carbon atom number of C6-C20, and a substituted or unsubstituted heteroaryl group having a carbon atom number of C5-C20;
m and p each independently represent 0, 1, 2, 3, or 4, and n represents 0, 1, 2, or 3; and
in Formulas I and II, any hydrogen can be replaced by deuterium, any nitrogen can be replaced by nitrogen-15, any sulfur can be replaced by sulfur-33, sulfur-34, or sulfur-36, any oxygen can be replaced by oxygen-17 or oxygen-18, any carbon can be replaced by carbon-13, and any boron can be replaced by boron-11.

Furthermore, X represents O;
L represents any one of a single bond, a substituted or unsubstituted phenylene group, and a substituted or unsubstituted naphthylene group.

Furthermore, R₁ represents one of the following structures:

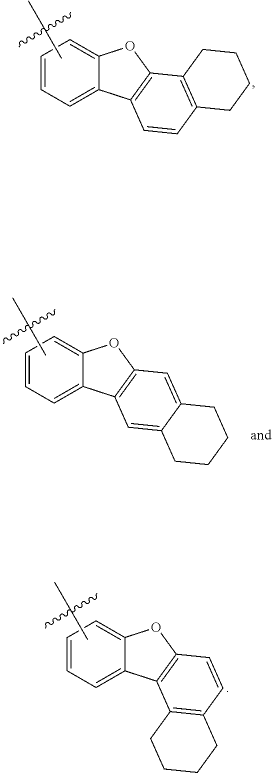

Furthermore, the general structural formula of the blue luminescent compound is as shown in one of Formulas I-1 to I-5:

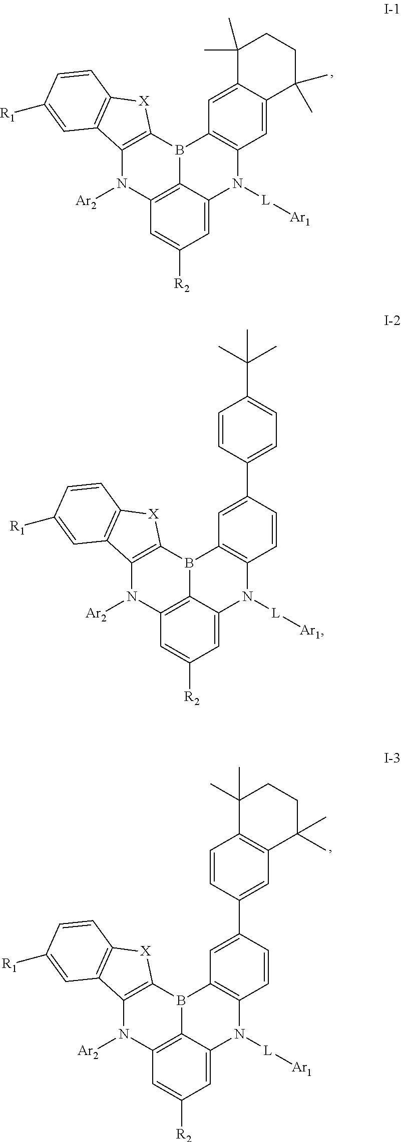

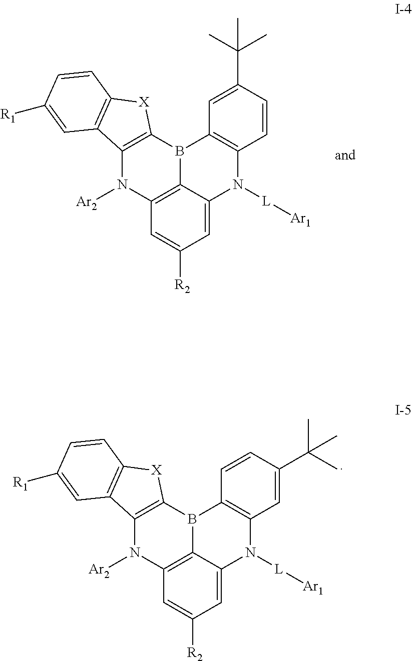

Furthermore, R₁, R₂, and R₃ each independently represent any one of hydrogen, deuterium, halogen, a substituted or unsubstituted alkyl group having a carbon atom number of C1-C10, a substituted or unsubstituted cycloalkyl group having a carbon atom number of C3-C10, a substituted or unsubstituted aryl group having a carbon atom number of C6-C20, a substituted or unsubstituted heteroaryl group having a carbon atom number of C5-C20, a substituted or unsubstituted fused aryl group having a carbon atom number of C6-C20, and a substituted or unsubstituted heterocyclic fused aryl group having a carbon atom number of C5-C20, wherein two or more R₁, R₂, or R₃ can be connected to each other to form a five-membered ring or a six-membered ring; and
Ar₂ represents any one of a substituted or unsubstituted aryl group having a carbon atom number of C6-C20, a substituted or unsubstituted heteroaryl group having a carbon atom number of C5-C20, a substituted or unsubstituted fused aryl group having a carbon atom number of C6-C20, and a substituted or unsubstituted heterocyclic fused aryl group having a carbon atom number of C5-C20.

Furthermore, R₁ and R₂ each independently represent any one of

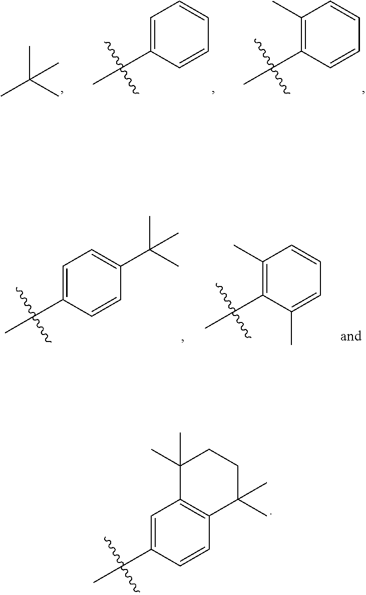

Furthermore, L represents any one of

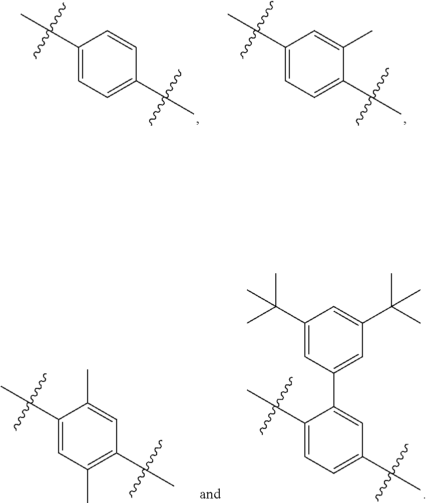

Furthermore, Ar₂ represents one of the following structures:

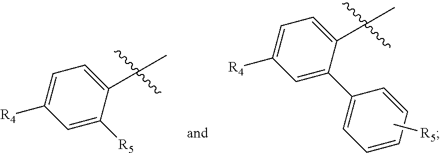

R₄ represents any one of an alkyl group having a carbon atom number of C1-C10 and a cycloalkyl group having a carbon atom number of C3-C10; and
R₅ represents a single substituent to the maximum permissible substituents and is selected from any one of an alkyl group having a carbon atom number of C1-C10 and a cycloalkyl group having a carbon atom number of C3-C10.

In the present invention, by way of example, the alkyl group may be arbitrarily selected from one of methyl, ethyl, propyl, isopropyl, n-butyl, sec-butyl, isobutyl, tert-butyl, n-pentyl, n-hexyl, n-heptyl, n-octyl, n-nonyl, n-decyl, etc.

By way of example, the alkenyl group may be arbitrarily selected from one of vinyl, propenyl, 1-butenyl, 2-butenyl, 3-butenyl, 1,3-butadienyl, 1-methylvinyl, etc.

By way of example, the cycloalkyl group may be arbitrarily selected from one of cyclobutyl, cyclopentyl, cyclohexyl, 4-methylcyclohexyl, 4,4-dimethylcyclohexyl, 1-adamantyl, 2-adamantyl, 1-norbornyl, 2-norbornyl, etc.

By way of example, the aryl group may be arbitrarily selected from one of phenyl, biphenyl, terphenyl, o-tolyl, m-tolyl, p-tolyl, etc.

By way of example, the heteroaryl group may be arbitrarily selected from one of dibenzothiophene, dibenzofuran, dibenzoselenophene, furan, thiophene, benzofuran, benzothiophene, benzoselenophene, carbazole, indolocarbazole, pyridoindole, pyrrolopyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indenoazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furanodipyridine, thienodipyridine, benzoselenophenopyridine, and benzothienopyridine, selenophenodipyridine, preferably dibenzothiophene, dibenzofuran, dibenzoselenophene, carbazole, indolocarbazole, imidazole, pyridine, triazine, benzimidazole, 1,2-azaborane, 1,3-azaborane, 1,4-azaborane, borazole, and aza-analogues thereof, etc.

By way of example, the fused aryl group may be arbitrarily selected from one of naphthyl, anthryl, phenanthryl, pyrenyl, etc.

By way of example, the heterocyclic fused aryl group can be arbitrarily selected from one of nitrogen-containing heterocyclic fused aryl such as indolyl, quinolyl, and purinyl; oxygen-containing heterocyclic fused aryl such as benzofuranyl; and sulfur-containing heterocyclic fused aryl such as benzothienyl and thienopyridyl.

Furthermore, the blue luminescent compound is selected from one of the following structures.

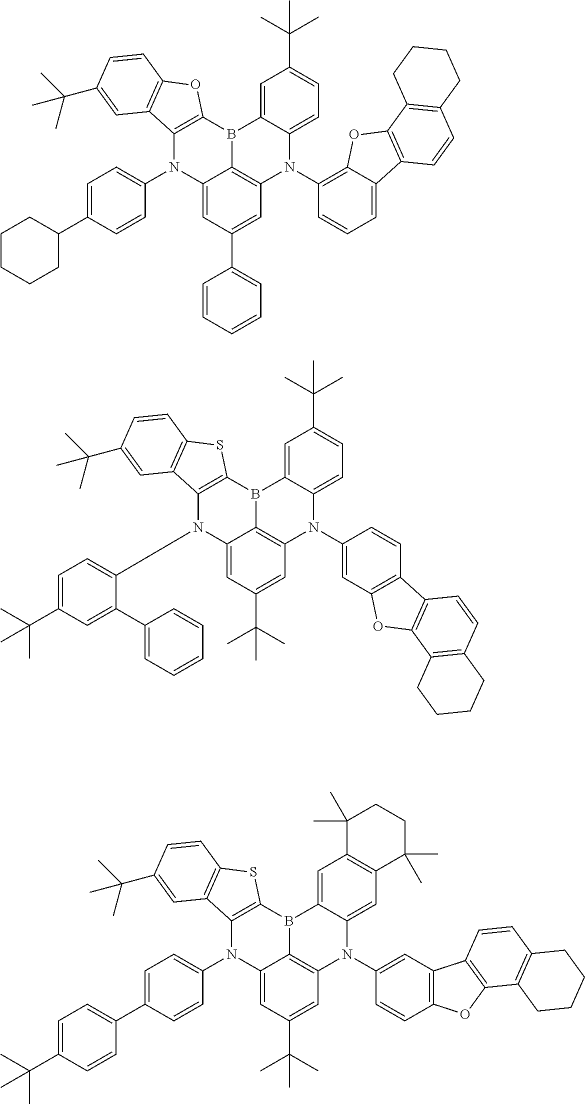 [SMILES: CC(C)(C)c1ccc2c(c1)B1c3oc4ccc(C(C)(C)C)cc4c3N(c3ccc(C4CCCCC4)cc3)c3cc(-c4ccccc4)cc(c31)N2c1cccc2c1oc1c3c(ccc12)CCCC3 ; CC(C)(C)c1ccc2c(c1)B1c3sc4ccc(C(C)(C)C)cc4c3N(c3ccc(C(C)(C)C)cc3-c3ccccc3)c3cc(C(C)(C)C)cc(c31)N2c1ccc2c(c1)oc1c3c(ccc12)CCCC3 ; CC(C)(C)c1ccc(-c2ccc(N3c4cc(C(C)(C)C)cc5c4B(c4cc6c(cc4N5c4ccc5oc7c8c(ccc7c5c4)CCCC8)C(C)(C)CCC6(C)C)c4sc5ccc(C(C)(C)C)cc5c43)cc2)cc1]

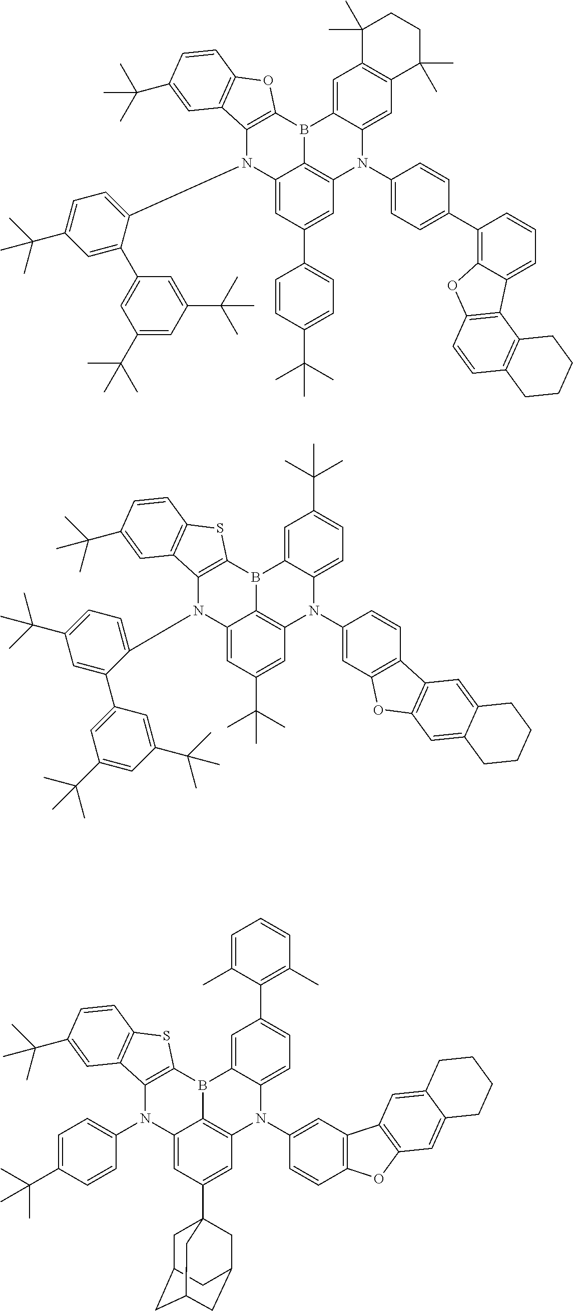 [SMILES: CC(C)(C)c1ccc(-c2cc3c4c(c2)N(c2ccc(C(C)(C)C)cc2-c2cc(C(C)(C)C)cc(C(C)(C)C)c2)c2c(oc5ccc(C(C)(C)C)cc25)B4c2cc4c(cc2N3c2ccc(-c3cccc5c3oc3ccc6c(c35)CCCC6)cc2)C(C)(C)CCC4(C)C)cc1 ; CC(C)(C)c1cc(-c2cc(C(C)(C)C)ccc2N2c3cc(C(C)(C)C)cc4c3B(c3cc(C(C)(C)C)ccc3N4c3ccc4c(c3)oc3cc5c(cc34)CCCC5)c3sc4ccc(C(C)(C)C)cc4c32)cc(C(C)(C)C)c1 ; Cc1cccc(C)c1-c1ccc2c(c1)B1c3sc4ccc(C(C)(C)C)cc4c3N(c3ccc(C(C)(C)C)cc3)c3cc(C45CC6CC(CC(C6)C4)C5)cc(c31)N2c1ccc2oc3cc4c(cc3c2c1)CCCC4]

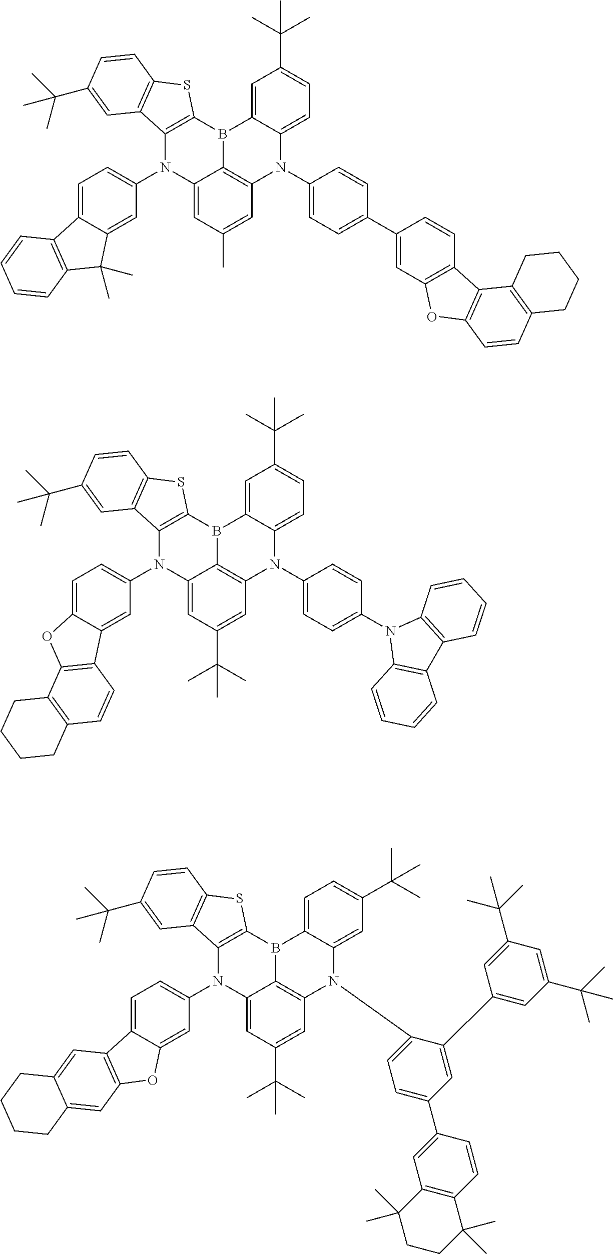 [SMILES: Cc1cc2c3c(c1)N(c1ccc4c(c1)C(C)(C)c1ccccc1-4)c1c(sc4ccc(C(C)(C)C)cc14)B3c1cc(C(C)(C)C)ccc1N2c1ccc(-c2ccc3c(c2)oc2ccc4c(c23)CCCC4)cc1 ; CC(C)(C)c1ccc2c(c1)B1c3sc4ccc(C(C)(C)C)cc4c3N(c3ccc4oc5c6c(ccc5c4c3)CCCC6)c3cc(C(C)(C)C)cc(c31)N2c1ccc(-n2c3ccccc3c3ccccc32)cc1 ; CC(C)(C)c1cc(-c2cc(-c3ccc4c(c3)C(C)(C)CCC4(C)C)ccc2N2c3cc(C(C)(C)C)ccc3B3c4sc5ccc(C(C)(C)C)cc5c4N(c4ccc5c(c4)oc4cc6c(cc45)CCCC6)c4cc(C(C)(C)C)cc2c43)cc(C(C)(C)C)c1]

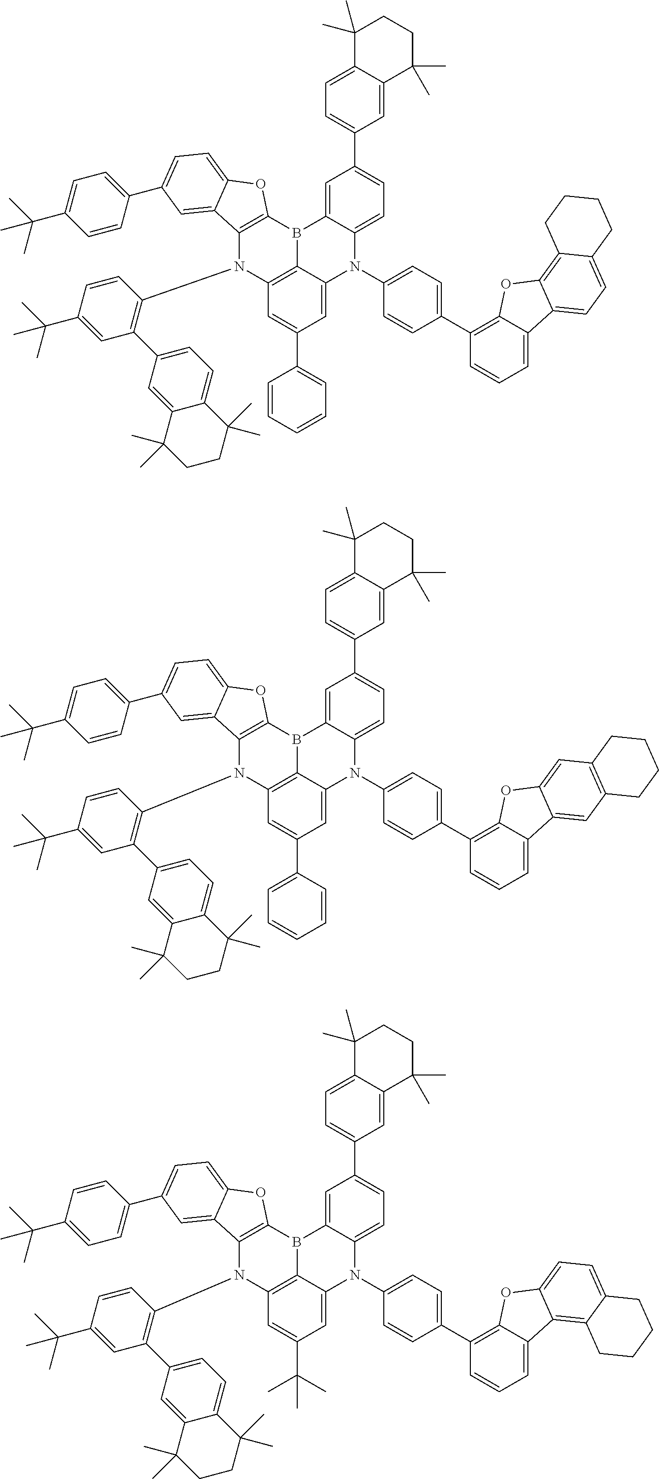

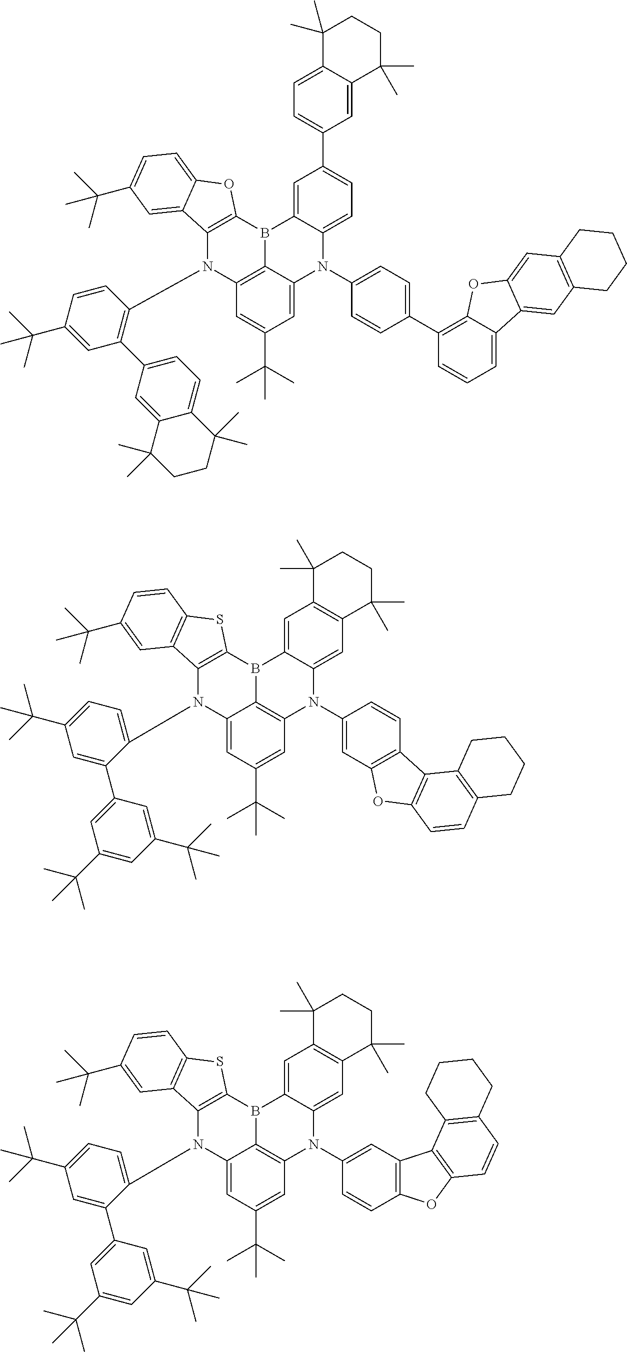 [SMILES: CC(C)(C)c1ccc(N2c3cc(C(C)(C)C)cc4c3B(c3cc(-c5ccc6c(c5)C(C)(C)CCC6(C)C)ccc3N4c3ccc(-c4cccc5c4oc4cc6c(cc45)CCCC6)cc3)c3oc4ccc(C(C)(C)C)cc4c32)c(-c2ccc3c(c2)C(C)(C)CCC3(C)C)c1 ; CC(C)(C)c1cc(-c2cc(C(C)(C)C)ccc2N2c3cc(C(C)(C)C)cc4c3B(c3cc5c(cc3N4c3ccc4c(c3)oc3ccc6c(c34)CCCC6)C(C)(C)CCC5(C)C)c3sc4ccc(C(C)(C)C)cc4c32)cc(C(C)(C)C)c1 ; CC(C)(C)c1cc(-c2cc(C(C)(C)C)ccc2N2c3cc(C(C)(C)C)cc4c3B(c3cc5c(cc3N4c3ccc4oc6ccc7c(c6c4c3)CCCC7)C(C)(C)CCC5(C)C)c3sc4ccc(C(C)(C)C)cc4c32)cc(C(C)(C)C)c1]

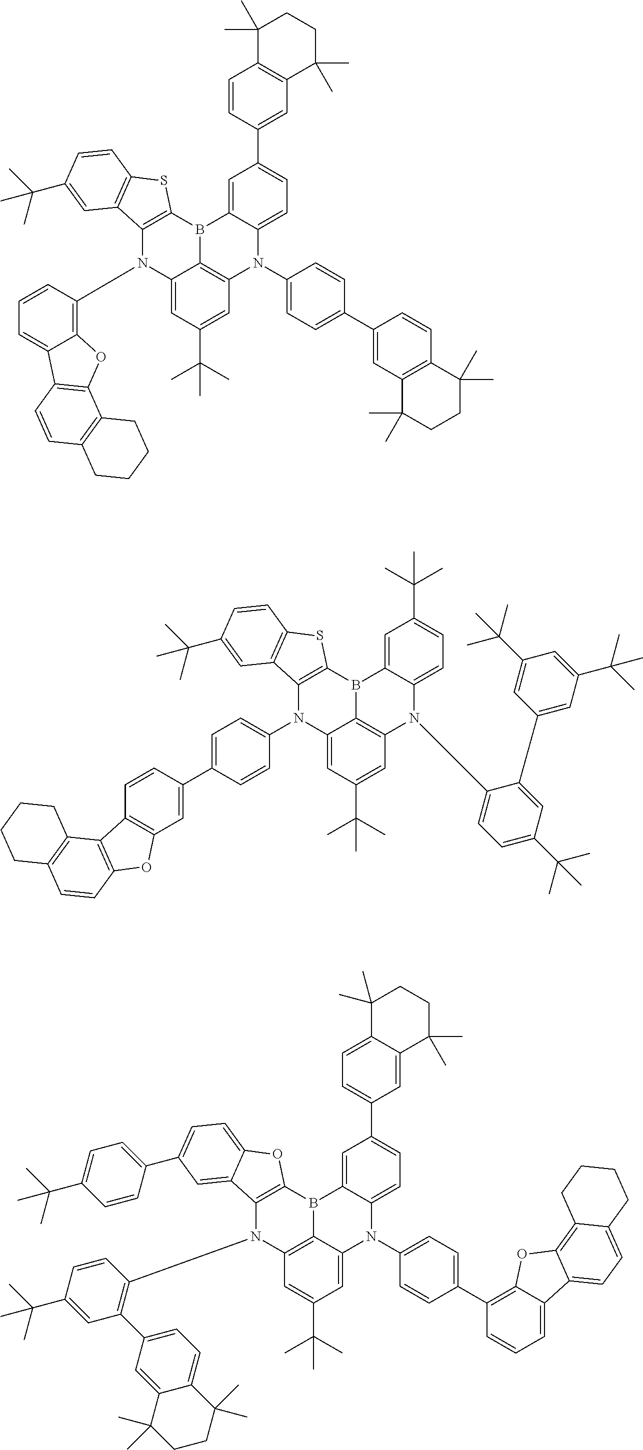

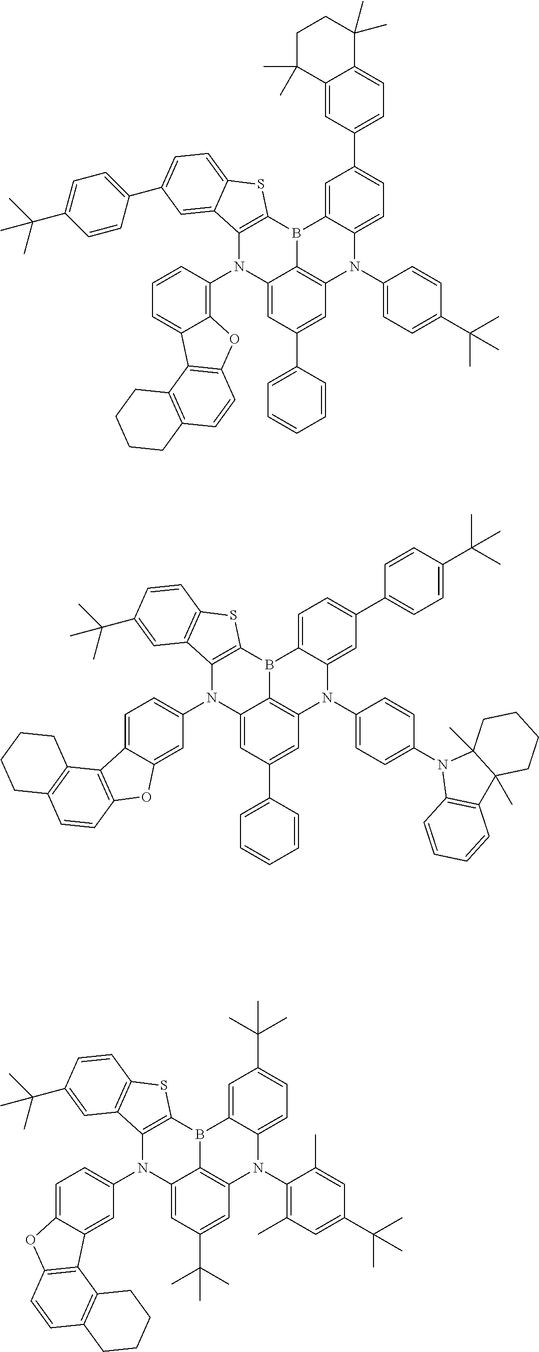

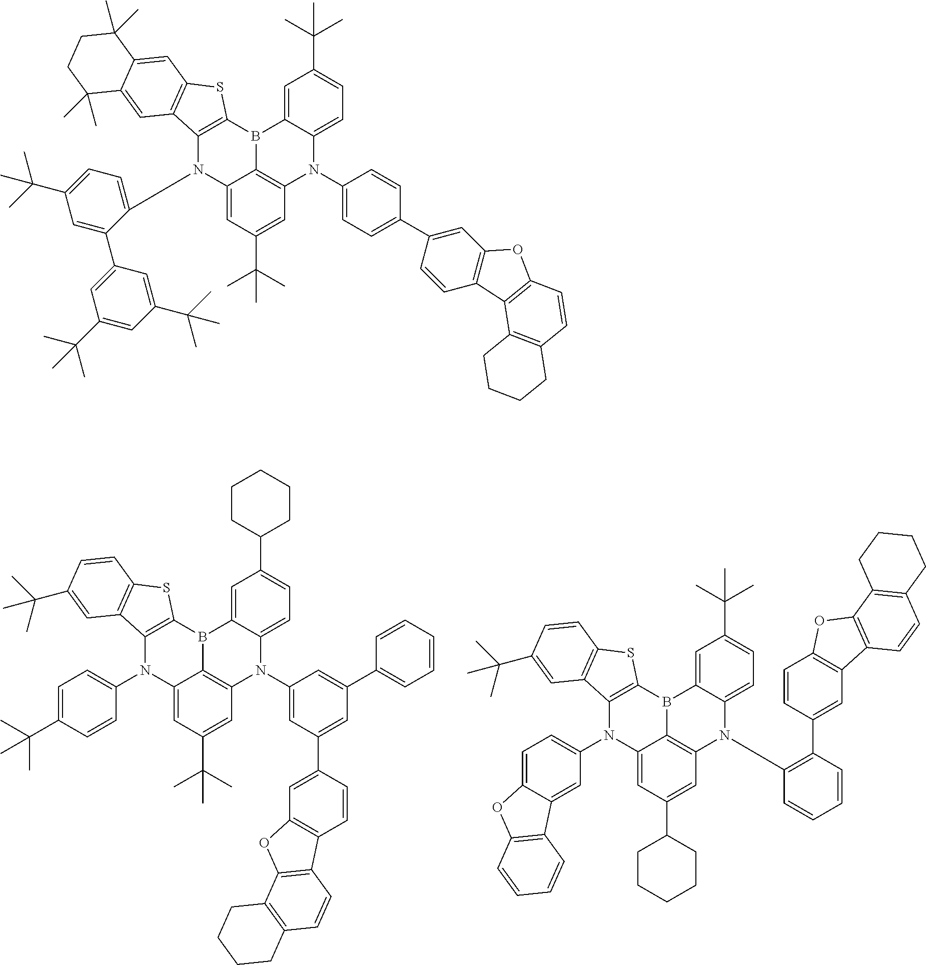

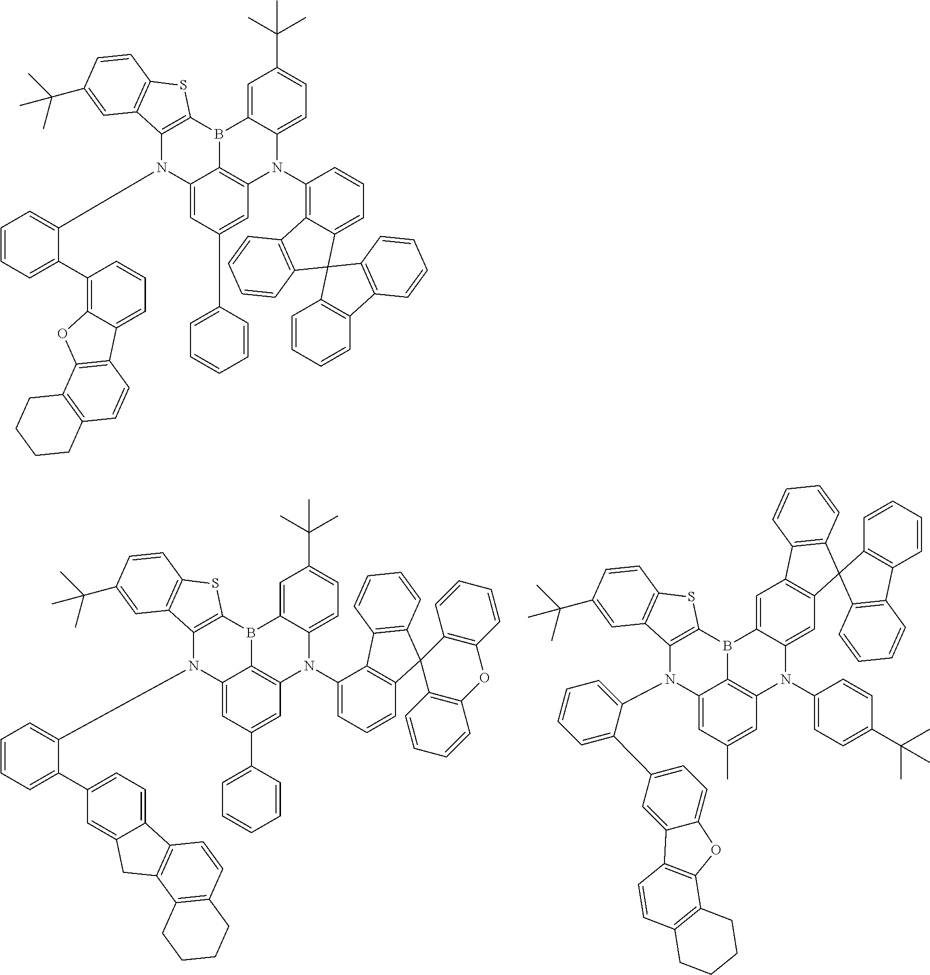

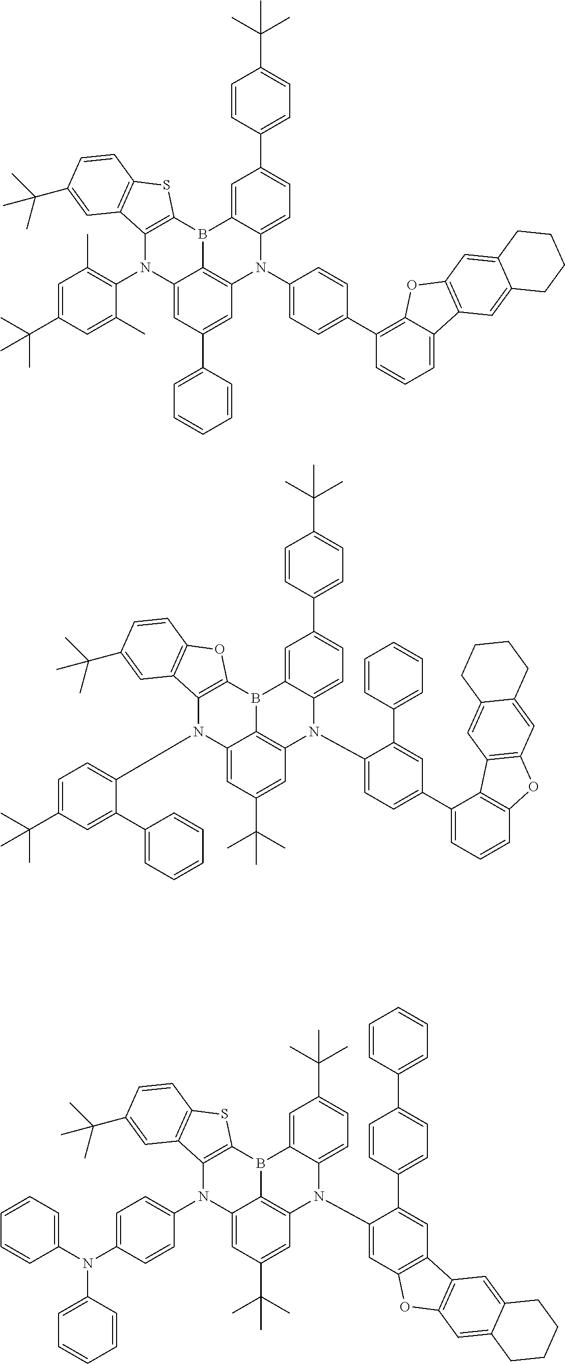 [SMILES: Cc1cc(C(C)(C)C)cc(C)c1N1c2cc(-c3ccccc3)cc3c2B(c2cc(-c4ccc(C(C)(C)C)cc4)ccc2N3c2ccc(-c3cccc4c3oc3cc5c(cc34)CCCC5)cc2)c2sc3ccc(C(C)(C)C)cc3c21 ; CC(C)(C)c1ccc(-c2ccc3c(c2)B2c4oc5ccc(C(C)(C)C)cc5c4N(c4ccc(C(C)(C)C)cc4-c4ccccc4)c4cc(C(C)(C)C)cc(c42)N3c2ccc(-c3cccc4oc5cc6c(cc5c34)CCCC6)cc2-c2ccccc2)cc1 ; CC(C)(C)c1ccc2c(c1)B1c3sc4ccc(C(C)(C)C)cc4c3N(c3ccc(N(c4ccccc4)c4ccccc4)cc3)c3cc(C(C)(C)C)cc(c31)N2c1cc2oc3cc4c(cc3c2cc1-c1ccc(-c2ccccc2)cc1)CCCC4]

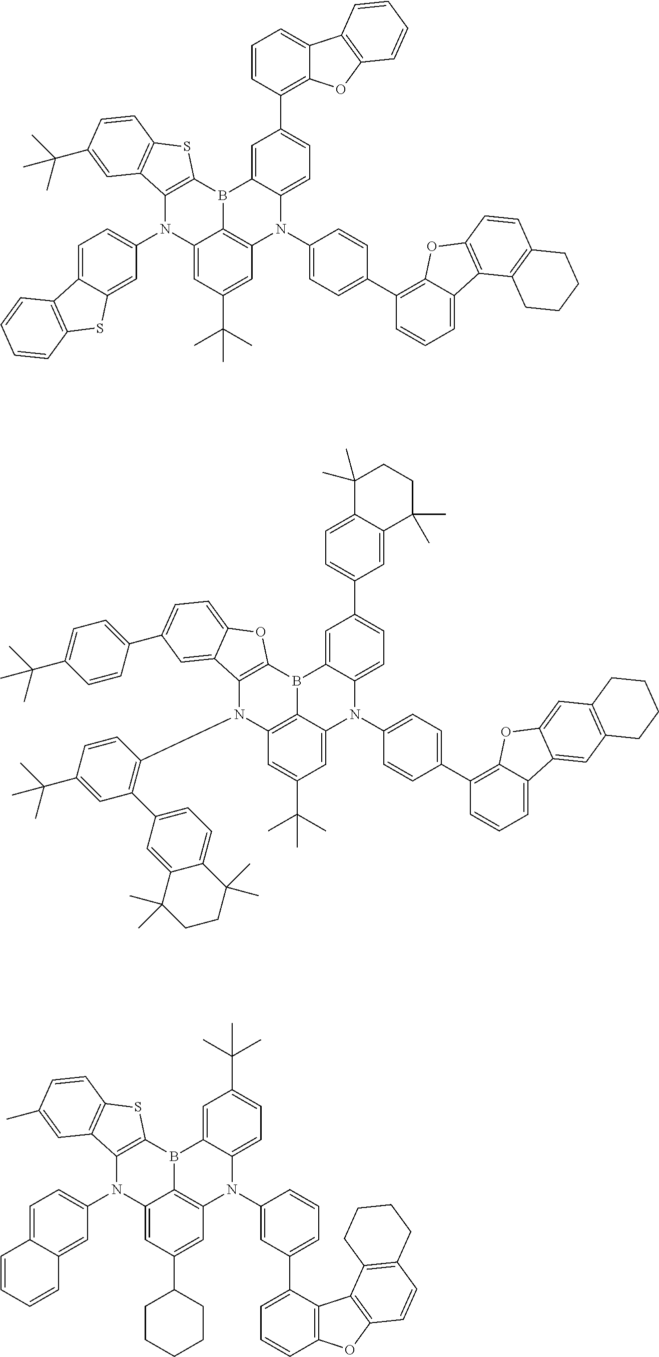 [SMILES: CC(C)(C)c1cc2c3c(c1)N(c1ccc4c(c1)sc1ccccc14)c1c(sc4ccc(C(C)(C)C)cc14)B3c1cc(-c3cccc4c3oc3ccccc34)ccc1N2c1ccc(-c2cccc3c2oc2ccc4c(c23)CCCC4)cc1 ; CC(C)(C)c1ccc(-c2ccc3oc4c(c3c2)N(c2ccc(C(C)(C)C)cc2-c2ccc3c(c2)C(C)(C)CCC3(C)C)c2cc(C(C)(C)C)cc3c2B4c2cc(-c4ccc5c(c4)C(C)(C)CCC5(C)C)ccc2N3c2ccc(-c3cccc4c3oc3cc5c(cc34)CCCC5)cc2)cc1 ; Cc1ccc2sc3c(c2c1)N(c1ccc2ccccc2c1)c1cc(C2CCCCC2)cc2c1B3c1cc(C(C)(C)C)ccc1N2c1cccc(-c2cccc3oc4ccc5c(c4c23)CCCC5)c1]

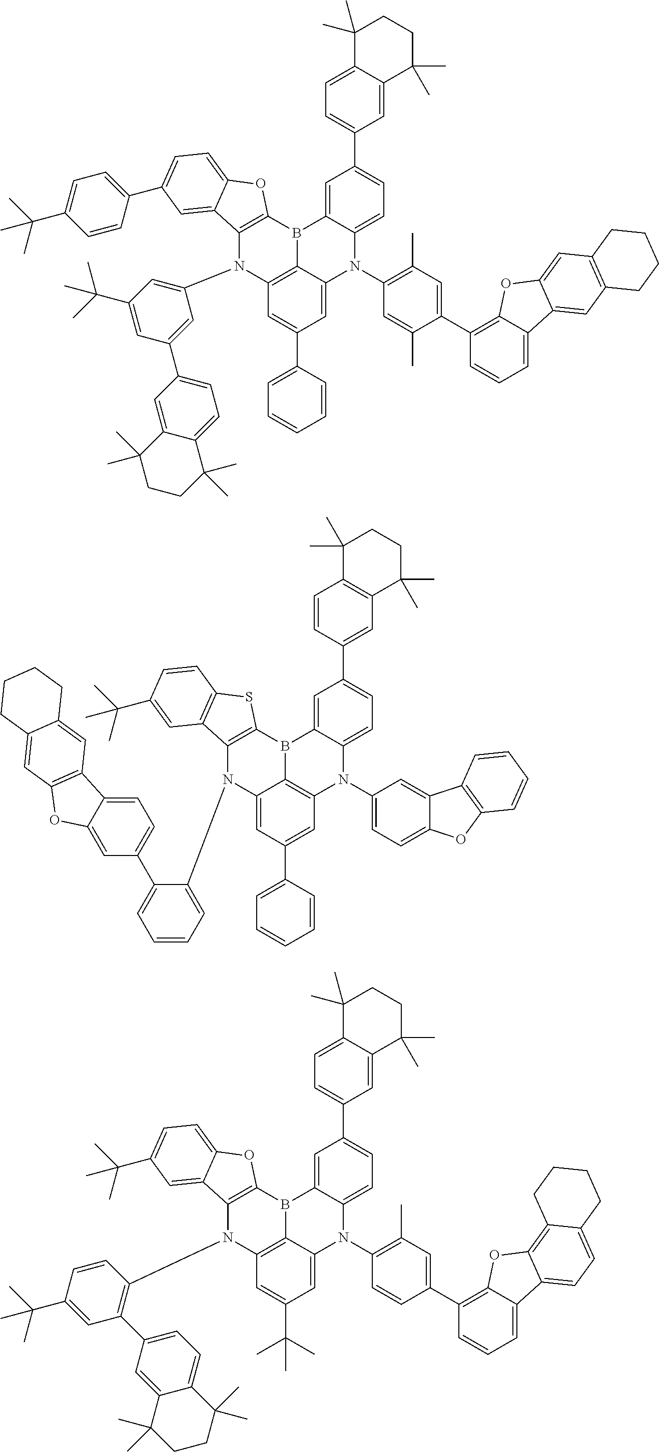

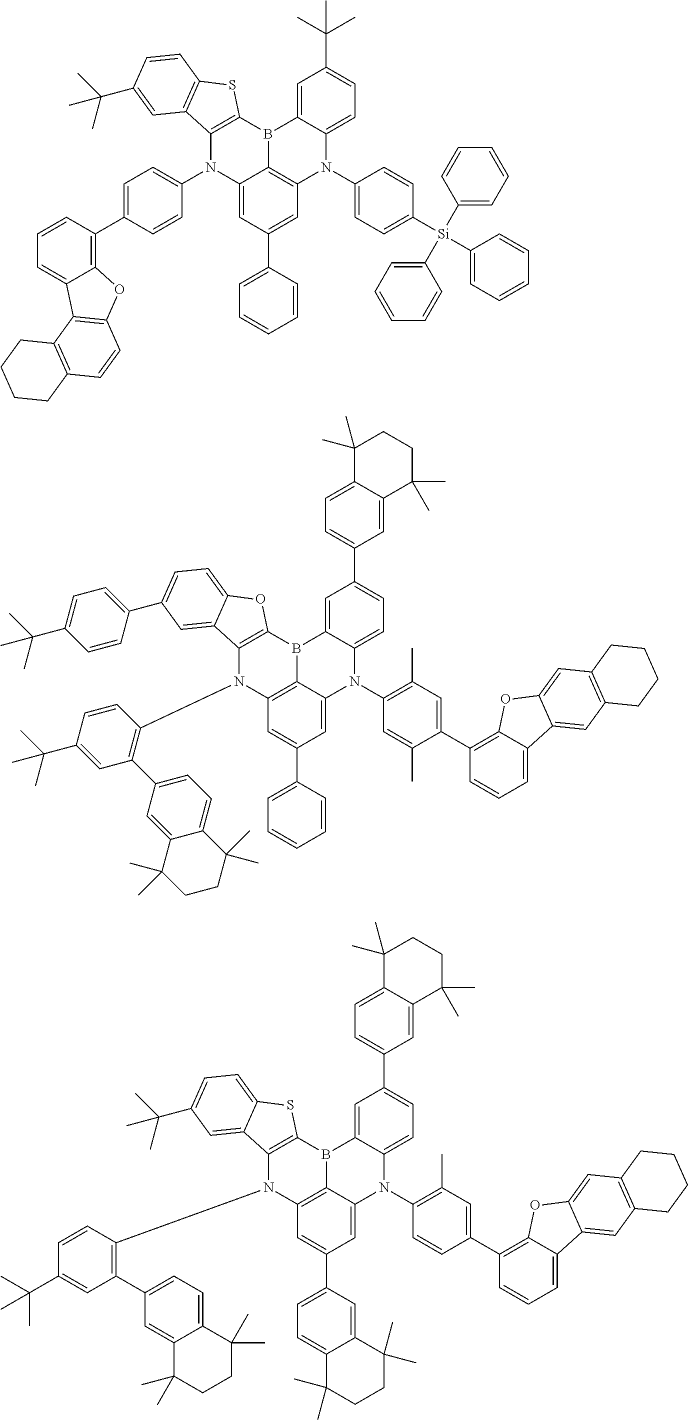

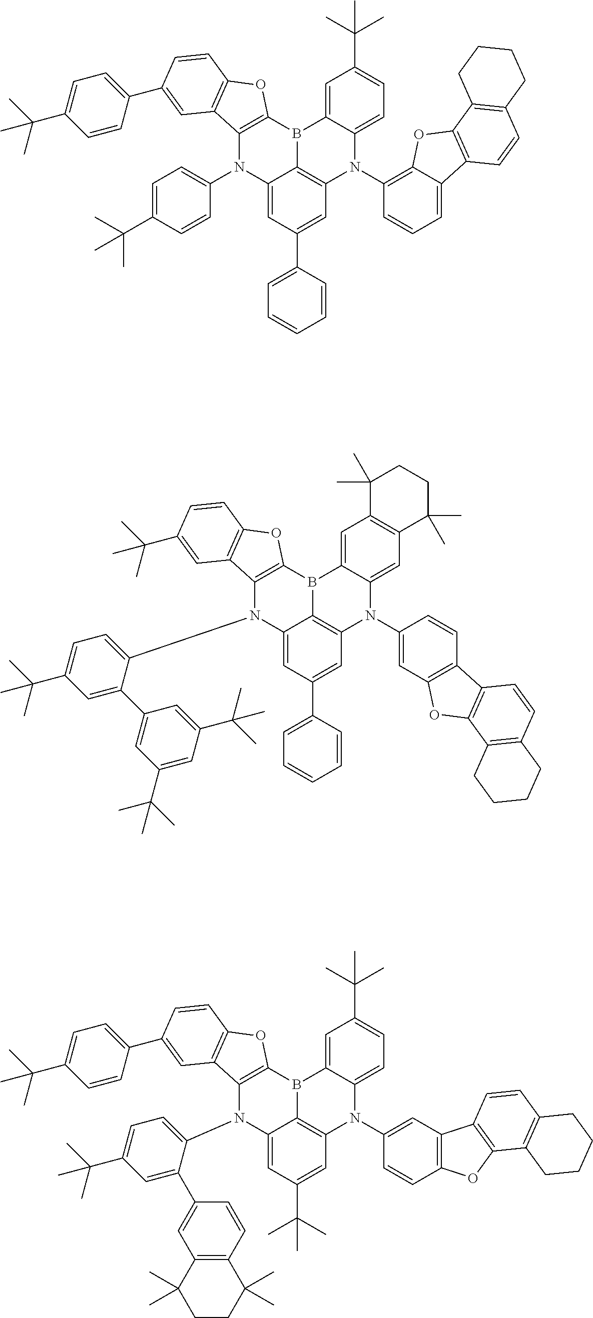 [SMILES: CC(C)(C)c1ccc(-c2ccc3oc4c(c3c2)N(c2ccc(C(C)(C)C)cc2)c2cc(-c3ccccc3)cc3c2B4c2cc(C(C)(C)C)ccc2N3c2cccc3c2oc2c4c(ccc23)CCCC4)cc1 ; CC(C)(C)c1cc(-c2cc(C(C)(C)C)ccc2N2c3cc(-c4ccccc4)cc4c3B(c3cc5c(cc3N4c3ccc4c(c3)oc3c6c(ccc34)CCCC6)C(C)(C)CCC5(C)C)c3oc4ccc(C(C)(C)C)cc4c32)cc(C(C)(C)C)c1 ; CC(C)(C)c1ccc(-c2ccc3oc4c(c3c2)N(c2ccc(C(C)(C)C)cc2-c2ccc3c(c2)C(C)(C)CCC3(C)C)c2cc(C(C)(C)C)cc3c2B4c2cc(C(C)(C)C)ccc2N3c2ccc3oc4c5c(ccc4c3c2)CCCC5)cc1]

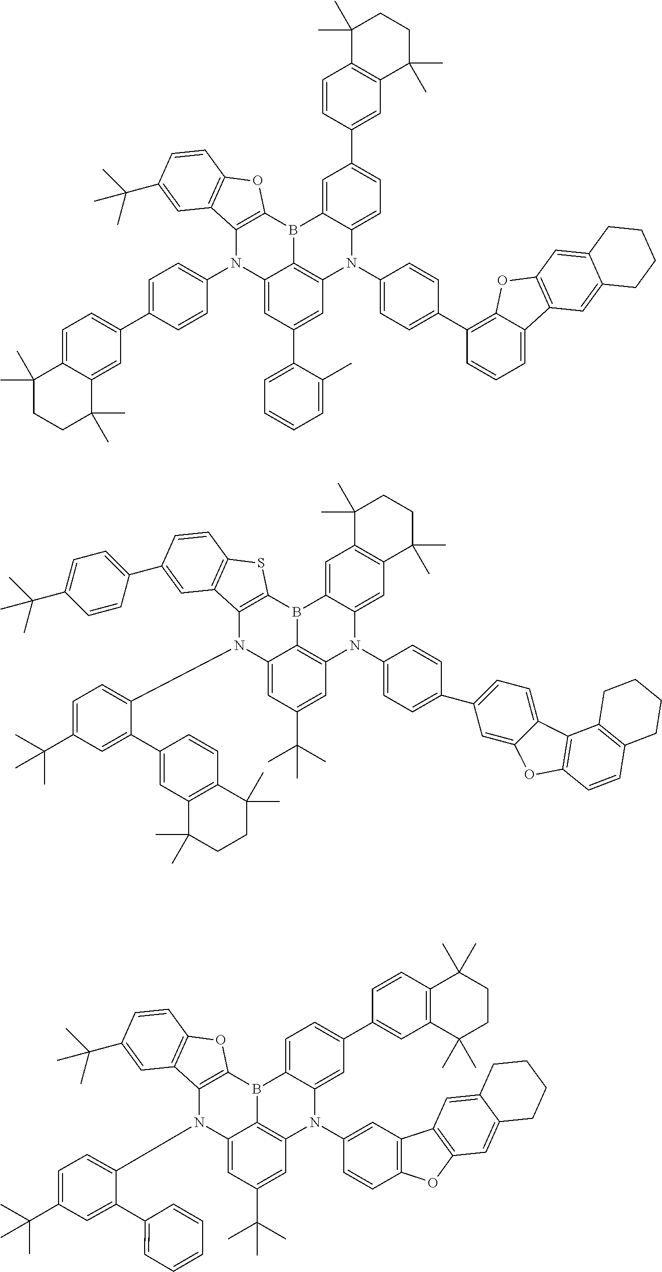 [SMILES: Cc1ccccc1-c1cc2c3c(c1)N(c1ccc(-c4ccc5c(c4)C(C)(C)CCC5(C)C)cc1)c1c(oc4ccc(C(C)(C)C)cc14)B3c1cc(-c3ccc4c(c3)C(C)(C)CCC4(C)C)ccc1N2c1ccc(-c2cccc3c2oc2cc4c(cc23)CCCC4)cc1 ; CC(C)(C)c1ccc(-c2ccc3sc4c(c3c2)N(c2ccc(C(C)(C)C)cc2-c2ccc3c(c2)C(C)(C)CCC3(C)C)c2cc(C(C)(C)C)cc3c2B4c2cc4c(cc2N3c2ccc(-c3ccc5c(c3)oc3ccc6c(c35)CCCC6)cc2)C(C)(C)CCC4(C)C)cc1 ; CC(C)(C)c1ccc(N2c3cc(C(C)(C)C)cc4c3B(c3ccc(-c5ccc6c(c5)C(C)(C)CCC6(C)C)cc3N4c3ccc4oc5cc6c(cc5c4c3)CCCC6)c3oc4ccc(C(C)(C)C)cc4c32)c(-c2ccccc2)c1]

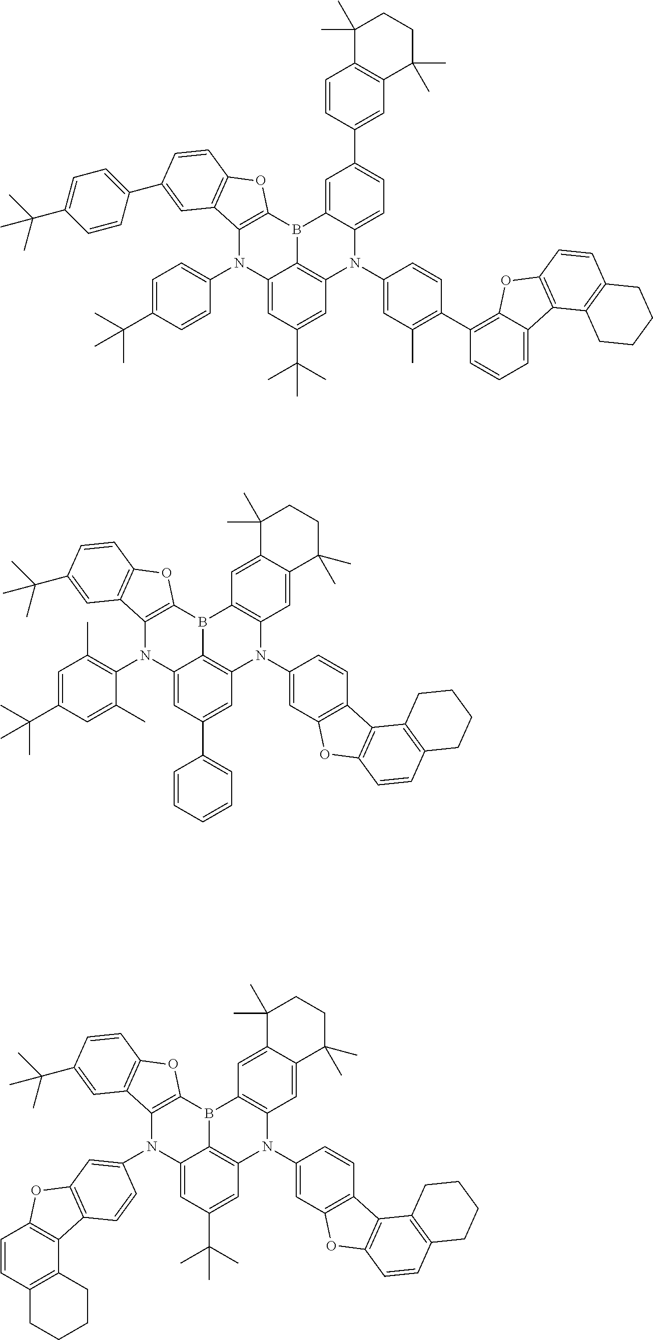 [SMILES: Cc1cc(N2c3ccc(-c4ccc5c(c4)C(C)(C)CCC5(C)C)cc3B3c4oc5ccc(-c6ccc(C(C)(C)C)cc6)cc5c4N(c4ccc(C(C)(C)C)cc4)c4cc(C(C)(C)C)cc2c43)ccc1-c1cccc2c1oc1ccc3c(c12)CCCC3 ; Cc1cc(C(C)(C)C)cc(C)c1N1c2cc(-c3ccccc3)cc3c2B(c2cc4c(cc2N3c2ccc3c(c2)oc2ccc5c(c23)CCCC5)C(C)(C)CCC4(C)C)c2oc3ccc(C(C)(C)C)cc3c21 ; CC(C)(C)c1cc2c3c(c1)N(c1ccc4c(c1)oc1ccc5c(c14)CCCC5)c1c(oc4ccc(C(C)(C)C)cc14)B3c1cc3c(cc1N2c1ccc2c(c1)oc1ccc4c(c12)CCCC4)C(C)(C)CCC3(C)C]

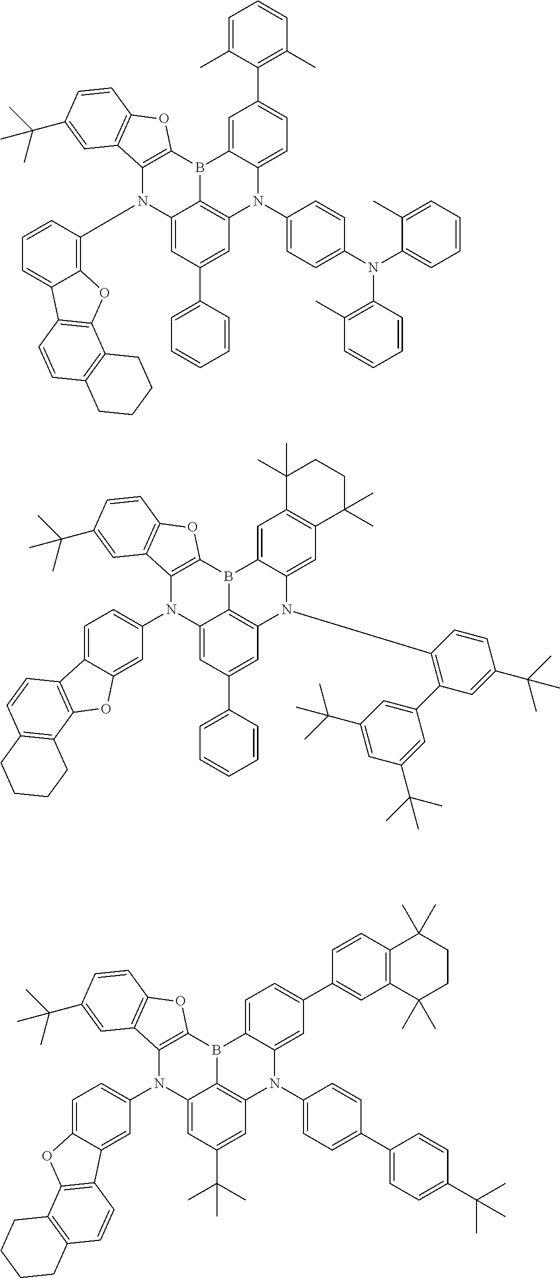 [SMILES: Cc1ccccc1N(c1ccc(N2c3ccc(-c4c(C)cccc4C)cc3B3c4oc5ccc(C(C)(C)C)cc5c4N(c4cccc5c4oc4c6c(ccc45)CCCC6)c4cc(-c5ccccc5)cc2c43)cc1)c1ccccc1C ; CC(C)(C)c1cc(-c2cc(C(C)(C)C)ccc2N2c3cc4c(cc3B3c5oc6ccc(C(C)(C)C)cc6c5N(c5ccc6c(c5)oc5c7c(ccc56)CCCC7)c5cc(-c6ccccc6)cc2c53)C(C)(C)CCC4(C)C)cc(C(C)(C)C)c1 ; CC(C)(C)c1ccc(-c2ccc(N3c4cc(-c5ccc6c(c5)C(C)(C)CCC6(C)C)ccc4B4c5oc6ccc(C(C)(C)C)cc6c5N(c5ccc6oc7c8c(ccc7c6c5)CCCC8)c5cc(C(C)(C)C)cc3c54)cc2)cc1]

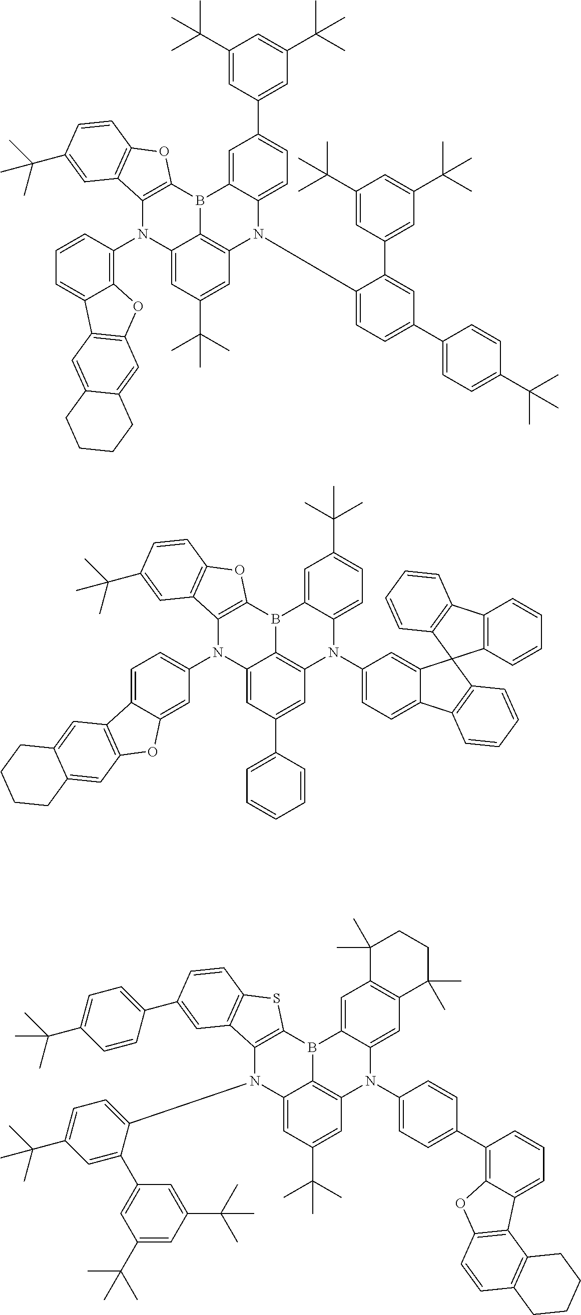

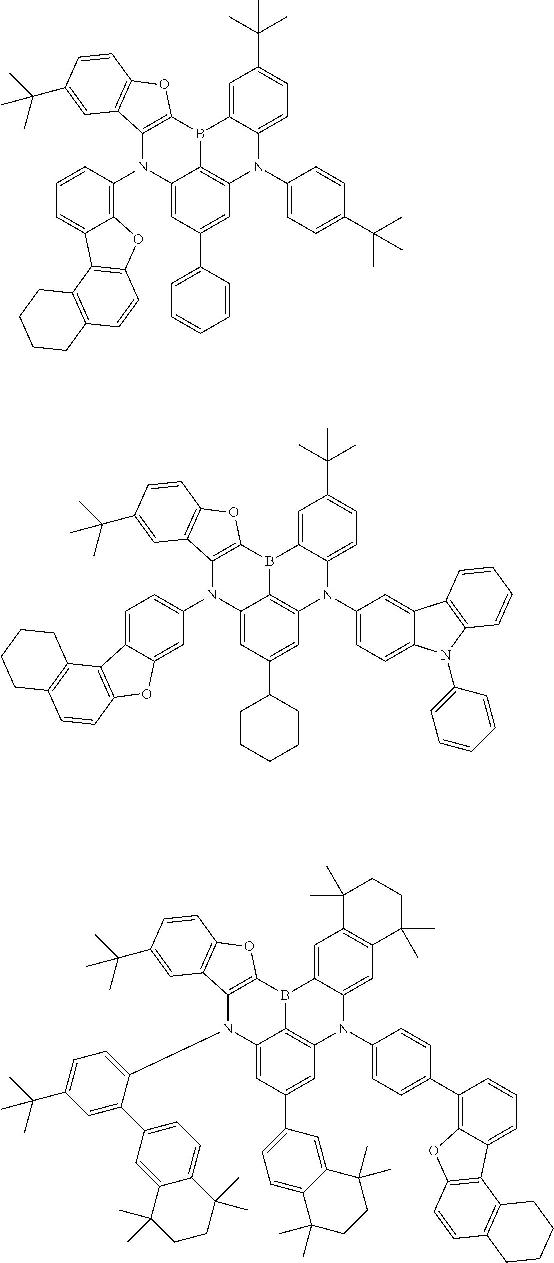

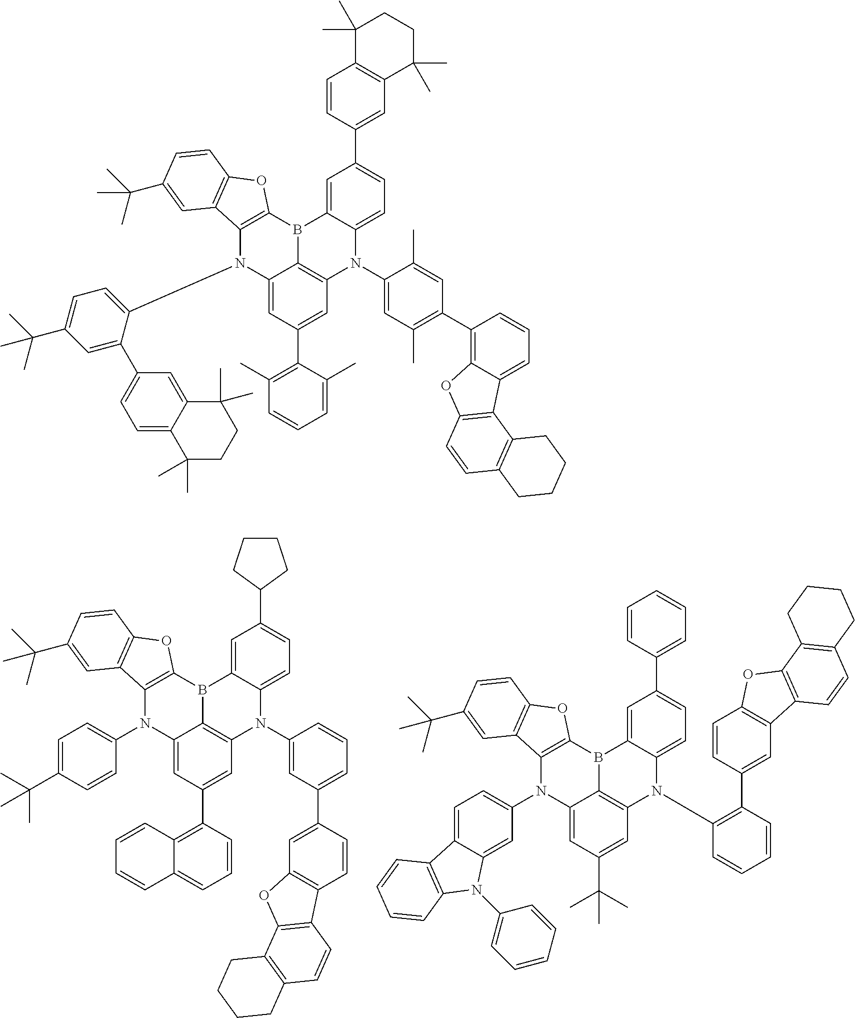

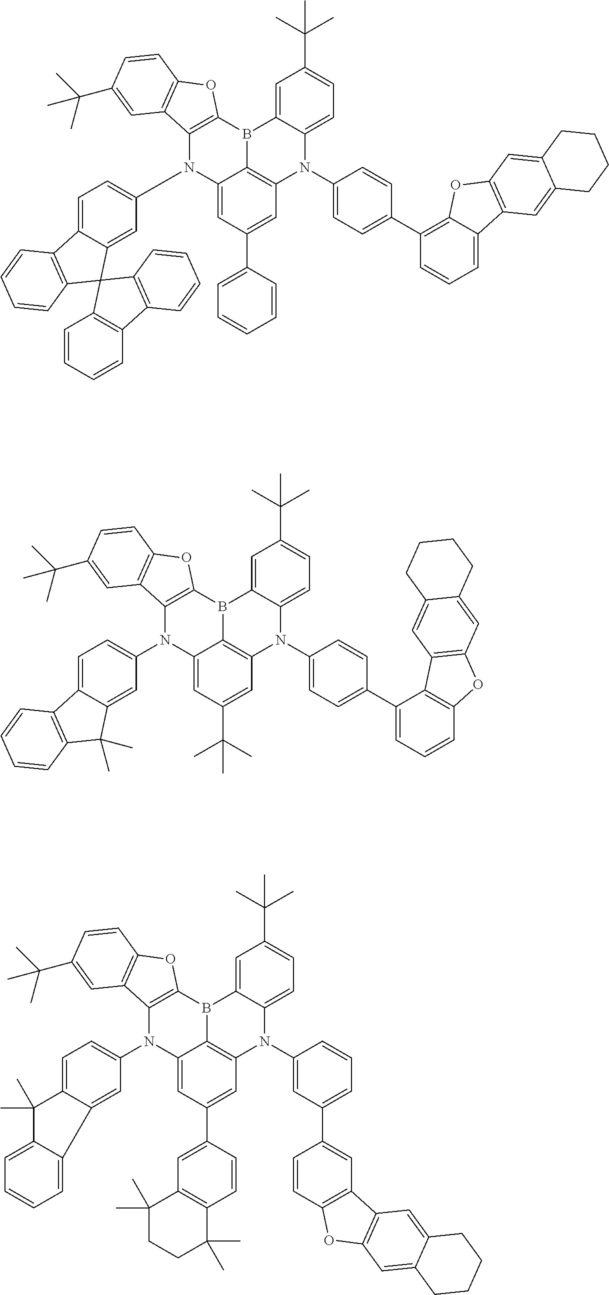 [SMILES: CC(C)(C)c1ccc2c(c1)B1c3oc4ccc(C(C)(C)C)cc4c3N(c3ccc4c(c3)C3(c5ccccc5-c5ccccc53)c3ccccc3-4)c3cc(-c4ccccc4)cc(c31)N2c1ccc(-c2cccc3c2oc2cc4c(cc23)CCCC4)cc1 ; CC(C)(C)c1ccc2c(c1)B1c3oc4ccc(C(C)(C)C)cc4c3N(c3ccc4c(c3)C(C)(C)c3ccccc3-4)c3cc(C(C)(C)C)cc(c31)N2c1ccc(-c2cccc3oc4cc5c(cc4c23)CCCC5)cc1 ; CC(C)(C)c1ccc2c(c1)B1c3oc4ccc(C(C)(C)C)cc4c3N(c3ccc4c(c3)-c3ccccc3C4(C)C)c3cc(-c4ccc5c(c4)C(C)(C)CCC5(C)C)cc(c31)N2c1cccc(-c2ccc3oc4cc5c(cc4c3c2)CCCC5)c1]

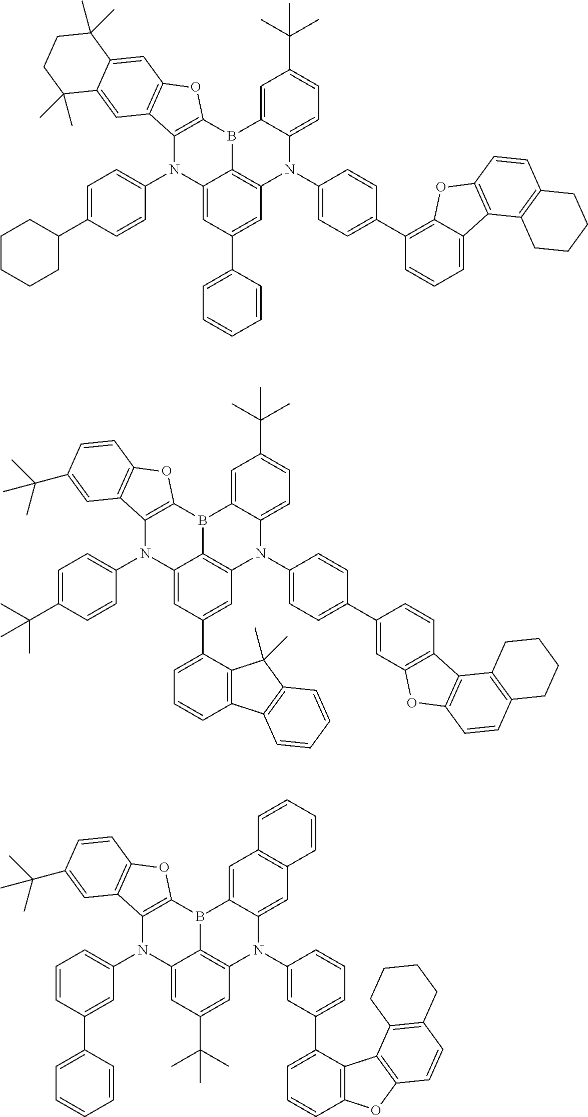 [SMILES: CC(C)(C)c1ccc2c(c1)B1c3oc4cc5c(cc4c3N(c3ccc(C4CCCCC4)cc3)c3cc(-c4ccccc4)cc(c31)N2c1ccc(-c2cccc3c2oc2ccc4c(c23)CCCC4)cc1)C(C)(C)CCC5(C)C ; CC(C)(C)c1ccc(N2c3cc(-c4cccc5c4C(C)(C)c4ccccc4-5)cc4c3B(c3cc(C(C)(C)C)ccc3N4c3ccc(-c4ccc5c(c4)oc4ccc6c(c45)CCCC6)cc3)c3oc4ccc(C(C)(C)C)cc4c32)cc1 ; CC(C)(C)c1cc2c3c(c1)N(c1cccc(-c4ccccc4)c1)c1c(oc4ccc(C(C)(C)C)cc14)B3c1cc3ccccc3cc1N2c1cccc(-c2cccc3oc4ccc5c(c4c23)CCCC5)c1]

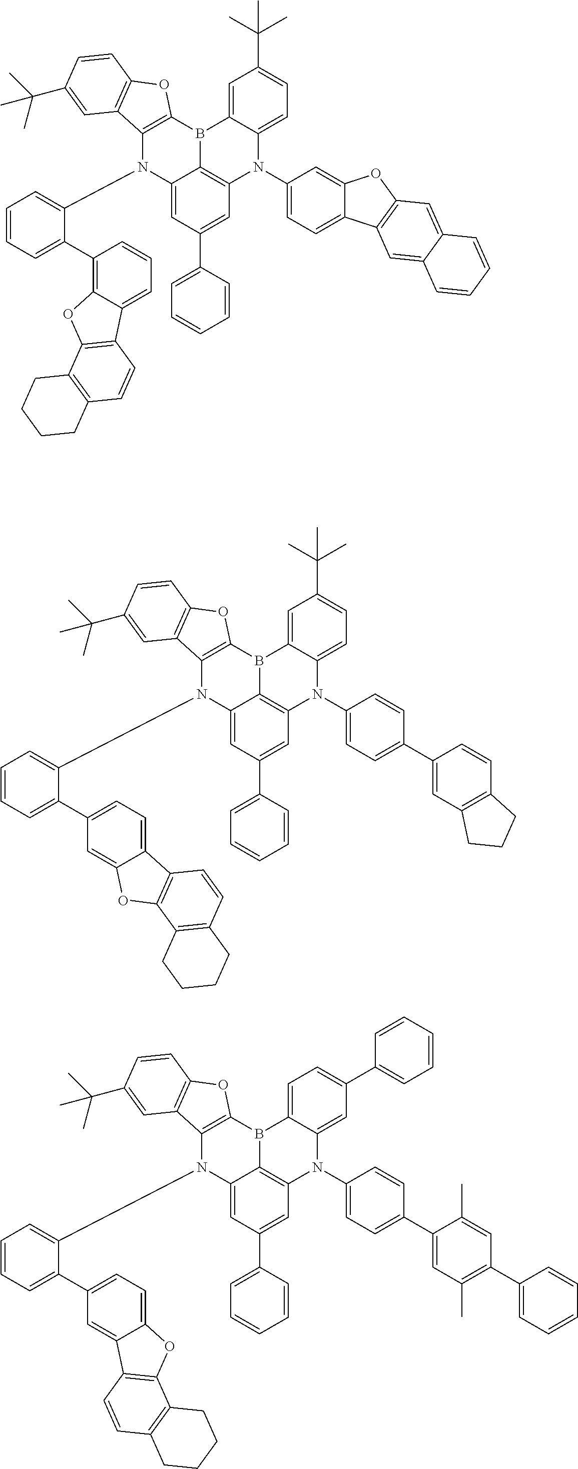 [SMILES: CC(C)(C)c1ccc2c(c1)B1c3oc4ccc(C(C)(C)C)cc4c3N(c3ccccc3-c3cccc4c3oc3c5c(ccc34)CCCC5)c3cc(-c4ccccc4)cc(c31)N2c1ccc2c(c1)oc1cc3ccccc3cc12 ; CC(C)(C)c1ccc2c(c1)B1c3oc4ccc(C(C)(C)C)cc4c3N(c3ccccc3-c3ccc4c(c3)oc3c5c(ccc34)CCCC5)c3cc(-c4ccccc4)cc(c31)N2c1ccc(-c2ccc3c(c2)CCC3)cc1 ; Cc1cc(-c2ccc(N3c4cc(-c5ccccc5)ccc4B4c5oc6ccc(C(C)(C)C)cc6c5N(c5ccccc5-c5ccc6oc7c8c(ccc7c6c5)CCCC8)c5cc(-c6ccccc6)cc3c54)cc2)c(C)cc1-c1ccccc1]

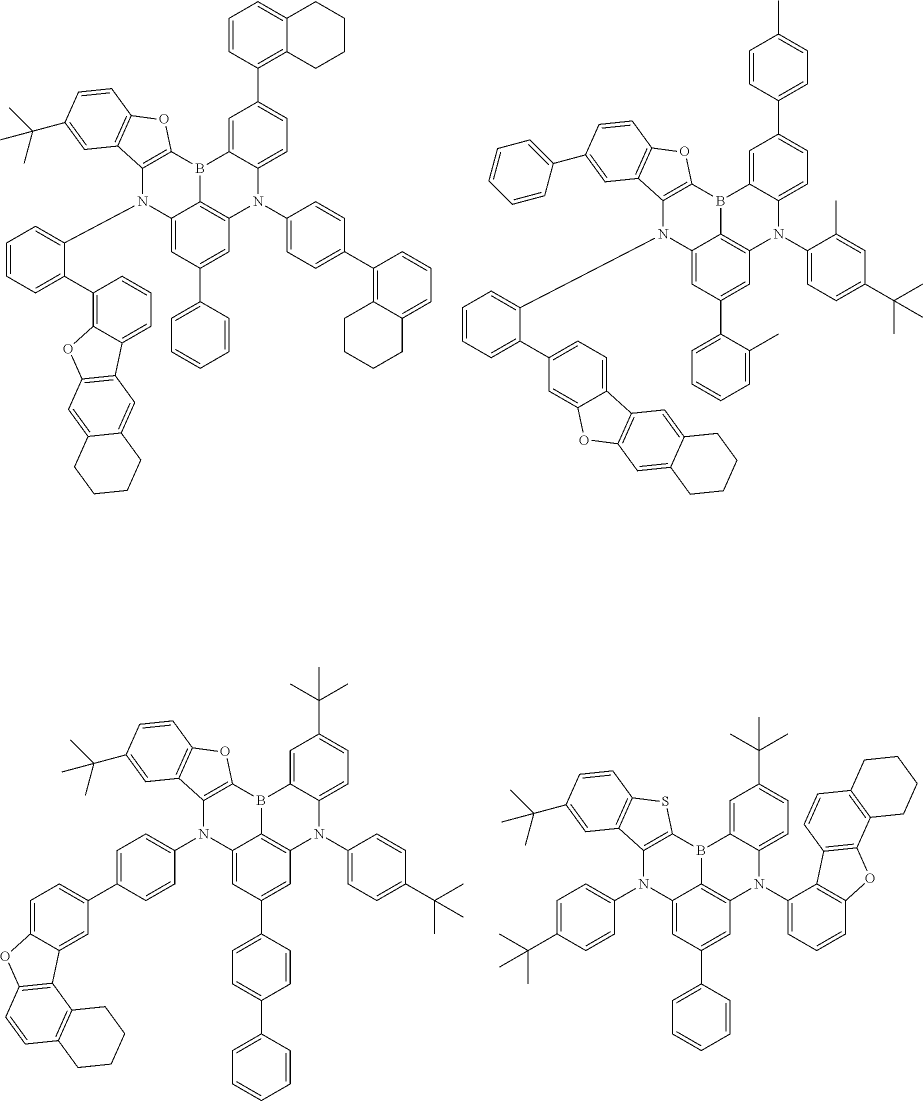

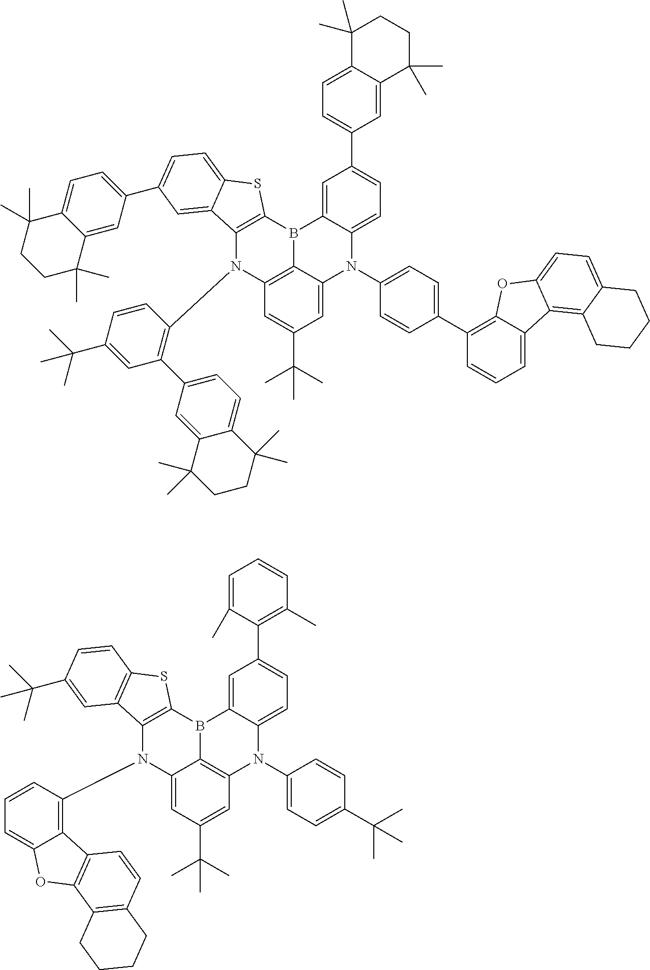 [SMILES: CC(C)(C)c1ccc(N2c3cc(C(C)(C)C)cc4c3B(c3cc(-c5ccc6c(c5)C(C)(C)CCC6(C)C)ccc3N4c3ccc(-c4cccc5c4oc4ccc6c(c45)CCCC6)cc3)c3sc4ccc(-c5ccc6c(c5)C(C)(C)CCC6(C)C)cc4c32)c(-c2ccc3c(c2)C(C)(C)CCC3(C)C)c1 ; Cc1cccc(C)c1-c1ccc2c(c1)B1c3sc4ccc(C(C)(C)C)cc4c3N(c3cccc4oc5c6c(ccc5c34)CCCC6)c3cc(C(C)(C)C)cc(c31)N2c1ccc(C(C)(C)C)cc1]

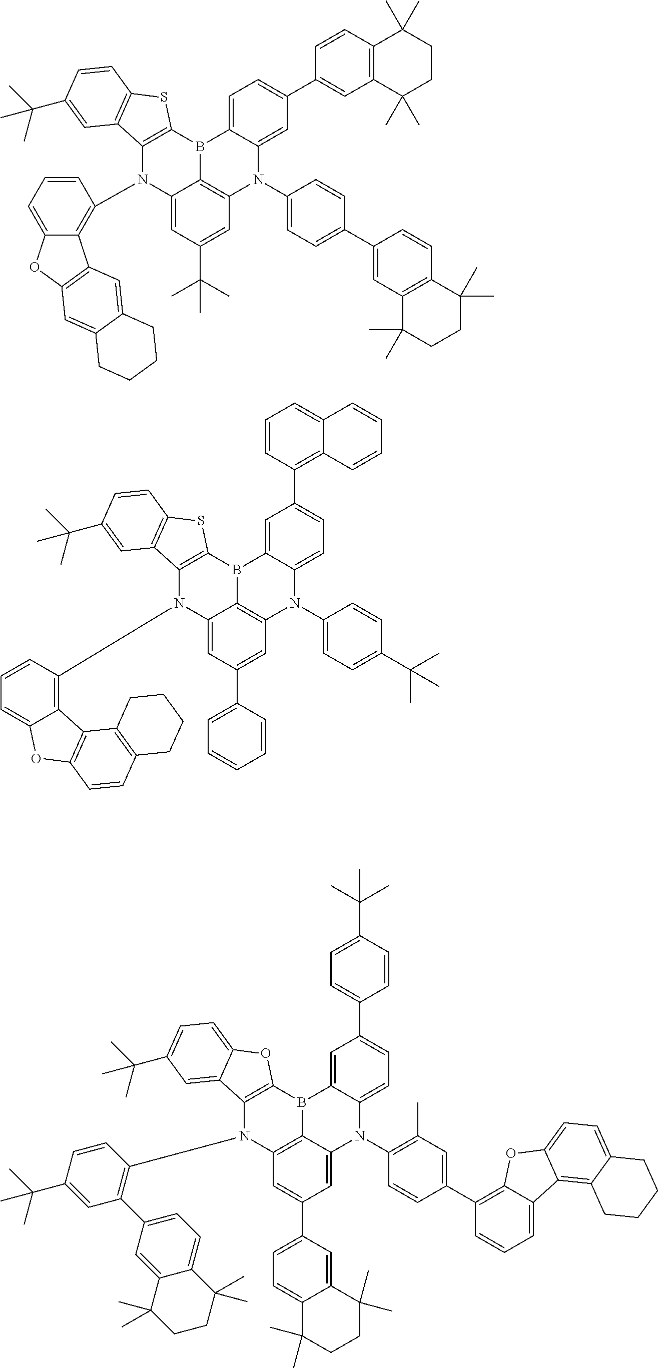

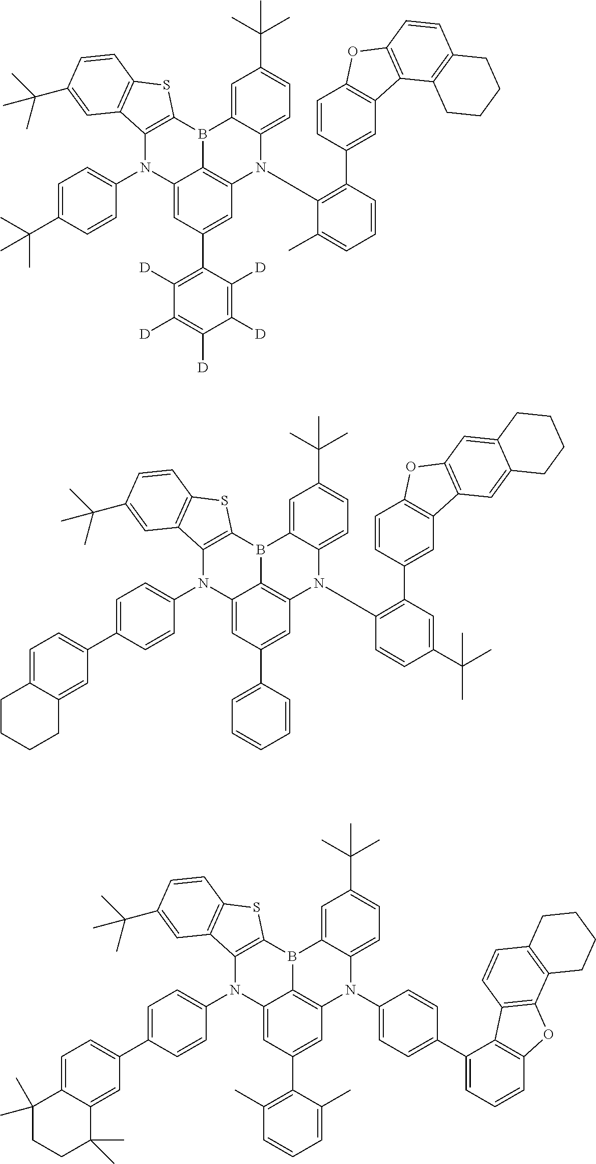 [SMILES: [2H]c1c([2H])c([2H])c(-c2cc3c4c(c2)N(c2ccc(C(C)(C)C)cc2)c2c(sc5ccc(C(C)(C)C)cc25)B4c2cc(C(C)(C)C)ccc2N3c2c(C)cccc2-c2ccc3oc4ccc5c(c4c3c2)CCCC5)c([2H])c1[2H] ; CC(C)(C)c1ccc2c(c1)B1c3sc4ccc(C(C)(C)C)cc4c3N(c3ccc(-c4ccc5c(c4)CCCC5)cc3)c3cc(-c4ccccc4)cc(c31)N2c1ccc(C(C)(C)C)cc1-c1ccc2oc3cc4c(cc3c2c1)CCCC4 ; Cc1cccc(C)c1-c1cc2c3c(c1)N(c1ccc(-c4ccc5c(c4)C(C)(C)CCC5(C)C)cc1)c1c(sc4ccc(C(C)(C)C)cc14)B3c1cc(C(C)(C)C)ccc1N2c1ccc(-c2cccc3oc4c5c(ccc4c23)CCCC5)cc1]

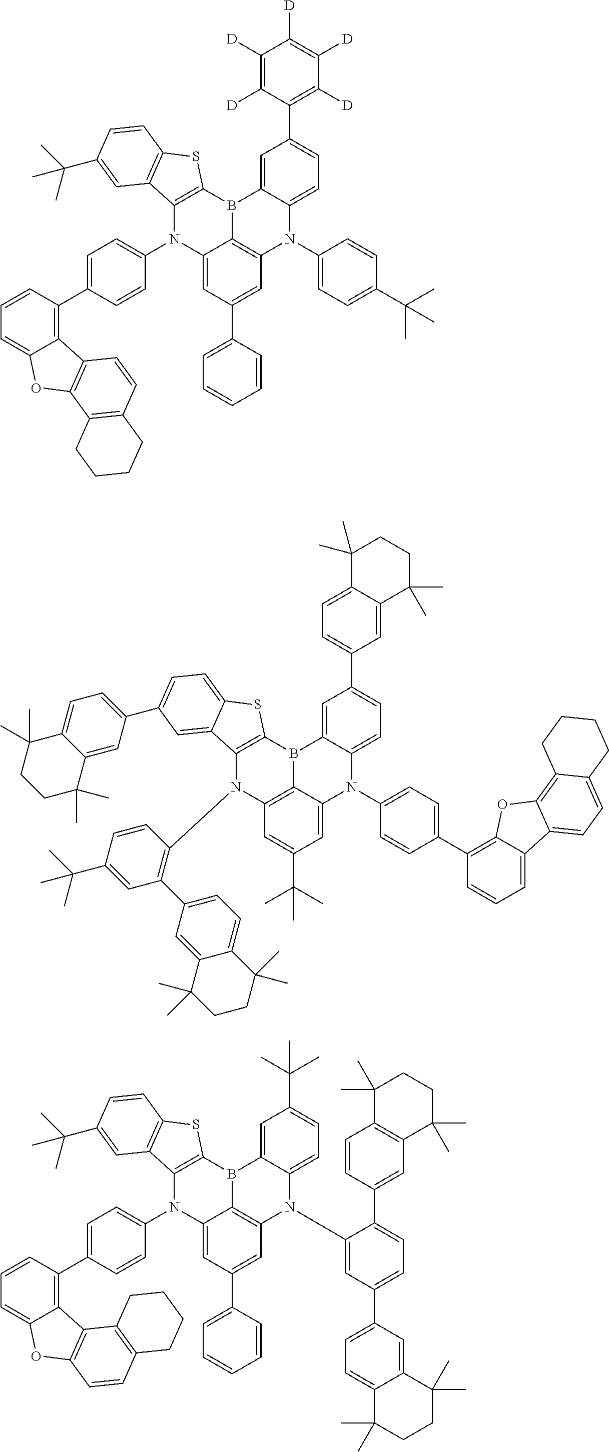

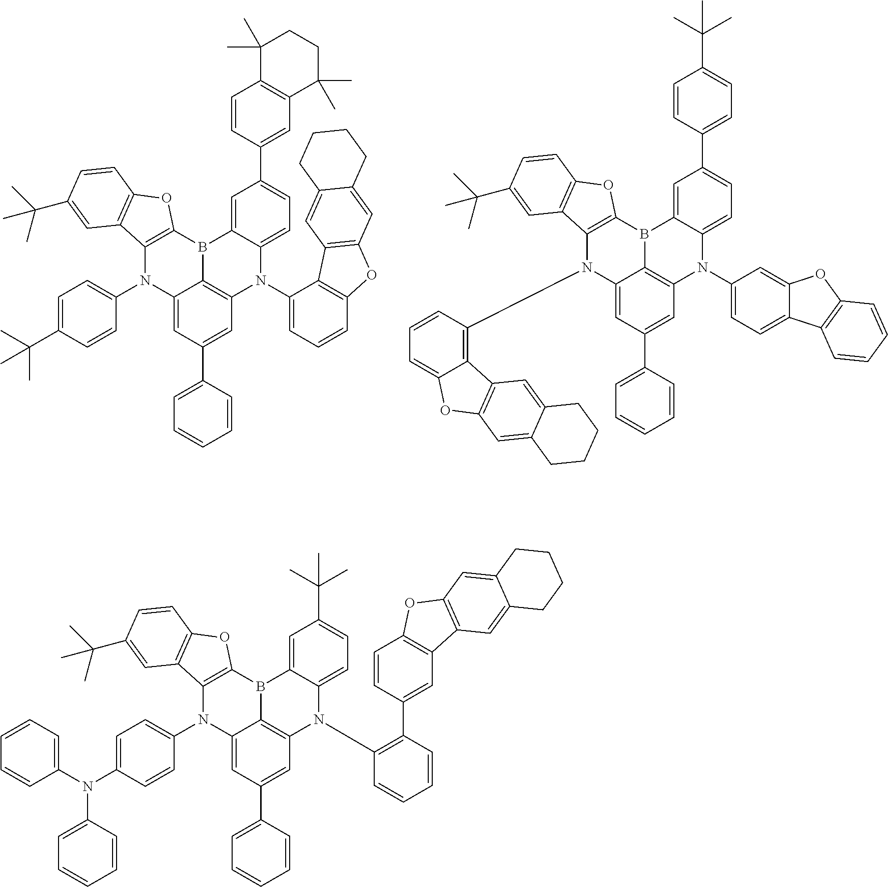 [SMILES: CC(C)(C)c1ccc(N2c3cc(-c4ccccc4)cc4c3B(c3cc(-c5ccc6c(c5)C(C)(C)CCC6(C)C)ccc3N4c3cccc4oc5cc6c(cc5c34)CCCC6)c3oc4ccc(C(C)(C)C)cc4c32)cc1 ; CC(C)(C)c1ccc(-c2ccc3c(c2)B2c4oc5ccc(C(C)(C)C)cc5c4N(c4cccc5oc6cc7c(cc6c45)CCCC7)c4cc(-c5ccccc5)cc(c42)N3c2ccc3c(c2)oc2ccccc23)cc1 ; CC(C)(C)c1ccc2c(c1)B1c3oc4ccc(C(C)(C)C)cc4c3N(c3ccc(N(c4ccccc4)c4ccccc4)cc3)c3cc(-c4ccccc4)cc(c31)N2c1ccccc1-c1ccc2oc3cc4c(cc3c2c1)CCCC4]

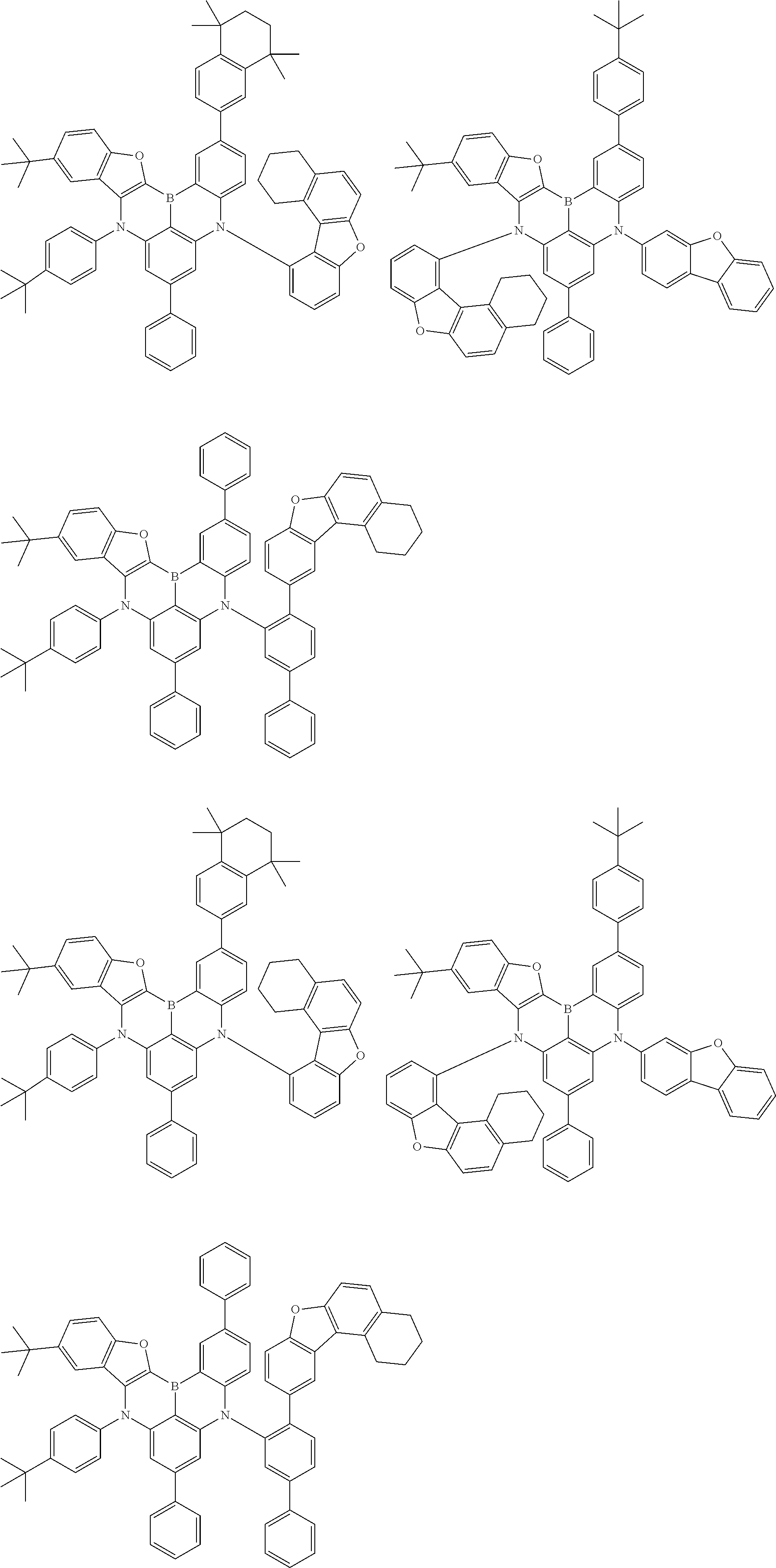

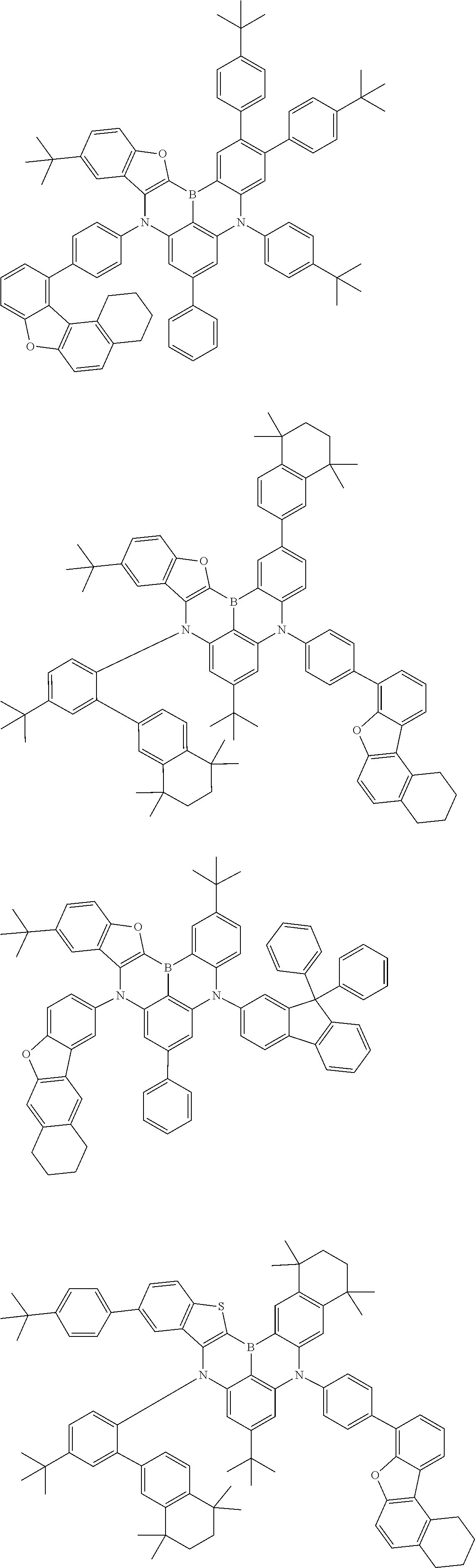

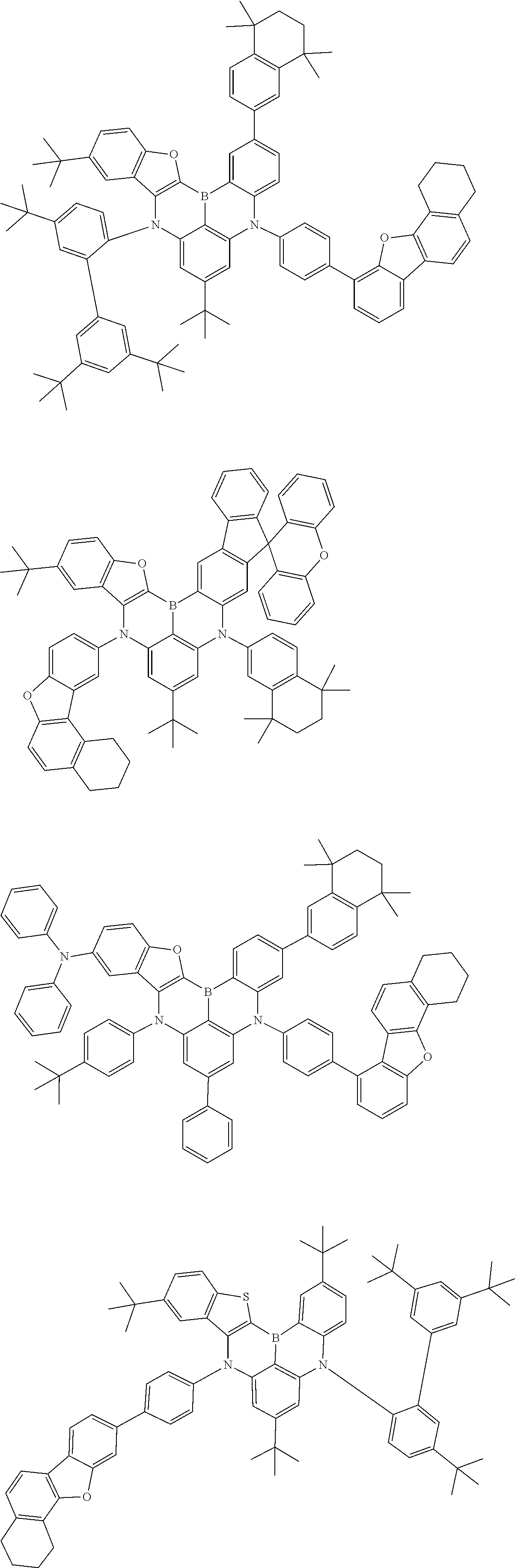

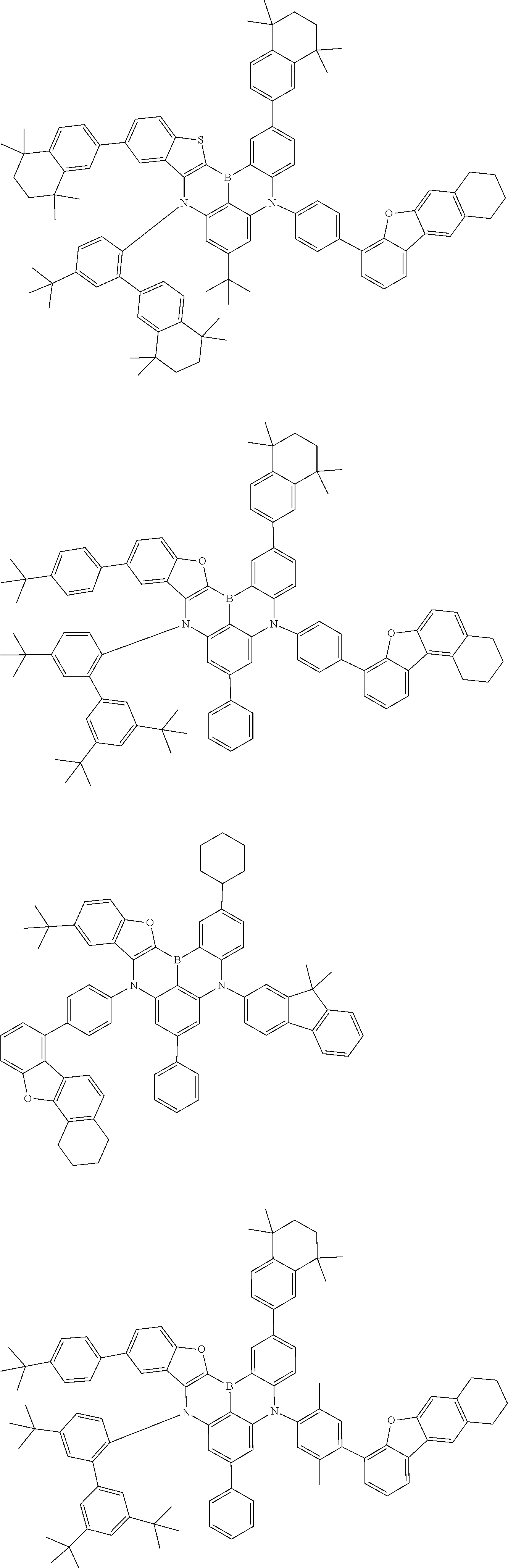

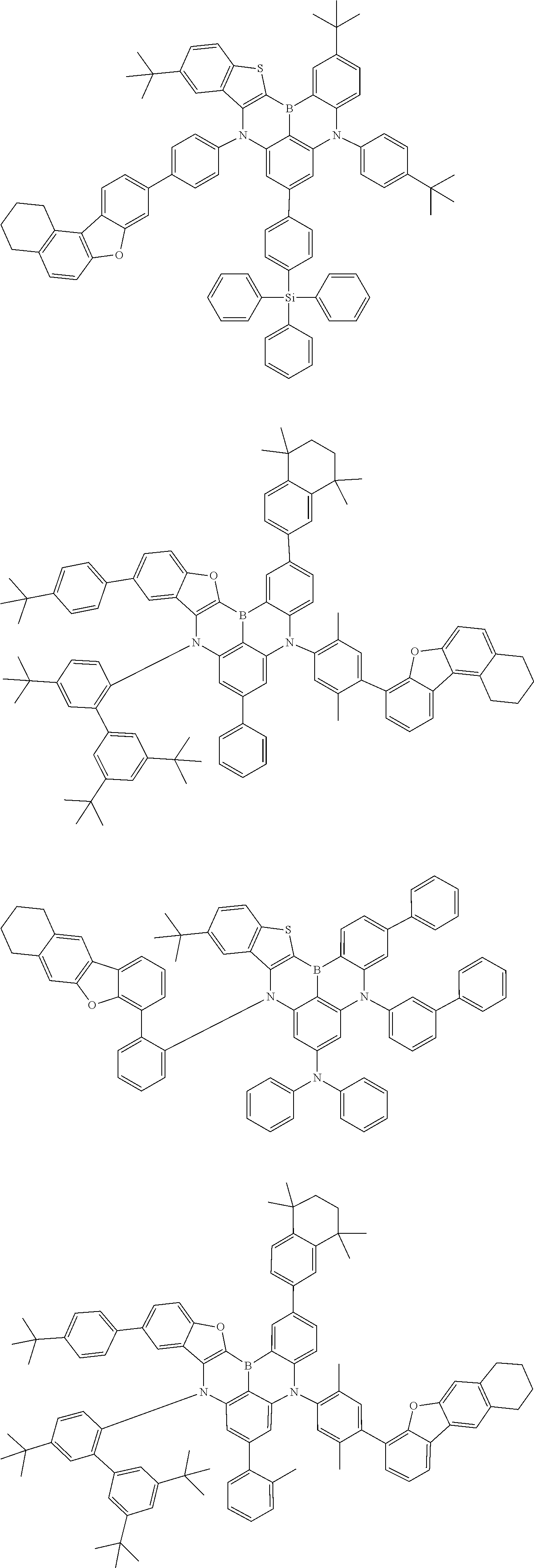

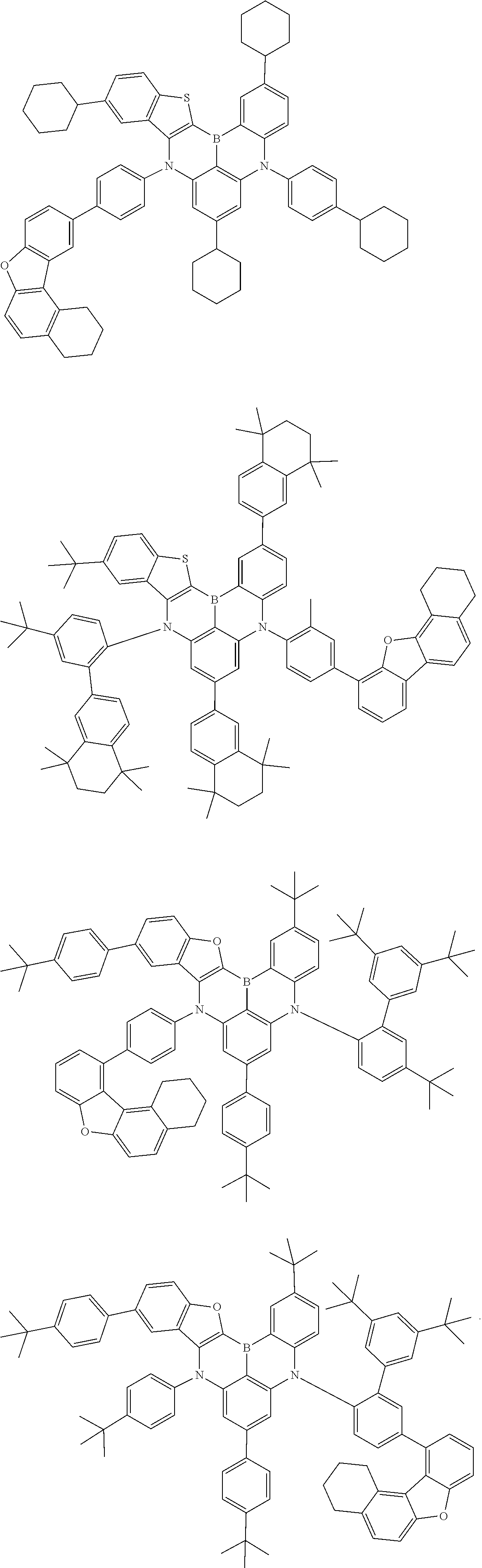

A second object of the present invention is to provide an organic electroluminescent device. The organic electroluminescent device comprises an anode, a hole transport region, a luminescent layer, an electron transport region, and a cathode, which are sequentially arranged on a substrate, wherein the luminescent layer comprises a host material and a guest material, and the guest material comprises one or more blue luminescent compounds as described above.

### Beneficial Effects of the Invention

By introducing the cyclohexyl-fused dibenzofuranyl structure into the blue luminescent compound provided by the present invention, the intermolecular distance is increased due to the action of mutual repulsion of lone-pair electrons of the oxygen atom in the cyclohexyl-fused dibenzofuranyl structure, thereby improving the fluorescence quantum yield. In addition, since the cyclohexyl-fused dibenzofuranyl is a non-planar structure, the thermal stability and rigidity of the molecule are increased, thereby indirectly reducing the problem of device performance degradation caused by heating. Therefore, using the blue luminescent compound of the present invention as a guest material for the luminescent layer in the preparation of an organic electroluminescent device is conducive to achieving more excellent luminescent performance, a higher BI value, and a longer service life.

### BRIEF DESCRIPTION OF THE DRAWINGS

FIG. 1 is a schematic structural diagram of an organic electroluminescent device of the present invention.

FIG. 2 is a PL spectrum of Synthesis Example 1.

FIG. 3 is a PL spectrum of Synthesis Example 5.

In the Brief Description of the Drawings: 1—substrate, 2—anode, 3—hole injection layer, 4—hole transport layer, 5—electron barrier layer, 6—luminescent layer, 7—hole barrier layer, 8—electron transport layer, 9—electron injection layer, 10—cathode, and 11—cover layer.

### DETAILED DESCRIPTION OF EMBODIMENTS

In order to understand the content of the present invention more clearly, the present invention will be described in detail in conjunction with the accompanying drawings and examples.

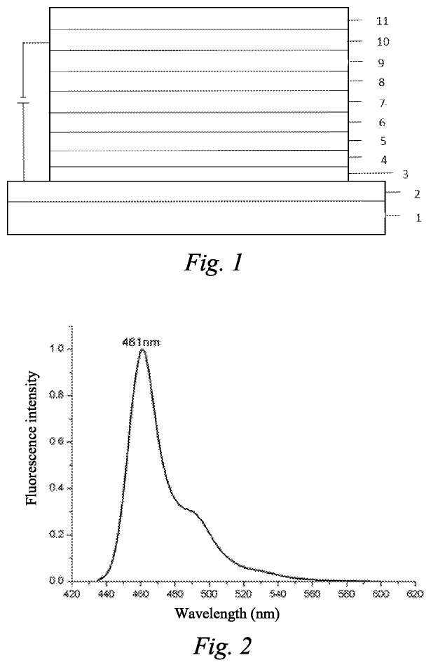

The organic compound of the present invention is suitable for light-emitting elements, display panels, and electronic devices, especially for organic electroluminescent devices. The electronic device described in the present invention is a device comprising a layer of at least one organic compound, and the device may also comprise an inorganic material or a layer formed entirely of an inorganic material. The electronic device is preferably an organic electroluminescent device (OLED). The schematic structural diagram of an exemplary organic electroluminescent device is as shown in FIG. 1.

### EXPERIMENTAL PART

In order to understand the content of the present invention more clearly, the organic compound, the preparation method for the organic compound, and the luminescent characteristics of the device will be explained in detail in conjunction with examples. Various chemical reactions can be applied to the synthesis method for a compound according to one embodiment of the present invention. However, it should be noted that the synthesis method for the compound according to one embodiment of the present invention is not limited to the synthesis method described below. Unless otherwise specified, the subsequent synthesis is carried out in an anhydrous solvent in a protective gas atmosphere. Solvents and reagents can be purchased from conventional reagent suppliers.

### Synthesis of Compounds

### Intermediate Synthesis 1

This example provided Intermediate compound P-10, and the synthesis route for the compound was as follows:

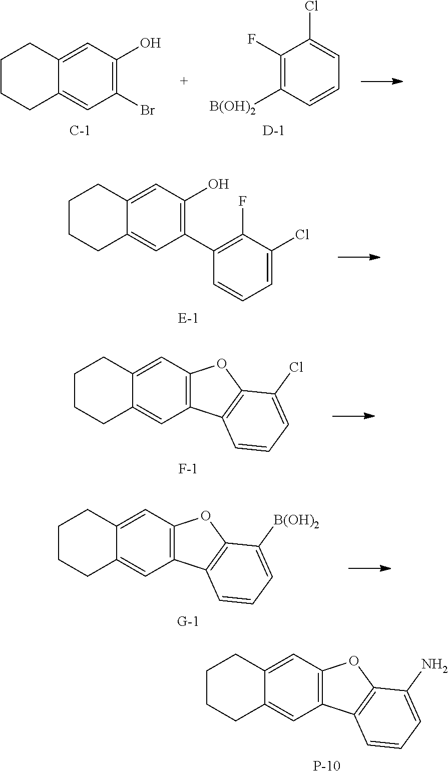

Compound C-1 (50.0 g, 220 mmol), D-1 (38.4 g, 220 mmol), tetrakis(triphenylphosphine)palladium (2.54 g, 2.20 mmol), potassium carbonate (60.72 g, 440 mmol), 1,4-dioxane (400 mL), and deionized water (100 mL) were added to a round-bottom flask having undergone nitrogen displacement, heated to 90° C. under stirring condition, and maintained for 4 h. Subsequently, the reaction mixture was cooled to room temperature, and deionized water (100 mL) and ethyl acetate (500 ml) were added and stirred for 20 min. An organic phase was separated. The organic phase was dried over anhydrous magnesium sulfate. The solvent was removed under reduced pressure to obtain a crude product. The crude product was purified by silica gel column chromatography (dichloromethane/n-heptane as a mobile phase) to obtain 43.16 g of Intermediate E-1, with a yield of 80%, MS (m/z) (M+): 277.

Intermediate E-1 (40 g, 145 mmol), potassium carbonate (60 g, 435 mmol), and N-methylpyrrolidone (300 mL) were added to a round-bottom flask which had been dried and undergone nitrogen displacement and stirred at 160° C. under nitrogen protection for 2 h. The solvent was removed under reduced pressure to obtain a crude product. The crude product was boiled and washed with deionized water and ethanol, dried, and then purified by silica gel column chromatography (dichloromethane/n-heptane as a mobile phase) to obtain 29.8 g of Intermediate F-1, with a yield of 75%, MS (m/z) (M+): 257.

Intermediate F-1 (29.8 g, 116 mmol), trimethyl borate (12 g, 116 mmol), and tetrahydrofuran (300 mL) were added to a round-bottom flask having undergone nitrogen displacement. Under nitrogen protection, tert-butyllithium (92.8 mL, 232 mmol) was added dropwise at −50° C. The dropwise addition was completed within 2 h. The mixture was maintained at this temperature for 3 h. 40 mL of a hydrochloric acid solution having a concentration of 5% was then added. Stirring was continued for 2 h. Tetrahydrofuran was distilled off under reduced pressure. The temperature was lowered to 10° C. Solid precipitation occurred. After suction filtration and drying, 27.3 g of Intermediate G-1 was obtained, with a yield of 88%, MS (m/z) (M+): 267.

Intermediate G-1 (27.3 g, 102 mmol), hydroxylamine sulfonic acid (31.74 g, 306 mmol), and sodium hydroxide (6.12 g, 153 mmol) were added to a round-bottom flask having undergone nitrogen displacement. 300 mL of a mixed solvent of acetonitrile and water (the volume of acetonitrile was 200 mL, and the volume of water was 100 mL) was added and dissolved under stirring at room temperature. After stirring at room temperature for 4 h, the reaction was complete. The filtrate was extracted twice with ethyl acetate (200 mL) and then dried over anhydrous magnesium sulfate. The solvent was removed under reduced pressure. After drying, purification by silica gel column chromatography (dichloromethane/n-heptane as a mobile phase) afforded 14.8 g of Intermediate P-10, with a yield of 61%, MS (m/z) (M+): 238.

### Intermediate Synthesis 2

This example provided Intermediate compound P-11, and the synthesis route for the compound was as follows:

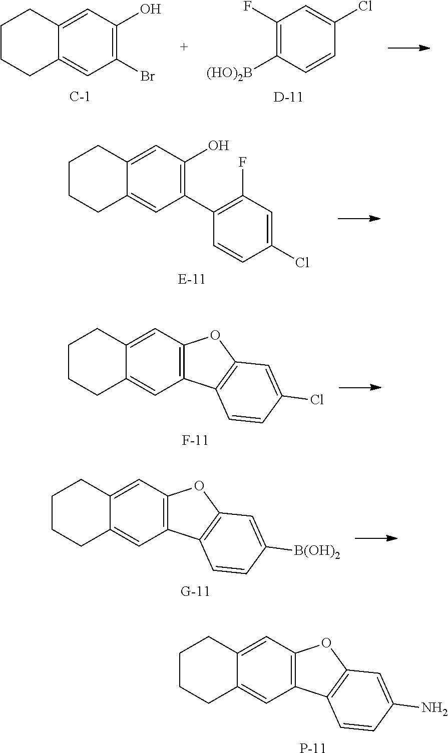

Referring to the synthesis method for E-1, Raw material D-1 was replaced by D-11 (38.4 g, 220 mmol) to obtain 41.94 g of Intermediate E-11, with a yield of 69%, MS (m/z) (M+): 277.

Referring to the synthesis method for F-1, Raw material E-1 was replaced by E-11 (40 g, 145 mmol) to obtain 26.2 g of Intermediate F-11, with a yield of 70.3%, MS (m/z) (M+): 257.

Referring to the synthesis method for G-1, Raw material F-1 was replaced by F-11 (25 g, 97.3 mmol) to obtain 24 g of Intermediate G-11, with a yield of 93%, MS (m/z) (M+): 267.

Referring to the synthesis method for P-10, Raw material G-1 was replaced by G-11 (24 g, 90.2 mmol) to obtain 14.9 g of Intermediate P-11, with a yield of 70%, MS (m/z) (M+): 238.

### Intermediate Synthesis 3

This example provided Intermediate compound P-12, and the synthesis route for the compound was as follows:

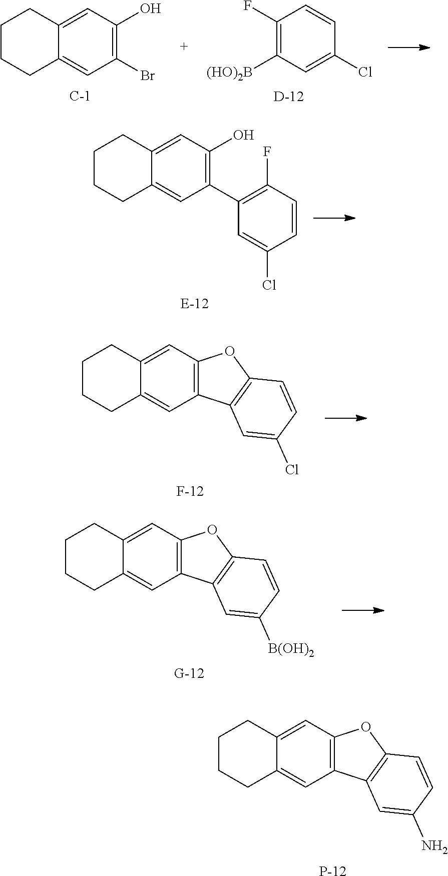

Referring to the synthesis method for E-1, Raw material D-1 was replaced by D-12 (38.4 g, 220 mmol) to obtain 43.7 g of Intermediate E-12, with a yield of 72%, MS (m/z) (M+): 277.

Referring to the synthesis method for F-1, Raw material E-1 was replaced by E-12 (40 g, 145 mmol) to obtain 28 g of Intermediate F-12, with a yield of 25 g and a yield of 67.1%, MS (m/z) (M+): 257.

Referring to the synthesis method for G-1, Raw material F-1 was replaced by F-12 (25 g, 97.3 mmol) to obtain 22.6 g of Intermediate G-12, with a yield of 87%, MS (m/z) (M+): 267.

Referring to the synthesis method for P-10, Raw material G-1 was replaced by G-12 (20 g, 75.18 mmol) to obtain 12.83 g of Intermediate P-12, with a yield of 72%, MS (m/z) (M+): 238.

### Intermediate Synthesis 4

This example provided Intermediate compound P-13, and the synthesis route for the compound was as follows:

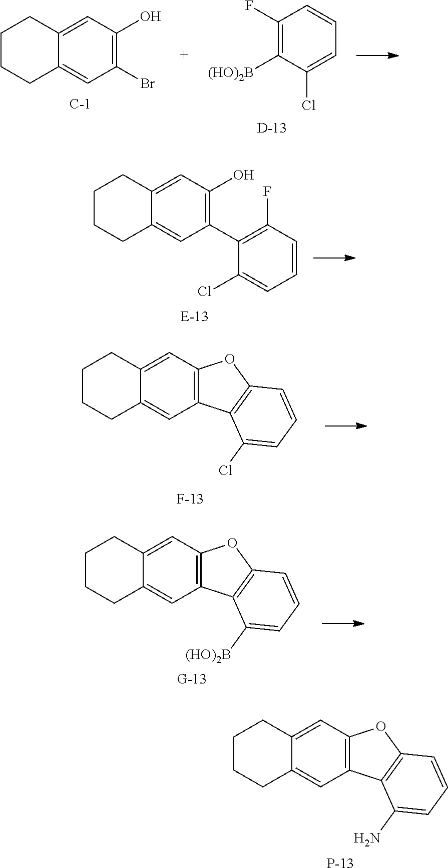

Referring to the synthesis method for E-1, Raw material D-1 was replaced by D-13 (38.4 g, 220 mmol) to obtain 30 g of Intermediate E-13, with a yield of 49.35%, MS (m/z) (M+): 277.

Referring to the synthesis method for F-1, Raw material E-1 was replaced by E-13 (30 g, 108.7 mmol) to obtain 20 g of Intermediate F-13, with a yield of 71.6%, MS (m/z) (M+): 257.

Referring to the synthesis method for G-1, Raw material F-1 was replaced by F-13 (20 g, 77.8 mmol) to obtain 17.5 g of Intermediate G-13, with a yield of 84.2%, MS (m/z) (M+): 267.

Referring to the synthesis method for P-10, Raw material G-1 was replaced by G-13 (17.5 g, 65.78 mmol) to obtain 12.3 g of Intermediate P-13, with a yield of 79%, MS (m/z) (M+): 238.

### Intermediate Synthesis 5

This example provided Intermediate compound P-14, and the synthesis route for the compound was as follows:

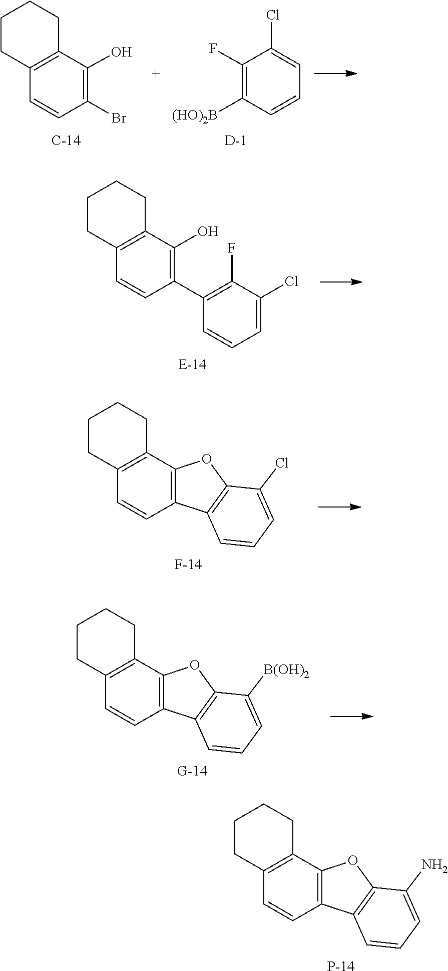

Referring to the synthesis method for E-1, Raw material C-1 was replaced by C-14 (40.0 g, 176 mmol) to obtain 27.6 g of Intermediate E-14, with a yield of 56.8%, MS (m/z) (M+): 277.

Referring to the synthesis method for F-1, Raw material E-1 was replaced by E-14 (25 g, 90.57 mmol) to obtain 19.9 g of Intermediate F-14, with a yield of 85.4%, MS (m/z) (M+): 257.

Referring to the synthesis method for G-1, Raw material F-1 was replaced by F-14 (17 g, 66.1 mmol) to obtain 16.2 g of Intermediate G-14, with a yield of 92%, MS (m/z) (M+): 267.

Referring to the synthesis method for P-10, Raw material G-1 was replaced by G-14 (15 g, 56.39 mmol) to obtain 8.9 g of Intermediate P-14, with a yield of 67%, MS (m/z) (M+): 238.

### Intermediate Synthesis 6

This example provided Intermediate compound P-15, and the synthesis route for the compound was as follows:

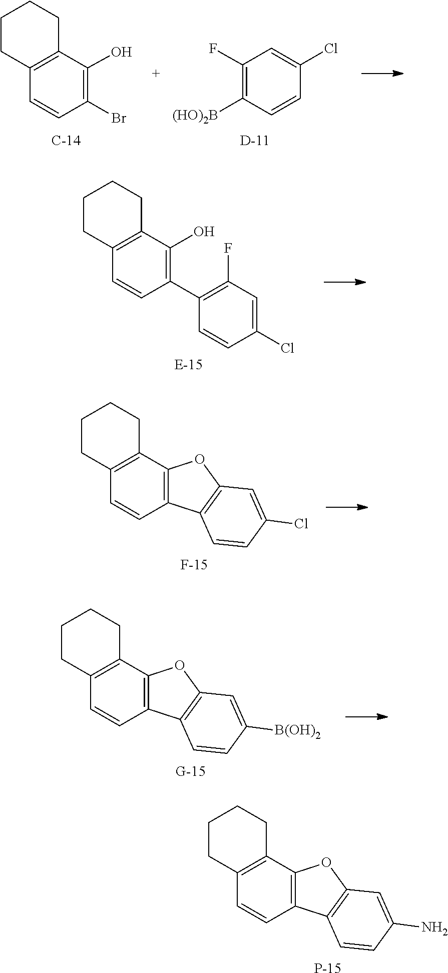

Referring to the synthesis method for E-1, Raw material C-1 was replaced by C-14 (50.0 g, 220 mmol), and D-1 was replaced by D-11 (38.4 g, 220 mmol) to obtain 39.5 g of Intermediate E-15, with a yield of 65%, MS (m/z) (M+): 277.

Referring to the synthesis method for F-1, Raw material E-1 was replaced by E-15 (39.5 g, 143 mmol) to obtain 29.7 g of Intermediate F-15, with a yield of 81%, MS (m/z) (M+): 257.

Referring to the synthesis method for G-1, Raw material F-1 was replaced by F-15 (29.7 g, 115.6 mmol) to obtain 27.3 g of Intermediate G-15, with a yield of 88.5%, MS (m/z) (M+): 267.

Referring to the synthesis method for P-10, Raw material G-1 was replaced by G-15 (27.3 g, 102.6 mmol) to obtain 17.2 g of Intermediate P-15, with a yield of 71%, MS (m/z) (M+): 238.

### Intermediate Synthesis 7

This example provided Intermediate compound P-16, and the synthesis route for the compound was as follows:

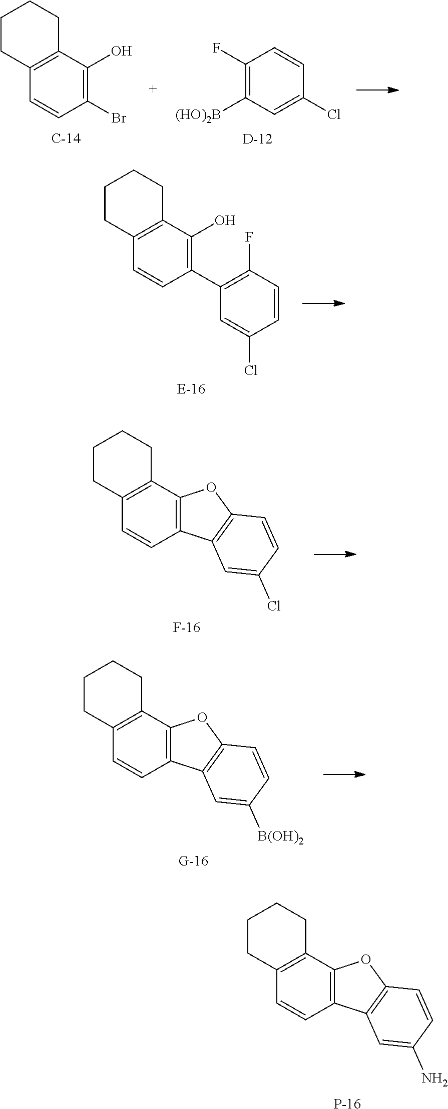

Referring to the synthesis method for E-1, Raw material C-1 was replaced by C-14 (50.0 g, 220 mmol), and D-1 was replaced by D-12 (38.4 g, 220 mmol) to obtain 40.0 g of Intermediate E-16, with a yield of 66%, MS (m/z) (M+): 277.

Referring to the synthesis method for F-1, Raw material E-1 was replaced by E-16 (35 g, 126.8 mmol) to obtain 26.8 g of Intermediate F-16, with a yield of 82.2%, MS (m/z) (M+): 257.

Referring to the synthesis method for G-1, Raw material F-1 was replaced by F-16 (26.8 g, 104.3 mmol) to obtain 22.8 g of Intermediate G-16, with a yield of 81.9%, MS (m/z) (M+): 267.

Referring to the synthesis method for P-10, Raw material G-1 was replaced by G-16 (22.8 g, 85.7 mmol) to obtain 14.6 g of Intermediate P-16, with a yield of 72%, MS (m/z) (M+): 238.

### Intermediate Synthesis 8

This example provided Intermediate compound P-17, and the synthesis route for the compound was as follows:

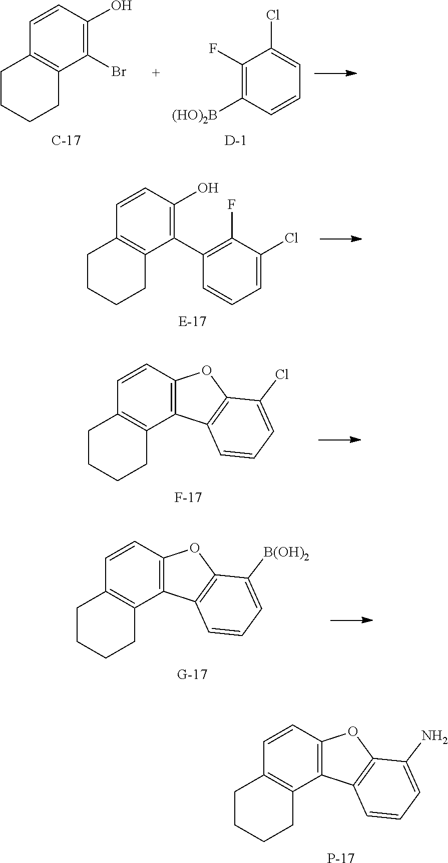

Referring to the synthesis method for E-1, Raw material C-1 was replaced by C-17 (50.0 g, 220 mmol) to obtain 44 g of Intermediate E-17, with a yield of 72%, MS (m/z) (M+): 277.

Referring to the synthesis method for F-1, Raw material E-1 was replaced by E-17 (40 g, 145 mmol) to obtain 30.5 g of Intermediate F-17, with a yield of 82%, MS (m/z) (M+): 257.

Referring to the synthesis method for G-1, Raw material F-1 was replaced by F-17 (30 g, 116.7 mmol) to obtain 25.5 g of Intermediate G-17, with a yield of 81.8%, MS (m/z) (M+): 267.

Referring to the synthesis method for P-10, Raw material G-1 was replaced by G-17 (25 g, 94 mmol) to obtain 17.1 g of Intermediate P-17, with a yield of 77%, MS (m/z) (M+): 238.

### Intermediate Synthesis 9

This example provided Intermediate compound P-18, and the synthesis route for the compound was as follows:

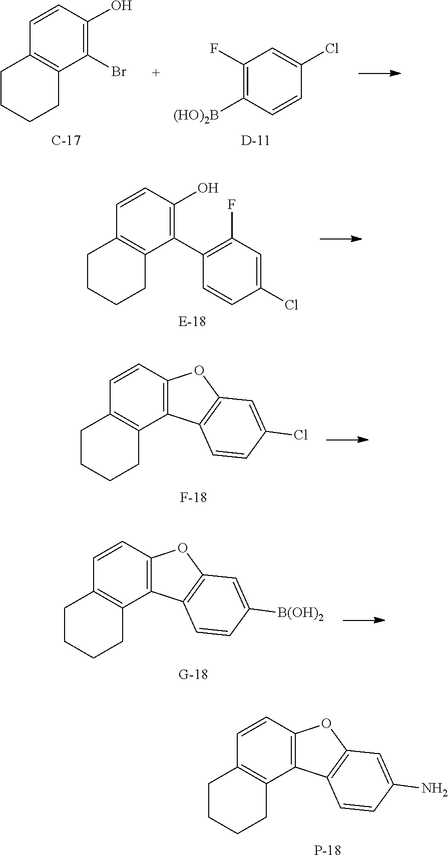

Referring to the synthesis method for E-1, Raw material C-1 was replaced by C-17 (50.0 g, 220 mmol), and D-1 was replaced by D-11 (38.4 g, 220 mmol) to obtain 46 g of Intermediate E-18, with a yield of 76%, MS (m/z) (M+): 277.

Referring to the synthesis method for F-1, Raw material E-1 was replaced by E-18 (40 g, 145 mmol) to obtain 32.8 g of Intermediate F-18, with a yield of 88%, MS (m/z) (M+): 257.

Referring to the synthesis method for G-1, Raw material F-1 was replaced by F-18 (30 g, 116.7 mmol) to obtain 24.6 g of Intermediate G-18, with a yield of 79%, MS (m/z) (M+): 267.

Referring to the synthesis method for P-10, Raw material G-1 was replaced by G-18 (20 g, 75.18 mmol) to obtain 15 g of Intermediate P-18, with a yield of 84%, MS (m/z) (M+): 238.

### Intermediate Synthesis 10

This example provided Intermediate compound P-19, and the synthesis route for the compound was as follows:

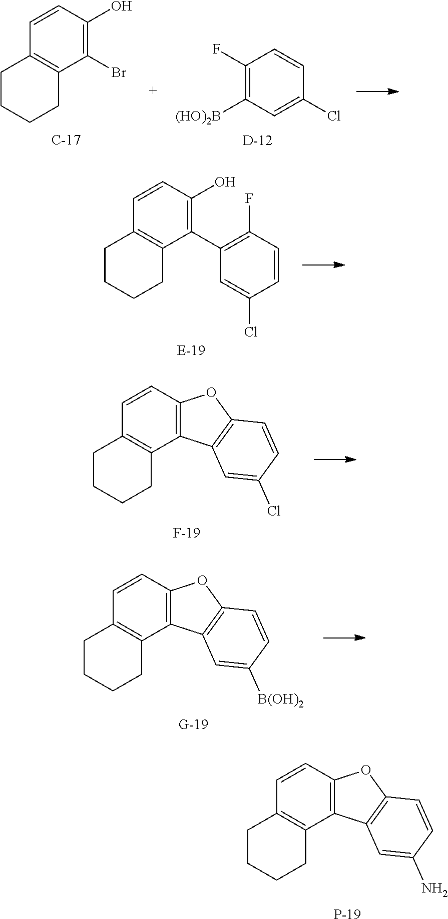

Referring to the synthesis method for E-1, Raw material C-1 was replaced by C-17 (50.0 g, 220 mmol), and D-1 was replaced by D-12 (38.4 g, 220 mmol) to obtain 47.4 g of Intermediate E-19, with a yield of 78%, MS (m/z) (M+): 277.

Referring to the synthesis method for F-1, Raw material E-1 was replaced by E-19 (40 g, 145 mmol) to obtain 32.6 g of Intermediate F-19, with a yield of 87.5%, MS (m/z) (M+): 257.

Referring to the synthesis method for G-1, Raw material F-1 was replaced by F-19 (30 g, 116.7 mmol) to obtain 23 g of Intermediate G-19, with a yield of 73.8%, MS (m/z) (M+): 267.

Referring to the synthesis method for P-10, Raw material G-1 was replaced by G-19 (20 g, 75.18 mmol) to obtain 16 g of Intermediate P-19, with a yield of 89.8%, MS (m/z) (M+): 238.

### Intermediate Synthesis 11

This example provided Intermediate compound P-20, and the synthesis route for the compound was as follows:

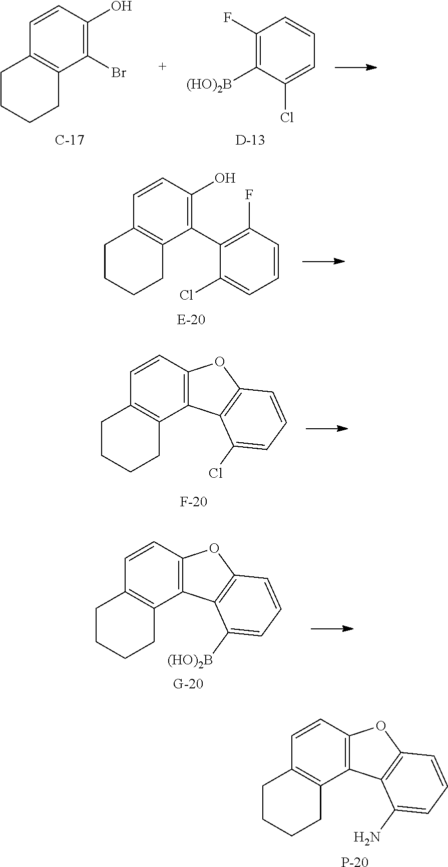

Referring to the synthesis method for E-1, Raw material C-1 was replaced by C-17 (50.0 g, 220 mmol), and D-1 was replaced by D-13 (38.4 g, 220 mmol) to obtain 45 g of Intermediate E-20, with a yield of 74%, MS (m/z) (M+): 277.

Referring to the synthesis method for F-1, Raw material E-1 was replaced by E-20 (40 g, 145 mmol) to obtain 33.5 g of Intermediate F-20, with a yield of 90%, MS (m/z) (M+): 257.

Referring to the synthesis method for G-1, Raw material F-1 was replaced by F-20 (30 g, 116.7 mmol) to obtain 24.5 g of Intermediate G-20, with a yield of 79%, MS (m/z) (M+): 267.

Referring to the synthesis method for P-10, Raw material G-1 was replaced by G-20 (20 g, 75.18 mmol) to obtain 13 g of Intermediate P-20, with a yield of 73%, MS (m/z) (M+): 238.

### Intermediate Synthesis 12

The synthesis route for Intermediate A1 was as follows:

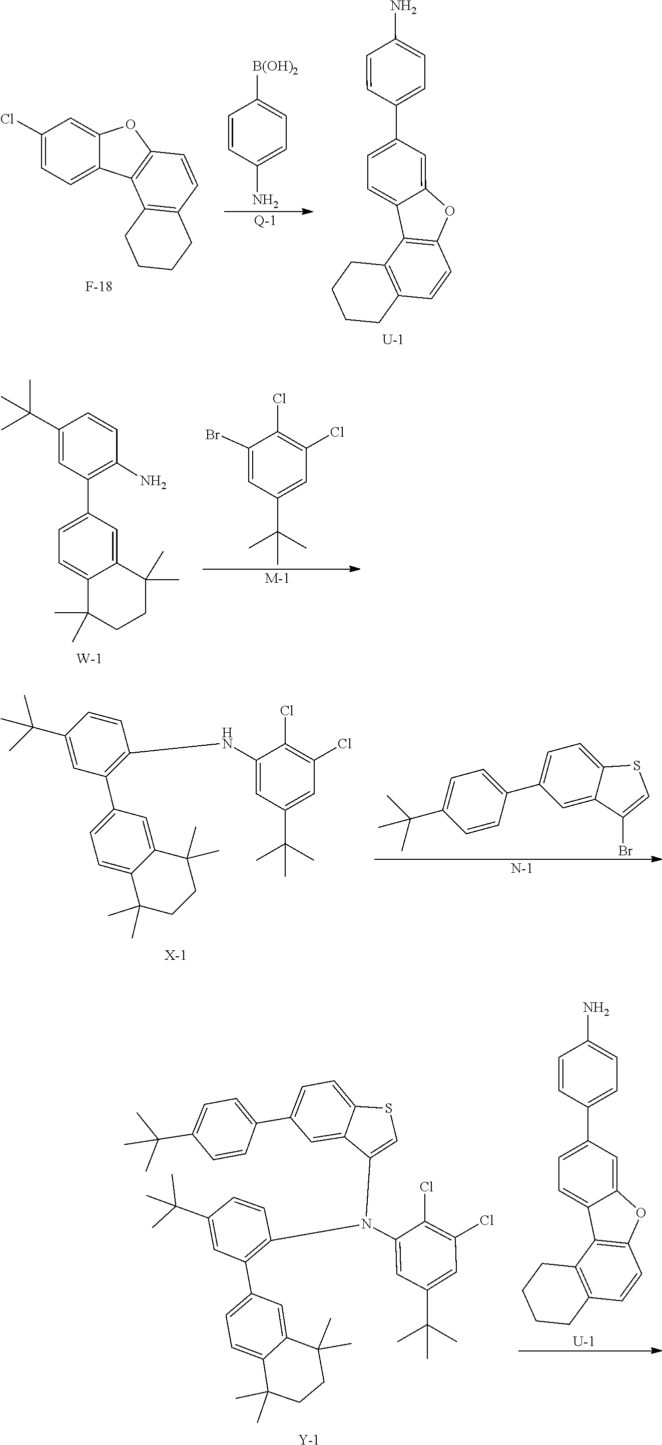

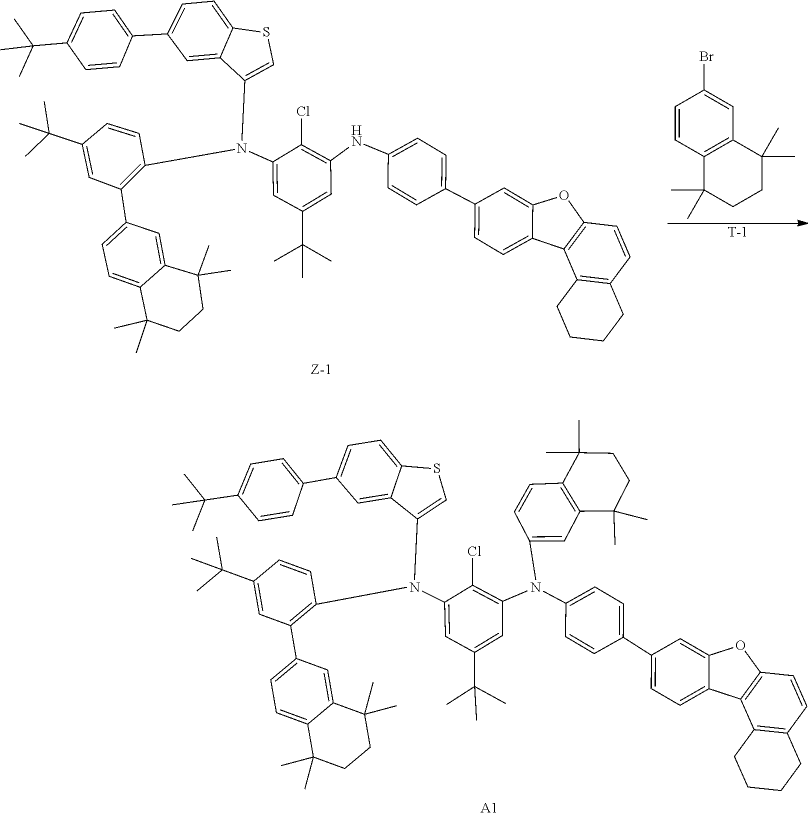

Compound F-18 (25.6 g, 100 mmol), Q-1 (13.7 g, 100 mmol), and potassium carbonate (41.4 g, 300 mmol) were added to a mixed solution of 1,4-dioxane (400 mL) and water (100 mL). Then, Pd-132 (0.07 g, 0.1 mmol) was added under nitrogen protection. Subsequently, the reaction system was heated to 100° C., and the reaction was maintained under heating for 3 h. After cooling to room temperature, deionized water was added for quenching. After liquid separation, the organic phase was dried over anhydrous sodium sulfate, and the solvent was removed by rotary evaporation. The crude product was purified by column chromatography to obtain 25.6 g of Product U-1, with a yield of 82%, MS (m/z) (M+): 313.

Compound W-1 (36.8 g, 110 mmol), M-1 (29.5 g, 100 mmol), and sodium tert-butoxide (28.8 g, 300 mmol) were added to toluene (400 mL). Then, under nitrogen protection, bis(dibenzylideneacetone) palladium (0.92 g, 1 mmol) and Xantphos (1.15 g, 2 mmol) were added. Subsequently, the reaction system was heated to 100° C., refluxed, and maintained for 4 h. After cooling to room temperature, deionized water was added for quenching. After liquid separation, the organic phase was dried over anhydrous sodium sulfate, and the solvent was removed by rotary evaporation. The crude product was purified by column chromatography to obtain 46 g of Product X-1, with a yield of 86%, MS (m/z) (M+): 536.

Compound X-1 (46 g, 85.8 mmol), N-1 (44.2 g, 128.7 mmol), and sodium tert-butoxide (24.7 g, 257.4 mmol) were added to toluene (500 mL). Then, under nitrogen protection, bis(dibenzylideneacetone) palladium (1.18 g, 1.29 mmol) and tri-tert-butylphosphine (0.52 g, 2.58 mmol) were added. Subsequently, the reaction system was heated to 110° C., refluxed, and maintained for 6 h. After cooling to room temperature, deionized water was added for quenching. After liquid separation, the organic phase was dried over anhydrous sodium sulfate, and the solvent was removed by rotary evaporation. The crude product was purified by column chromatography to obtain 47.3 g of Product Y-1, with a yield of 69%, MS (m/z) (M+): 799.

Compound Y-1 (47.3 g, 59.2 mmol), U-1 (20.4 g, 65.1 mmol), and sodium tert-butoxide (11.3 g, 118.4 mmol) were added to toluene (500 mL). Then, under nitrogen protection, bis(dibenzylideneacetone) palladium (0.81 g, 0.89 mmol) and Sphos (0.80 g, 1.78 mmol) were added. Subsequently, the reaction system was heated to 110° C., refluxed, and maintained for 2 h. After cooling to room temperature, deionized water was added for quenching. After liquid separation, the organic phase was dried over anhydrous sodium sulfate, and the solvent was removed by rotary evaporation. The crude product was purified by column chromatography to obtain 46.7 g of Product Z-1, with a yield of 77%, MS (m/z) (M+): 1026.

Compound Z-1 (46.7 g, 45.6 mmol), T-1 (12.1 g, 45.6 mmol), and sodium tert-butoxide (10.9 g, 114 mmol) were added to toluene (500 mL). Then, under nitrogen protection, bis(dibenzylideneacetone) palladium (0.85 g, 0.93 mmol) and Xantphos (1.07 g, 1.86 mmol) were added. Subsequently, the reaction system was heated to 100° C., refluxed, and maintained for 6 h. After cooling to room temperature, deionized water was added for quenching. After liquid separation, the organic phase was dried over anhydrous sodium sulfate, and the solvent was removed by rotary evaporation. The crude product was purified by column chromatography to obtain 35.1 g of Product A1, with a yield of 61%, MS (m/z) (M+): 1263.

### Intermediate Synthesis 13

The synthesis route for Intermediate A2 was as follows:

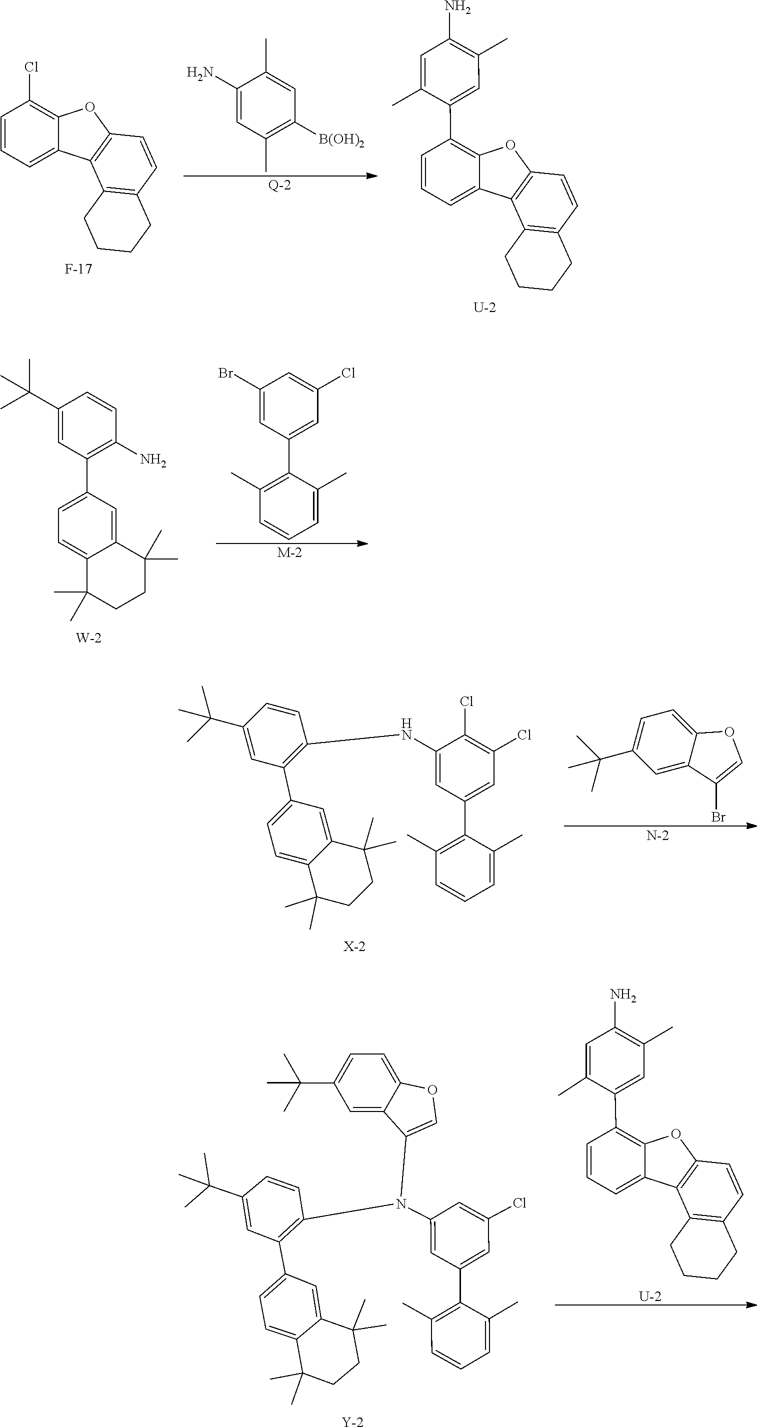

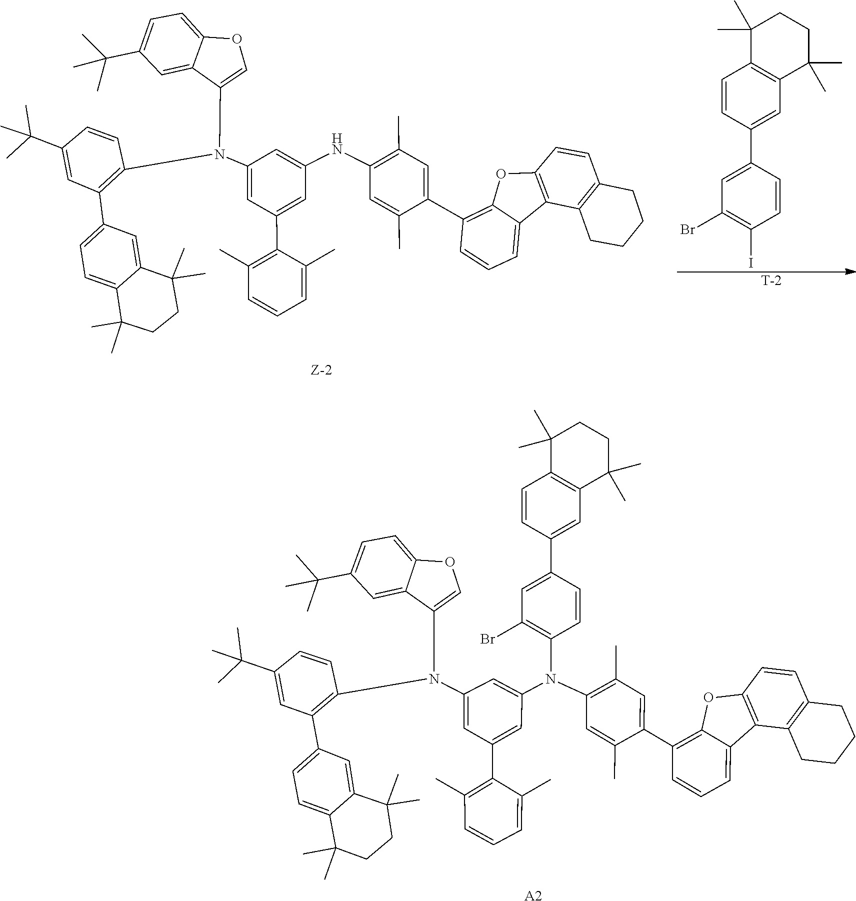

Referring to the synthesis method for U-1, Raw material F-18 was replaced by F-17 (25.6 g, 100 mmol), and Q-1 was replaced by Q-2 (16.5 g, 100 mmol) to obtain 28.3 g of Intermediate U-2, with a yield of 82%, MS (m/z) (M+): 341.

Referring to the synthesis method for X-1, Raw material W-1 was replaced by W-2 (36.8 g, 110 mmol), and M-1 was replaced by M-2 (29.4 g, 100 mmol) to obtain 46 g of Intermediate X-2, with a yield of 79%, MS (m/z) (M+): 583.

Referring to the synthesis method for Y-1, Raw material X-1 was replaced by X-2 (46 g, 78.9 mmol), and N-1 was replaced by N-2 (29.8 g, 118.3 mmol) to obtain 37.5 g of Intermediate Y-2, with a yield of 66%, MS (m/z) (M+): 721.

Referring to the synthesis method for Z-2, Raw material Y-1 was replaced by Y-2 (37.5 g, 52 mmol), and U-1 was replaced by U-2 (26.6 g, 78 mmol) to obtain 32 g of Intermediate Z-2, with a yield of 83%, MS (m/z) (M+): 1027.

Referring to the synthesis method for A1, Raw material Z-1 was replaced by Z-2 (32 g, 31.2 mmol), and T-1 was replaced by T-2 (14.6 g, 31.2 mmol) to obtain 20.6 g of Intermediate A2, with a yield of 72%, MS (m/z) (M+): 1354.

After A1 and A2 were obtained by the above process, other intermediates could be readily obtained by a preparation method analogous to that for A1 or A2.

### BD SYNTHESIS EXAMPLES

### Synthesis Example 1

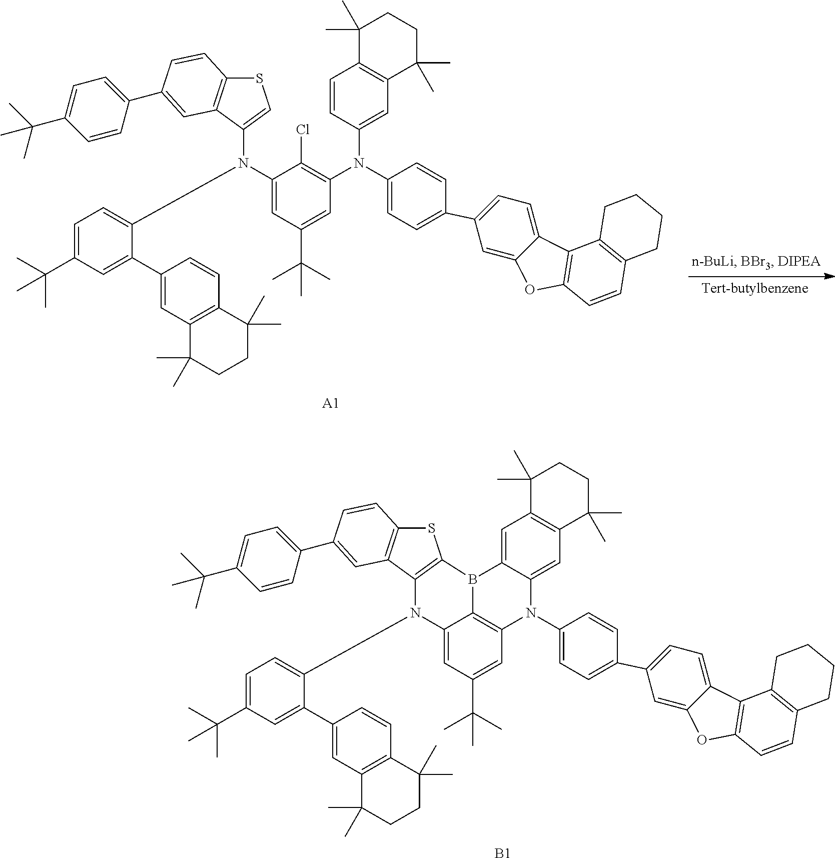 [SMILES: CC(C)(C)c1ccc(-c2ccc3scc(N(c4ccc(C(C)(C)C)cc4-c4ccc5c(c4)C(C)(C)CCC5(C)C)c4cc(C(C)(C)C)cc(N(c5ccc(-c6ccc7c(c6)oc6ccc8c(c67)CCCC8)cc5)c5ccc6c(c5)C(C)(C)CCC6(C)C)c4Cl)c3c2)cc1 ; "A1" ; CC(C)(C)c1ccc(-c2ccc3sc4c(c3c2)N(c2ccc(C(C)(C)C)cc2-c2ccc3c(c2)C(C)(C)CCC3(C)C)c2cc(C(C)(C)C)cc3c2B4c2cc4c(cc2N3c2ccc(-c3ccc5c(c3)oc3ccc6c(c35)CCCC6)cc2)C(C)(C)CCC4(C)C)cc1 ; "B1"]

A1 (12.63 g, 10 mmol) was added to tert-butylbenzene (125 ml). Then under nitrogen protection, the mixture was cooled to −30° C. A solution of 2.5 M tert-butyllithium in pentane (8 ml, 20 mmol) was added. The mixture was heated to 60° C., stirred for 2 hours, and then cooled to −30° C. 1.85 ml of boron tribromide (20 mmol) was added and stirred for 1 h. After further cooling to 0° C., 3.6 ml of N,N-diisopropylethylamine (20 mmol) was added. The mixture was heated to 60° C. and stirred for 2 h. After cooling to room temperature, ice water was added, followed by quenching and liquid separation. The organic phase was filtered, and water was then removed using anhydrous magnesium sulfate. After the organic solvent was removed by rotary evaporation, the crude product was purified by silica gel column chromatography (dichloromethane/n-heptane as a mobile phase) and then purified by recrystallization from dichloromethane and n-heptyl to finally obtain 0.62 g of Product B1, with a yield of 5%, MS (m/z) (M+): 1237.

Compound B1 was prepared into a solution with toluene, and then, the fluorescence intensity of the solution was measured by a fluorescence spectrophotometer to obtain a PL spectrum of Compound B1 (see FIG. 2). The results show that the PL of Compound B1 was at 461 nm, and FWHM (full width at half maximum)=22 nm.

### Synthesis Example 2

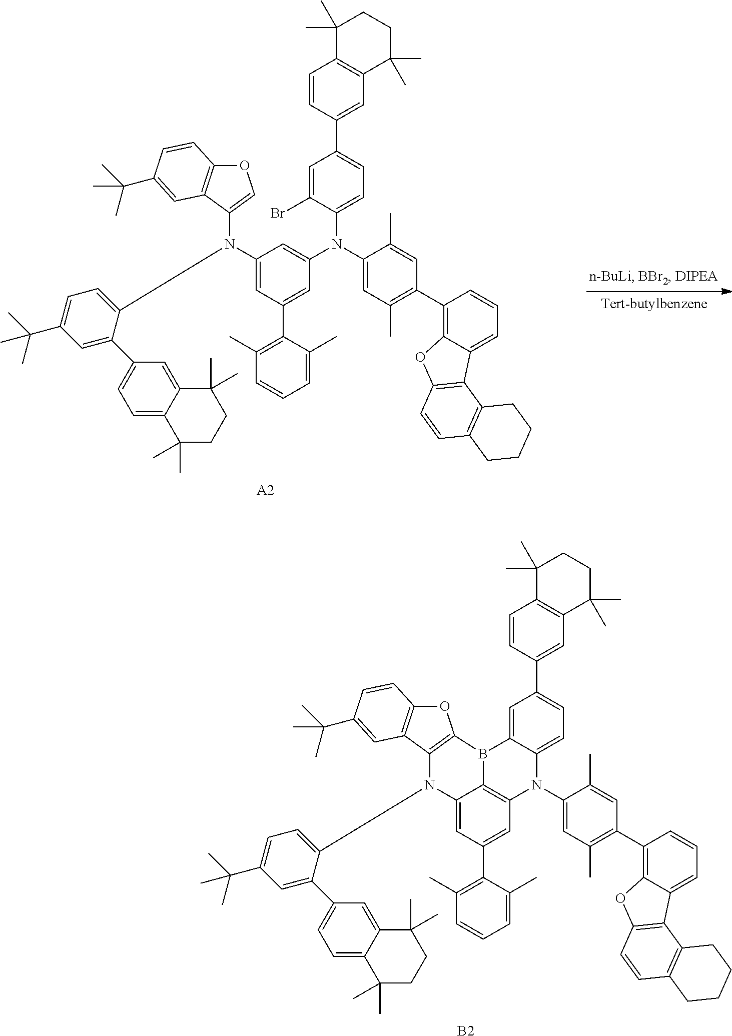 [SMILES: Cc1cc(N(c2cc(-c3c(C)cccc3C)cc(N(c3ccc(C(C)(C)C)cc3-c3ccc4c(c3)C(C)(C)CCC4(C)C)c3coc4ccc(C(C)(C)C)cc34)c2)c2ccc(-c3ccc4c(c3)C(C)(C)CCC4(C)C)cc2Br)c(C)cc1-c1cccc2c1oc1ccc3c(c12)CCCC3 ; "A2" ; Cc1cc(N2c3ccc(-c4ccc5c(c4)C(C)(C)CCC5(C)C)cc3B3c4oc5ccc(C(C)(C)C)cc5c4N(c4ccc(C(C)(C)C)cc4-c4ccc5c(c4)C(C)(C)CCC5(C)C)c4cc(-c5c(C)cccc5C)cc2c43)c(C)cc1-c1cccc2c1oc1ccc3c(c12)CCCC3 ; "B2"]

A2 (13.68 g, 10 mmol) was added to tert-butylbenzene (120 ml). Then under nitrogen protection, the mixture was cooled to −30° C. A solution of 2 M n-butyllithium in pentane (10 ml, 20 mmol) was added. The mixture was heated to 60° C., stirred for 2 hours, and then cooled to −20° C. 1.85 ml of boron tribromide (20 mmol) was added and stirred for 1 h. After further cooling to 0° C., 3.6 ml of N,N-diisopropylethylamine (20 mmol) was added. The mixture was heated to 60° C. and stirred for 2 h. After cooling to room temperature, ice water was added, followed by quenching and liquid separation. The organic phase was filtered, and water was then removed using anhydrous magnesium sulfate. After the organic solvent was removed by rotary evaporation, the crude product was purified by silica gel column chromatography (dichloromethane/n-heptane as a mobile phase) and then purified by recrystallization from dichloromethane and n-heptyl to finally obtain 0.58 g of Product B2, with a yield of 4.5%, MS (m/z) (M+): 1297.

### Synthesis Example 3

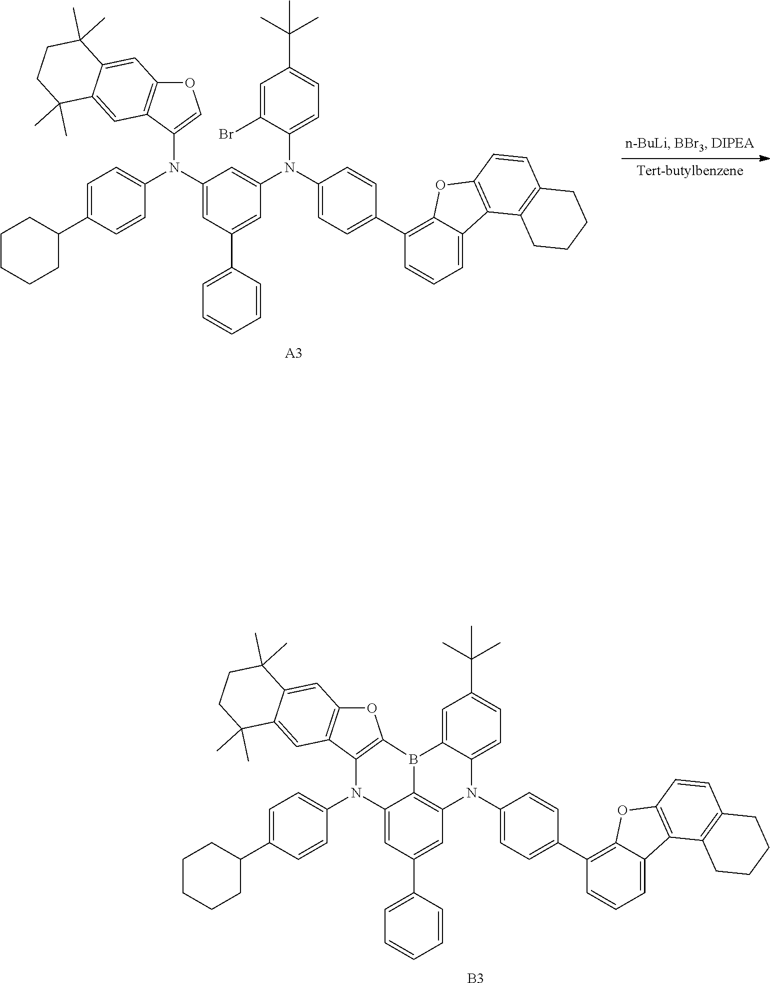

The method was the same as in Synthesis Example 2, except that A3 (10.75 g, 10 mmol) was replaced by A1 to finally obtain 0.7 g of Product B3, with a yield of 7%, MS (m/z) (M+): 1005.

### Synthesis Example 4

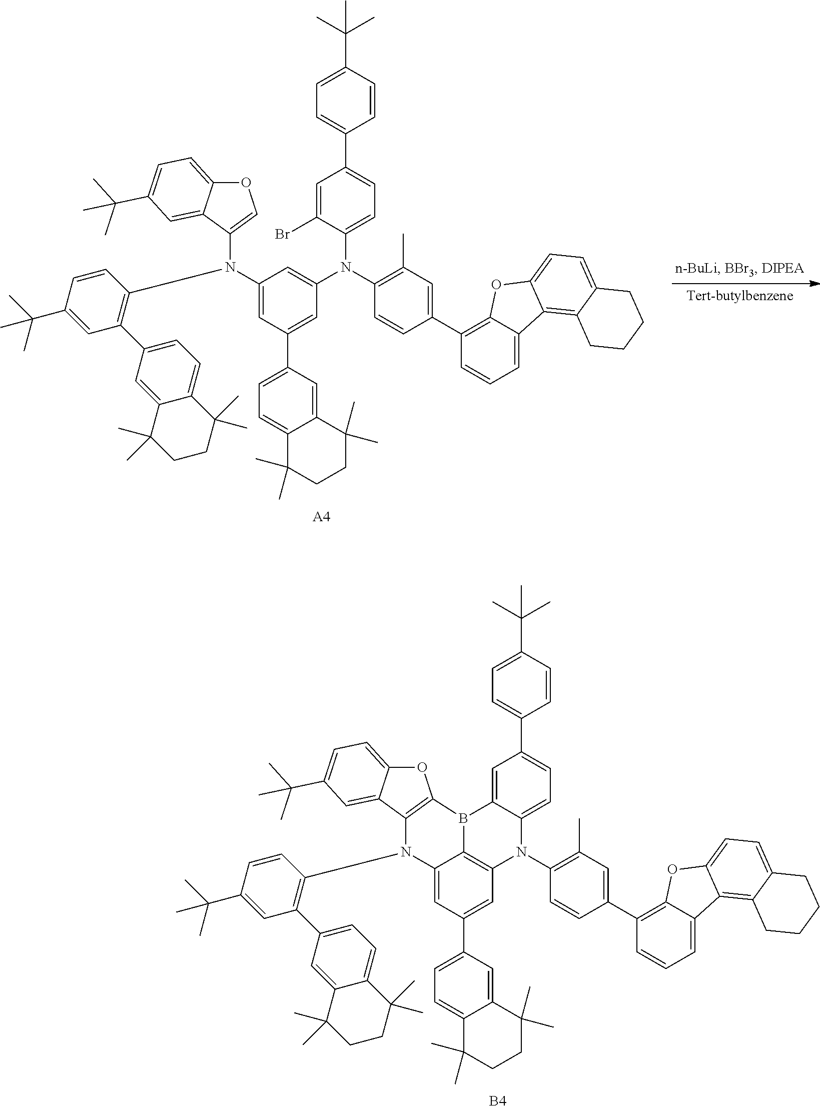

The method was the same as in Synthesis Example 2, except that A4 (13.81 g, 10 mmol) was replaced by A2 to finally obtain 0.59 g of Product B4, with a yield of 4.5%, MS (m/z) (M+): 1311.

### Synthesis Example 5

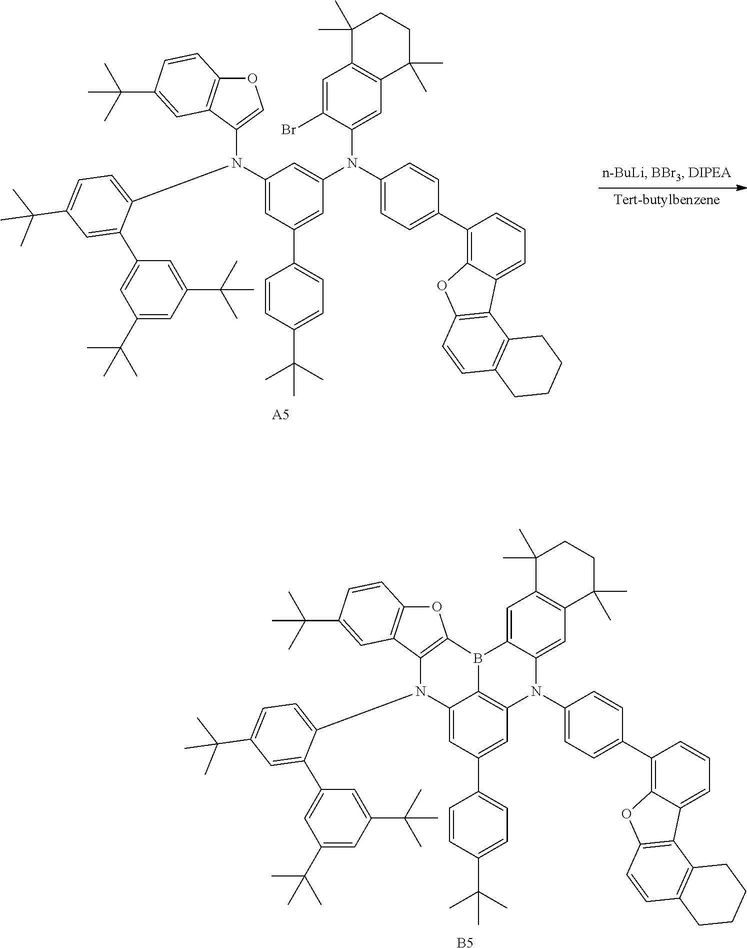

The method was the same as in Synthesis Example 2, except that A5 (13.27 g, 10 mmol) was replaced by A2 to finally obtain 0.76 g of Product B5, with a yield of 6%, MS (m/z) (M+): 1271.

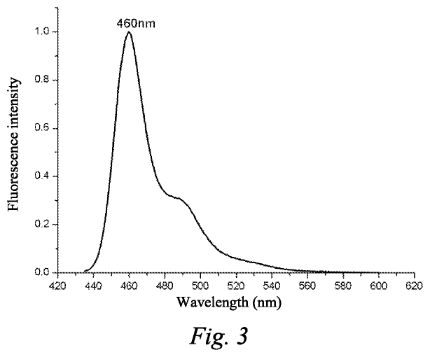

FIG. 3 shows a PL spectrum of Synthesis Example 5. The test method was the same as that for Synthesis Example 1. The test results indicate that the PL of Compound B5 is at 460 nm, and FWHM (full width at half maximum)=21 nm.

### Synthesis Example 6

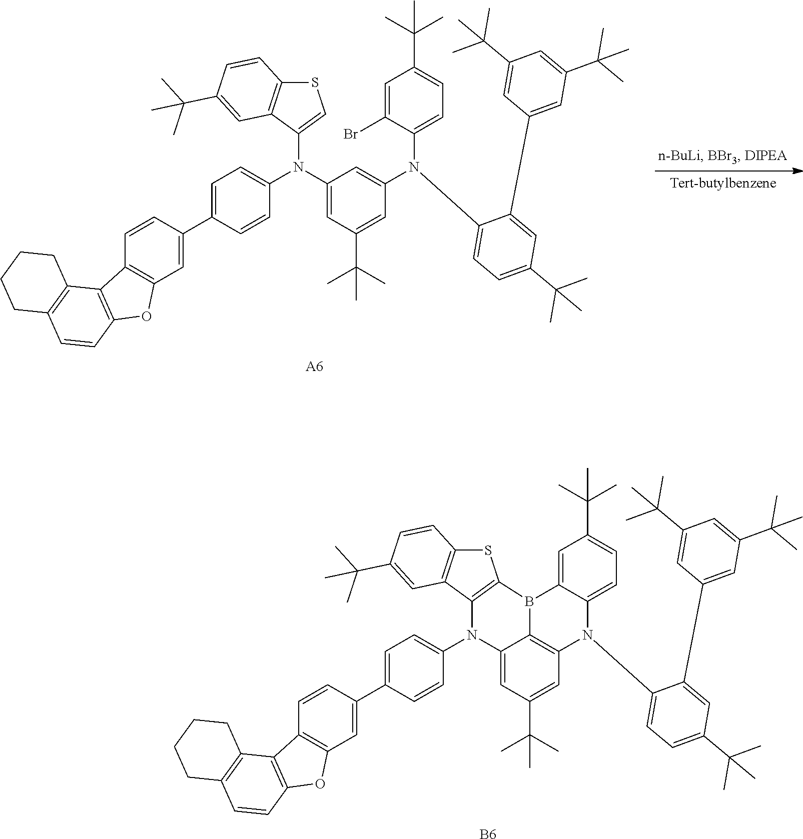 [SMILES: CC(C)(C)c1cc(N(c2ccc(C(C)(C)C)cc2Br)c2ccc(C(C)(C)C)cc2-c2cc(C(C)(C)C)cc(C(C)(C)C)c2)cc(N(c2ccc(-c3ccc4c(c3)oc3ccc5c(c34)CCCC5)cc2)c2csc3ccc(C(C)(C)C)cc23)c1 ; "A6" ; CC(C)(C)c1cc(-c2cc(C(C)(C)C)ccc2N2c3ccc(C(C)(C)C)cc3B3c4sc5ccc(C(C)(C)C)cc5c4N(c4ccc(-c5ccc6c(c5)oc5ccc7c(c56)CCCC7)cc4)c4cc(C(C)(C)C)cc2c43)cc(C(C)(C)C)c1 ; "B6"]

The method was the same as in Synthesis Example 2, except that A6 (11.79 g, 10 mmol) was replaced by A2 to finally obtain 0.61 g of Product B6, with a yield of 5.5%, MS (m/z) (M+): 1109.

### Synthesis Example 7

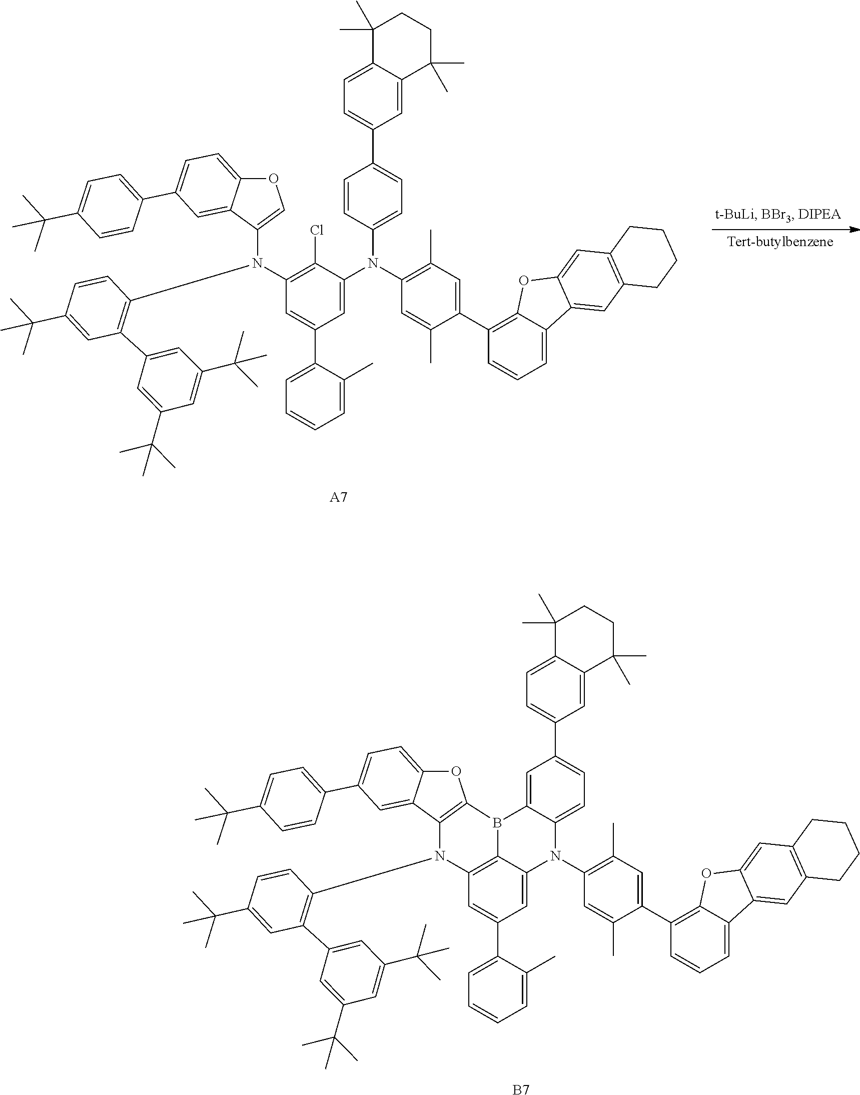

The method was the same as in Synthesis Example 1, except that A7 (13.87 g, 10 mmol) was replaced by A1 to finally obtain 1.17 g of Product B7, with a yield of 8.5%, MS (m/z) (M+): 1361.

### Synthesis Example 8

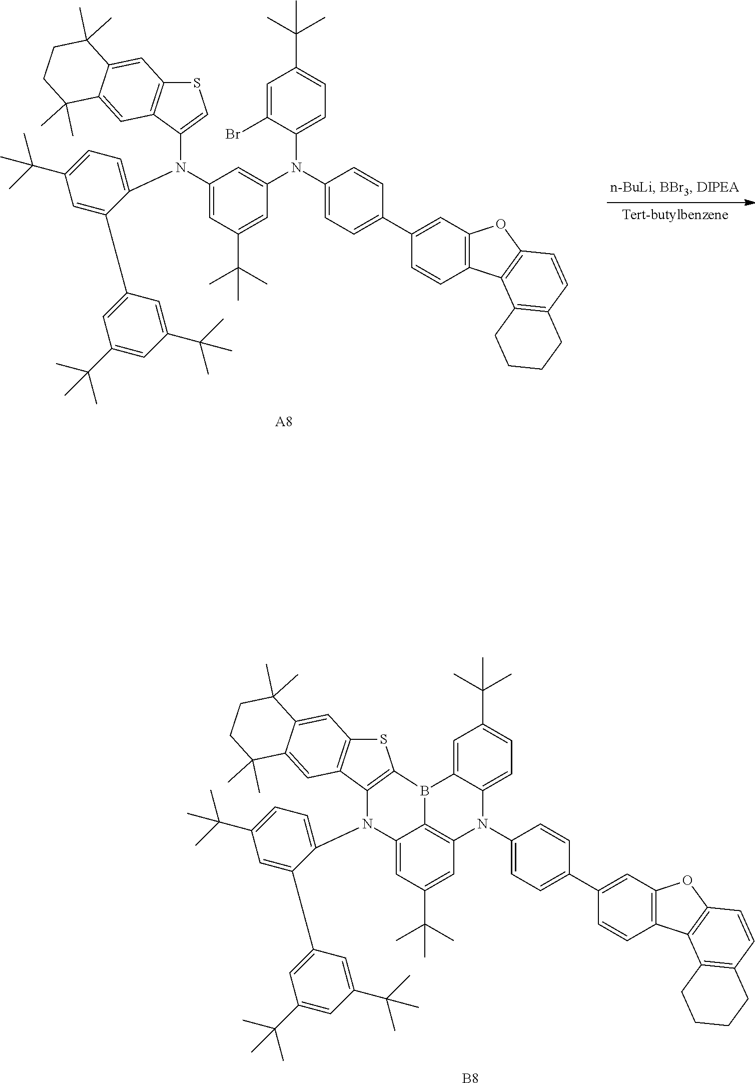

The method was the same as in Synthesis Example 2, except that A8 (12.33 g, 10 mmol) was replaced by A2 to finally obtain 0.46 g of Product B8, with a yield of 4%, MS (m/z) (M+): 1163.

### Synthesis Example 9

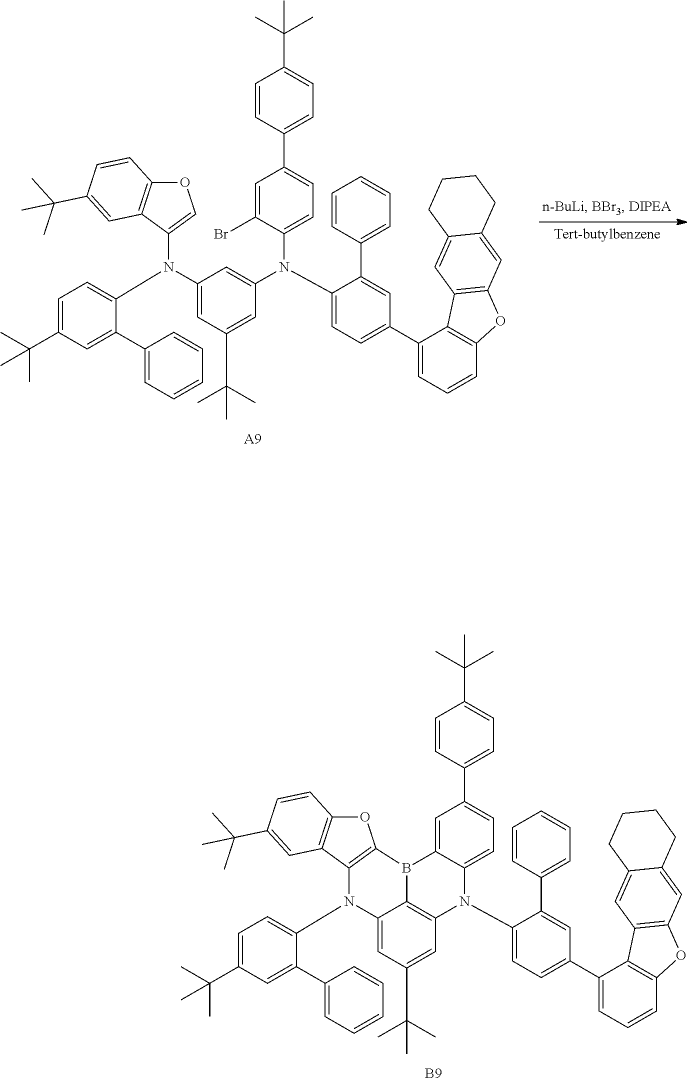

The method was the same as in Synthesis Example 2, except that A9 (12.03 g, 10 mmol) was replaced by A2 to finally obtain 0.75 g of Product B9, with a yield of 6.6%, MS (m/z) (M+): 1133.

### Synthesis Example 10

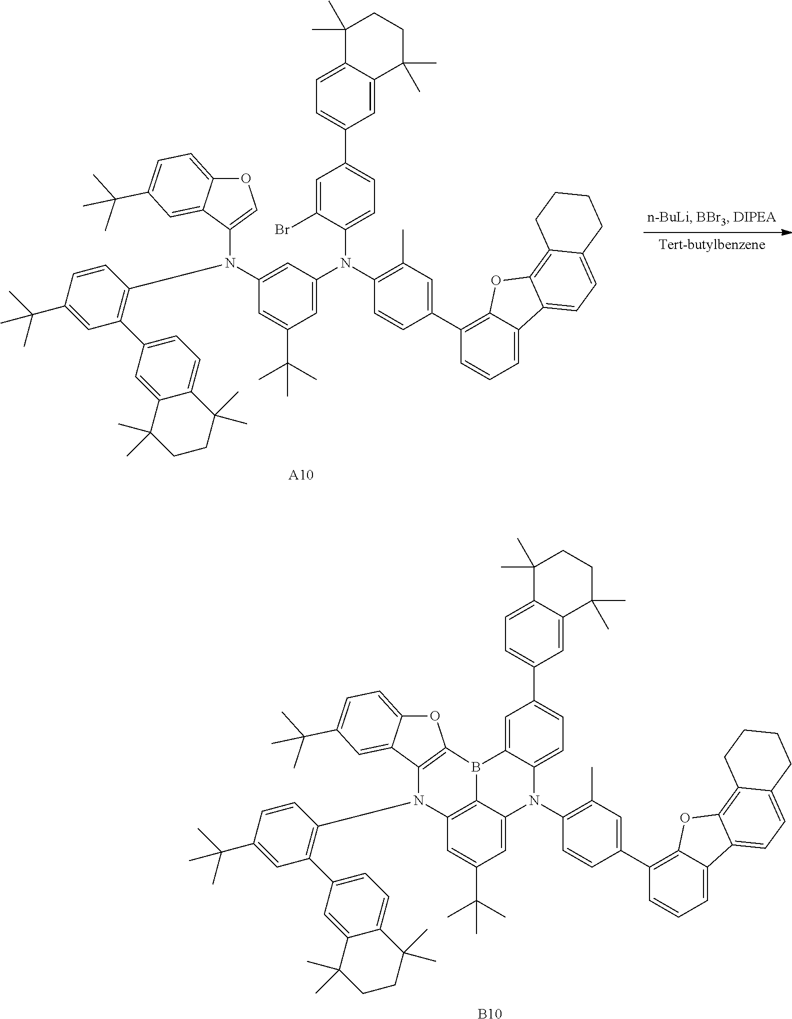

The method was the same as in Synthesis Example 2, except that A10 (13.05 g, 10 mmol) was replaced by A1 to finally obtain 0.57 g of Product B10, with a yield of 4.6%, MS (m/z) (M+): 1235.

### Synthesis Example 11

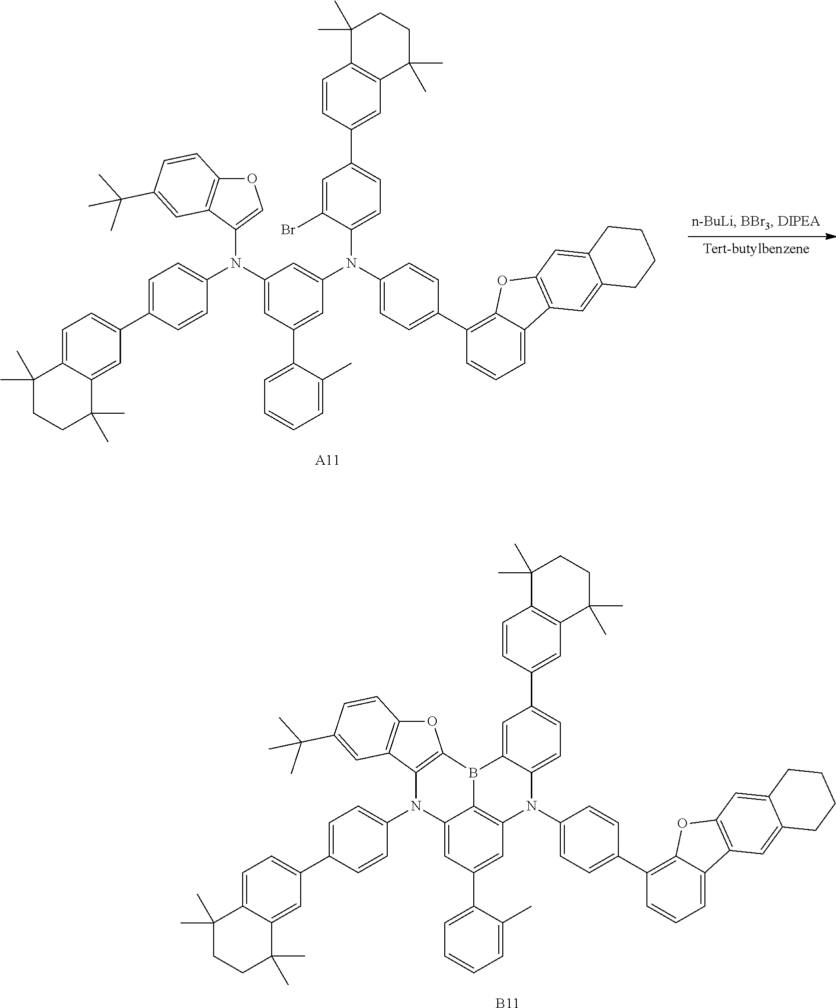

The method was the same as in Synthesis Example 2, except that A11 (12.69 g, 10 mmol) was replaced by A2 to finally obtain 0.67 g of Product B11, with a yield of 5.6%, MS (m/z) (M+): 1199.

### Synthesis Example 12

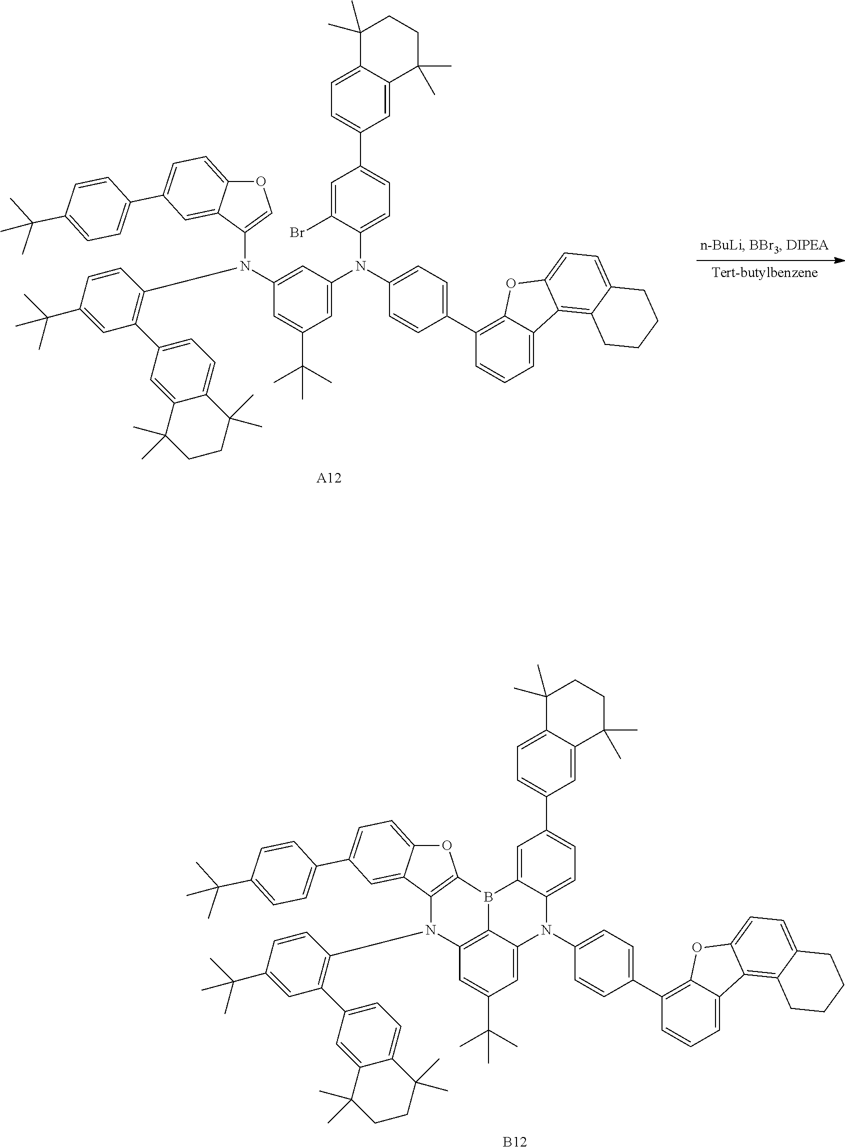

The method was the same as in Synthesis Example 2, except that A12 (13.67 g, 10 mmol) was replaced by A2 to finally obtain 0.78 g of Product B12, with a yield of 6%, MS (m/z) (M+): 1297.

### Synthesis Example 13

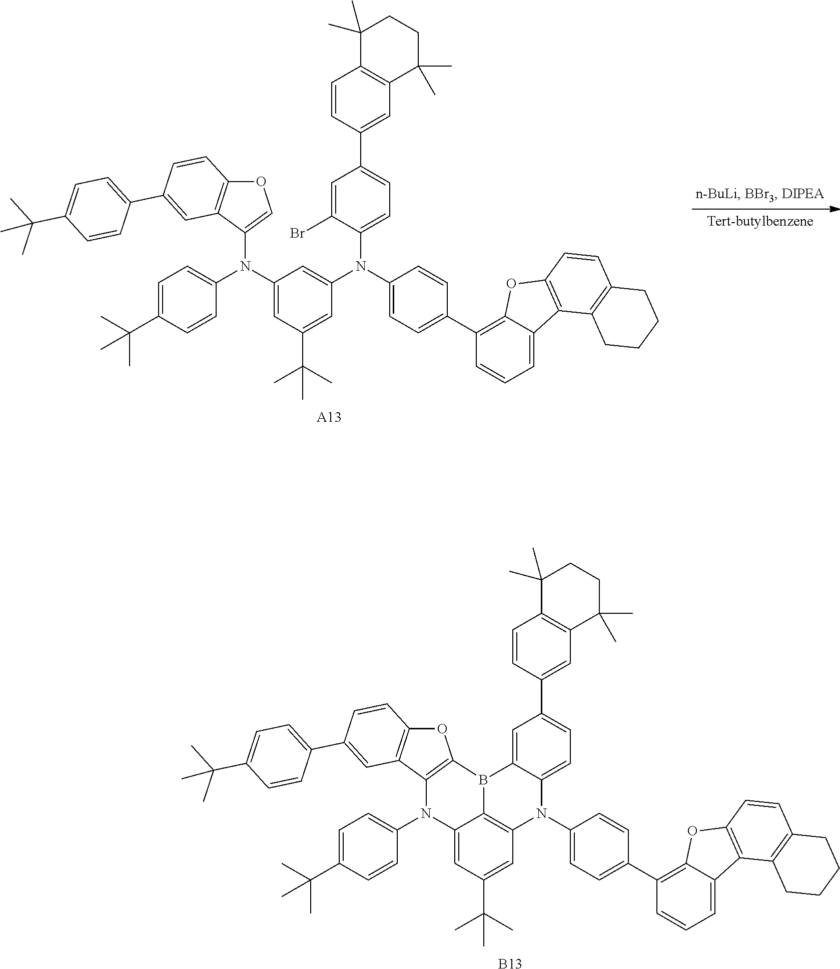

The method was the same as in Synthesis Example 2, except that A13 (11.95 g, 10 mmol) was replaced by A2 to finally obtain 0.56 g of Product B13, with a yield of 5%, MS (m/z) (M+): 1110.

### Synthesis Example 14

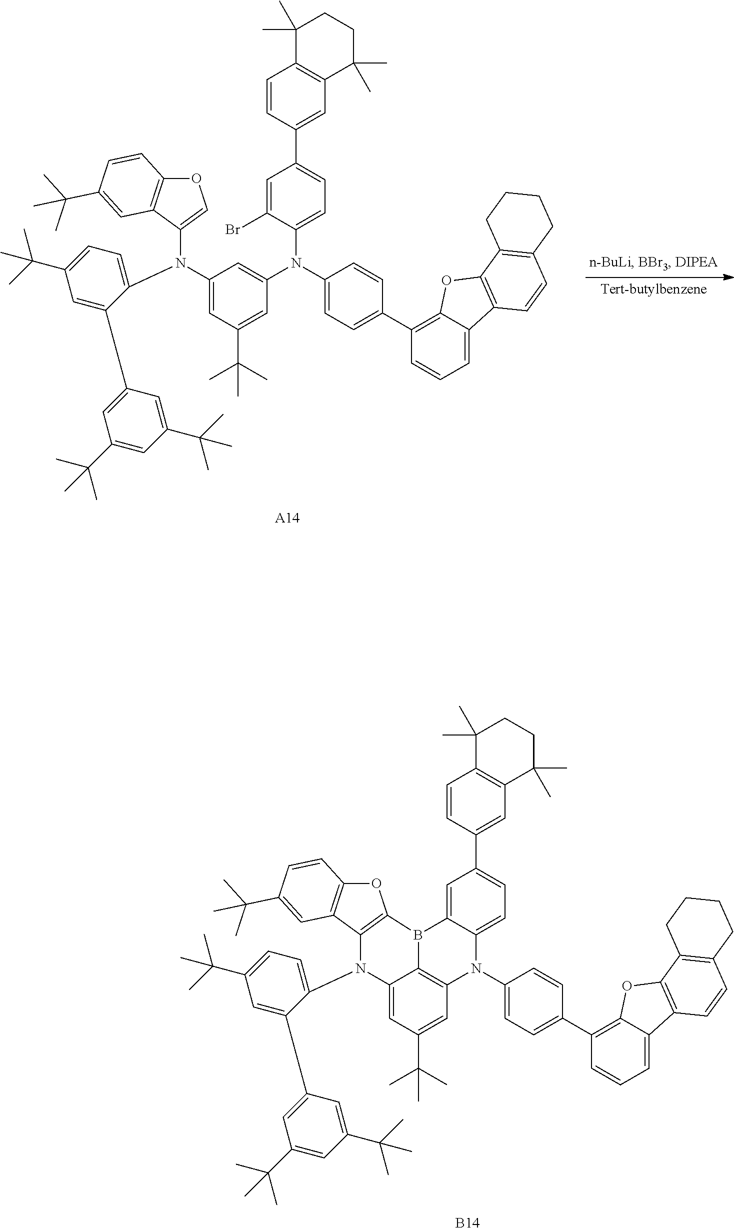

The method was the same as in Synthesis Example 2, except that A14 (13 g, 10 mmol) was replaced by A2 to finally obtain 0.85 g of Product B14, with a yield of 7%, MS (m/z) (M+): 1223.

### Synthesis Example 15

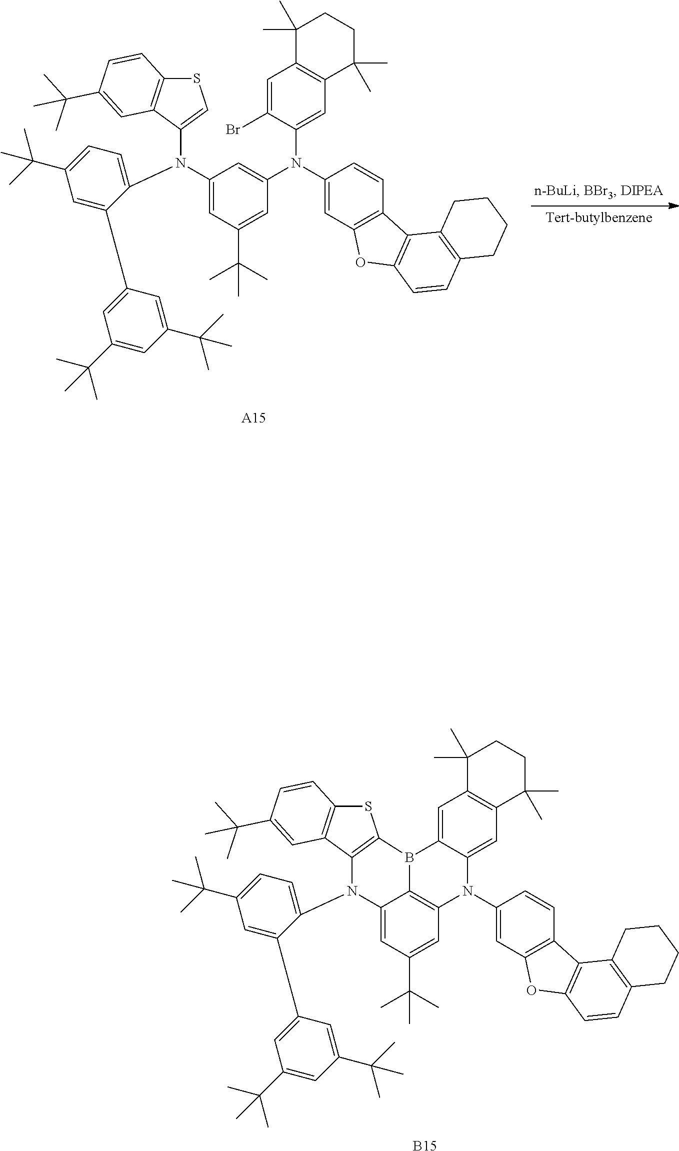

The method was the same as in Synthesis Example 2, except that A15 (11.6 g, 10 mmol) was replaced by A2 to finally obtain 0.76 g of Product B15, with a yield of 7%, MS (m/z) (M+): 1087.

### Synthesis Example 16

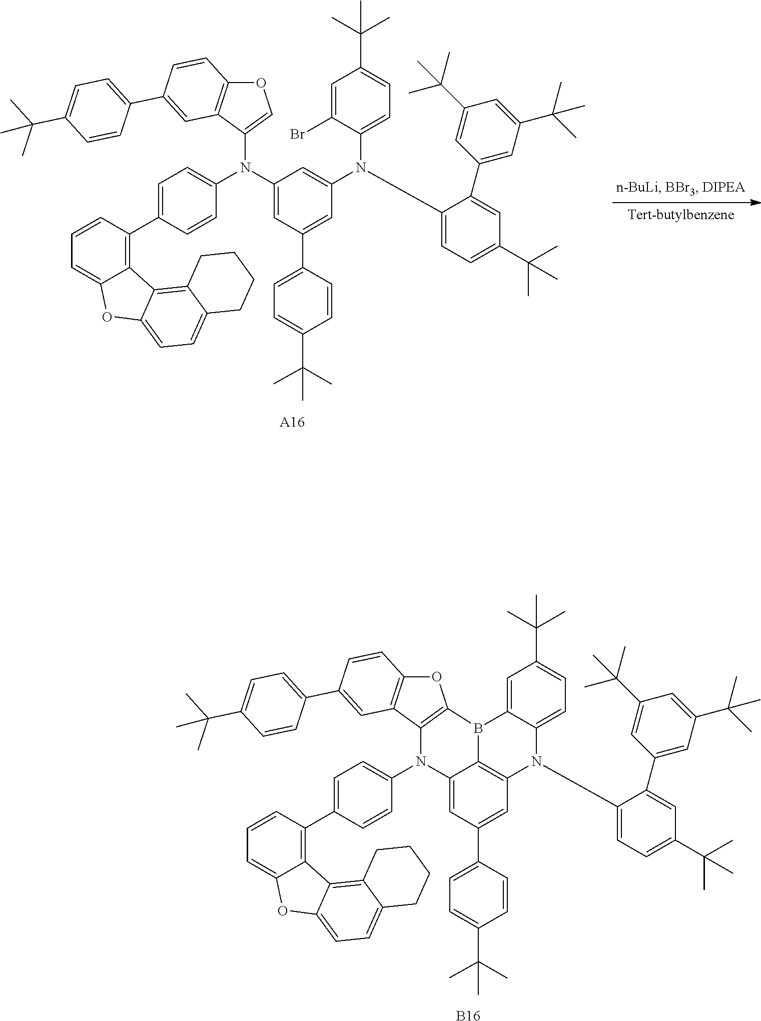

The method was the same as in Synthesis Example 2, except that A16 (13.2 g, 10 mmol) was replaced by A2 to finally obtain 0.99 g of Product B16, with a yield of 8%, MS (m/z) (M+): 1245.

### Synthesis Example 17

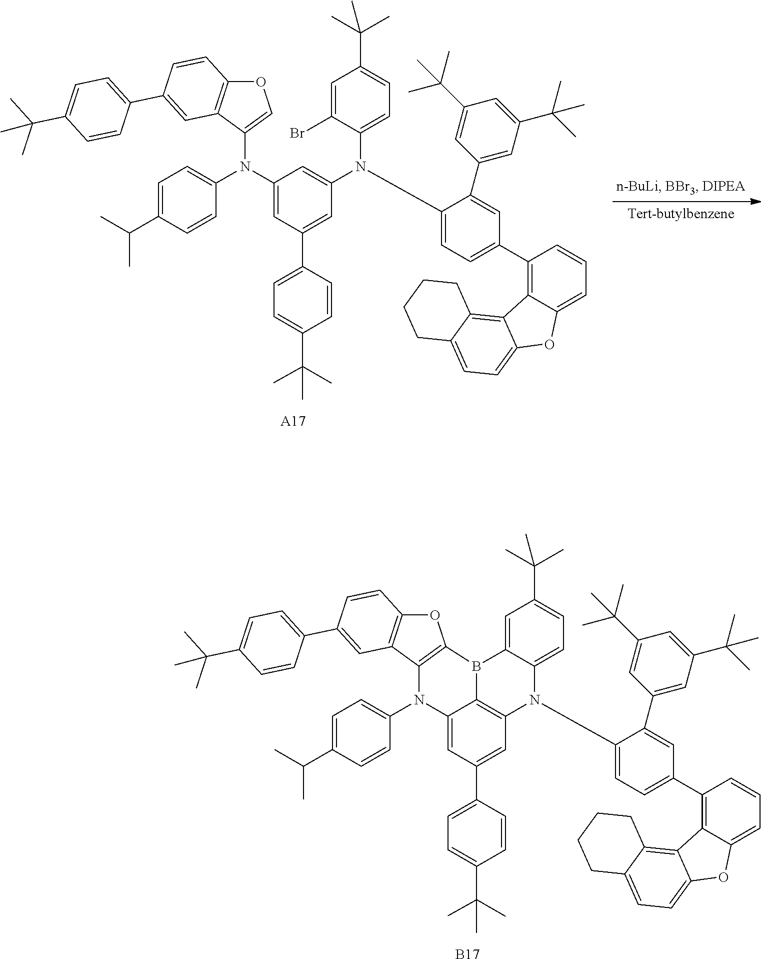

The method was the same as in Synthesis Example 2, except that A17 (13.2 g, 10 mmol) was replaced by A2 to finally obtain 0.75 g of Product B17, with a yield of 6%, MS (m/z) (M+): 1245.

### Comparative Compounds

The following provided several compounds that had been tested during research:

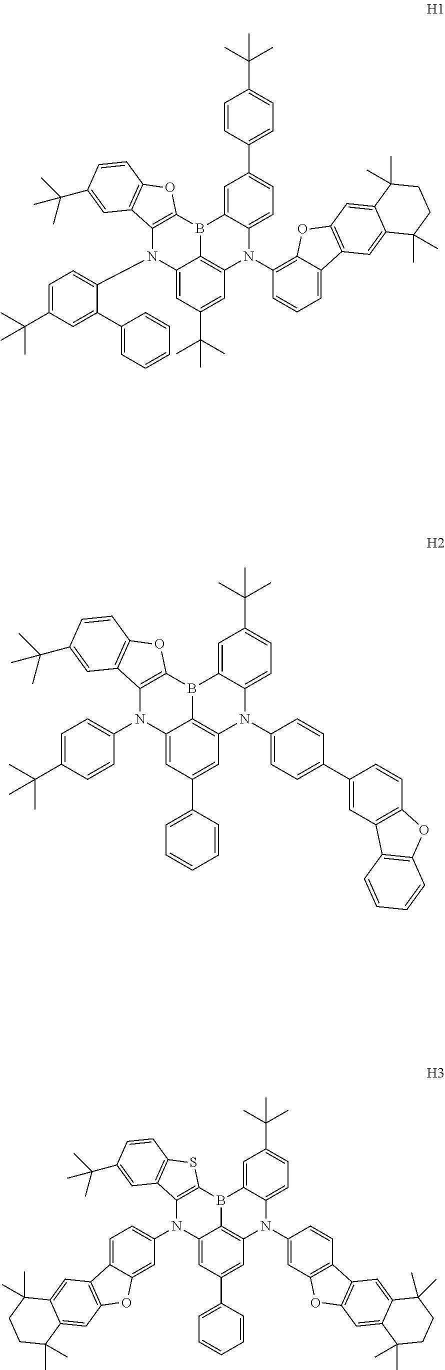

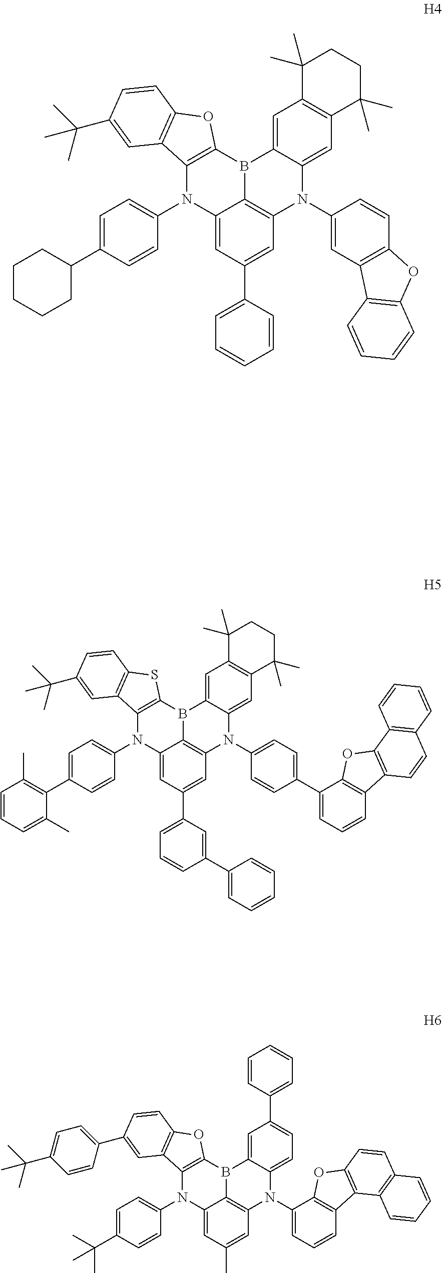 [SMILES: CC(C)(C)c1ccc2oc3c(c2c1)N(c1ccc(C2CCCCC2)cc1)c1cc(-c2ccccc2)cc2c1B3c1cc3c(cc1N2c1ccc2oc4ccccc4c2c1)C(C)(C)CCC3(C)C ; Cc1cccc(C)c1-c1ccc(N2c3cc(-c4cccc(-c5ccccc5)c4)cc4c3B(c3cc5c(cc3N4c3ccc(-c4cccc6c4oc4c7ccccc7ccc64)cc3)C(C)(C)CCC5(C)C)c3sc4ccc(C(C)(C)C)cc4c32)cc1 ; Cc1cc2c3c(c1)N(c1cccc4c1oc1ccc5ccccc5c14)c1ccc(-c4ccccc4)cc1B3c1oc3ccc(-c4ccc(C(C)(C)C)cc4)cc3c1N2c1ccc(C(C)(C)C)cc1]

### Material Performance

The compounds prepared by the synthesis examples of the present invention and the comparative compounds were tested in a thermal stability experiment. The experimental steps were as follows: placing the material to be tested in a thermal stabilizer for sublimation at 280° C., followed by refining for 240 h; then dissolving a solid sample resulting from sublimation and diluting the dissolved material with a mobile phase; and testing the change of material purity before and after the experiment by means of a high performance liquid chromatograph. The smaller the purity difference value, the better the thermal stability of the material. As can be seen from the following table, compared with Compounds H1-H6, the materials of the present invention show significantly improved thermal stability, reaching a level equivalent to that of conventional BD materials.

TABLE 1

| | Purity difference value | |
|---|---|---|
| Guest material | (%) | Evaluation |
| B1 | 0.006 | Excellent |
| B2 | 0.004 | Excellent |
| B3 | 0.007 | Excellent |
| B4 | 0.003 | Excellent |
| B5 | 0.005 | Excellent |
| B6 | 0.008 | Excellent |
| B7 | 0.003 | Excellent |
| B8 | 0.007 | Excellent |
| B9 | 0.005 | Excellent |
| B10 | 0.004 | Excellent |
| B11 | 0.004 | Excellent |
| B12 | 0.005 | Excellent |
| B13 | 0.003 | Excellent |
| B14 | 0.003 | Excellent |
| B15 | 0.009 | Excellent |
| B16 | 0.003 | Excellent |
| B17 | 0.004 | Excellent |
| H1 | 0.015 | Good |
| H2 | 0.072 | Good |
| H3 | 0.035 | Good |
| H4 | 0.133 | Moderate |
| H5 | 0.085 | Good |
| H6 | 0.022 | Good |

Note:
A purity change of <0.01% before and after the thermal stability experiment was rated as “excellent”; a purity change between 0.01% and 0.1% was rated as “good”; and a purity change of >0.1% was rated as “moderate”.

### Manufacturing and Characterization of OLEDs

The following organic electroluminescent device comprised an anode, a hole transport region, a luminescent layer, an electron transport region, a cathode, and a cover layer, which were sequentially arranged on a substrate plate, wherein the hole transport region comprised a hole injection layer, a hole transport layer, and a luminescent auxiliary layer; the electron transport region comprised a hole barrier layer, an electron transport layer, and an electron injection layer; and the luminescent layer was composed of a host and a guest, and the host material of the luminescent layer could be composed of one or more molecular materials.

For the anodes of the following examples, anode materials commonly used in the art, such as ITO, Ag or multilayer structures thereof, were used. For hole injection units, hole injection materials commonly used in the art were used, and at the same time NDP-9, etc. were added for doping. For hole transport units, hole transport materials commonly used in the art were used. For light-emitting units, luminescent materials commonly used in the art were used, for example, they could be composed of a host material doped with an emitting guest material, wherein the emitting guest material could be an organic material such as a pyrene compound or could also be a metal complex (such as the metal Ir or Pt). For electron transport units, electron transport materials commonly used in the art were used. For the electron injection layer, electron injection materials commonly used in the art, such as Liq, LiF and Yb, were used. For the cathode, commonly used materials in the art, such as the metals A1 and Ag or metal mixtures (Ag-doped Mg, Ag-doped Ca, etc.), were used.

### Device Example 1

The electrode preparation method and the deposition method for each functional layer in this example were both conventional methods in the art, such as vacuum thermal evaporation or ink-jet printing. No more detailed will be repeated here. Only some process details and test methods in the preparation process are supplemented as follows:

The substrates used in the present invention were all subjected to the following operations: patterning an ITO substrate such that the luminescent area thereof had a size of 3 mm×3 mm, then carrying out an ultrasonic treatment separately with water/isopropanol, followed by UV/ozone irradiation and then drying at 100° C., then mounting the ITO substrate on a substrate support in a vacuum deposition device, and adjusting the pressure such that the vacuum level became 1×10⁻⁷ torr.

Subsequently, the following operations were carried out. Firstly, on an ITO layer (anode) formed on a substrate, Compound HTL and Compound P-dopant (at a mass ratio of HTL to P-dopant of 97:3) were deposited in vacuo to a thickness of 10 nm to form a hole injection layer; secondly, on the above hole injection layer, Compound HTL was deposited in vacuo to a thickness of 120 nm to form a hole transport layer; thirdly, on the above hole transport layer, Compound B-Prime was deposited in vacuo to a thickness of 5 nm to form an electron barrier layer; fourthly, on the above electron barrier layer, a mixture of Compound BH and Compound B1 was deposited in vacuo to a thickness of 20 nm to form a luminescent layer, wherein Compound BH was used as a host and Compound B1 as a guest, and the mass ratio of the host to the guest was 98:2; next, on the above luminescent layer, Compound HB was deposited in vacuo to a thickness of 5 nm to form a hole barrier layer; then, on the above hole barrier layer, Compound ETL and Compound Liq (at a mass ratio of ETL to Liq of 1:1) was deposited in vacuo to a thickness of 20 nm to form an electron transport layer; then, on the above electron transport layer, Yb was deposited in vacuo to a thickness of 1 nm to form an electron injection layer; then, on the above electron injection layer, Mg and Ag (at a mass ratio of Mg to Ag of 1:9) were deposited to a thickness of 15 nm to form a cathode; then, on the above cathode, Compound CPL was deposited to a thickness of 50 nm to form a cover layer; and finally, the evaporated substrate was packaged and the cleaned cover plate was subjected to a coating process using a UV adhesive by a coating apparatus. The coated cover plate was then moved to a pressure bonding work stage. The evaporated substrate was placed on top of the cover plate. Finally, the substrate and the cover plate were laminated under the action of a lamination apparatus while the UV adhesive was simultaneously photocured, thereby preparing a stacked organic electroluminescent device.

The molecular structural formula of the material in each of the layers of the device, other than the material B1 used in the present invention, was as follows:

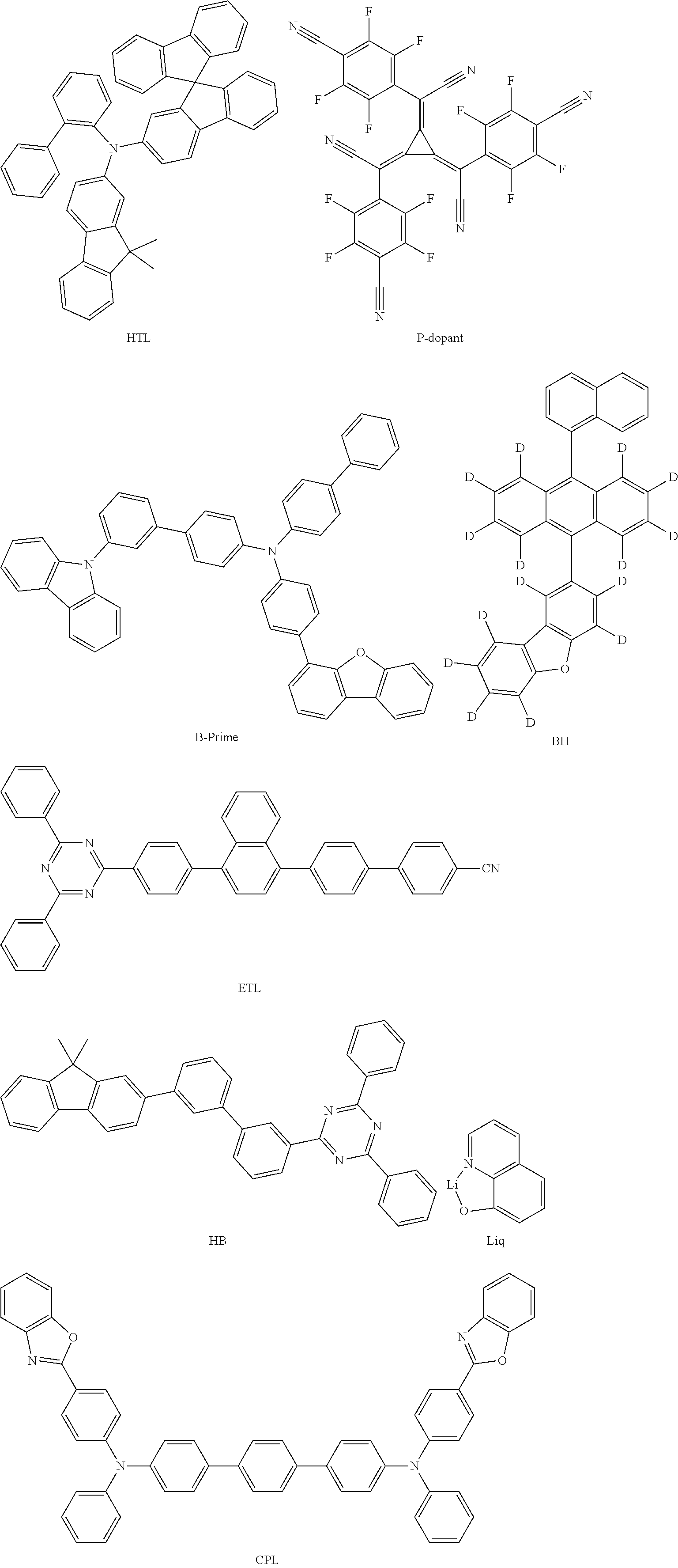

### Device Examples 2-17

Using the above-mentioned method, the compounds described in the examples were prepared into organic electroluminescent devices. Organic Electroluminescent Device Examples 2-17 were prepared by replacing B1 with B2-B17, respectively.

### Comparative Device Examples 1-6

Using the above-mentioned method, the compounds described in the comparative examples were prepared into organic electroluminescent devices. Specifically, B1 was replaced by H1-H6 to prepare Comparative Organic Electroluminescent Device Examples 1-6.

The OLED devices described above were tested by means of a standard method. To this end, the driving voltage and luminous efficiency of the organic electroluminescent devices were determined at a current density of J=10 mA/cm². LT95 means that when the prepared blue-light device operates at J=20 mA/cm², the luminous brightness decreases to 95% of its initial value L₀ after the time LT95.

The test instruments and methods for testing the performance of the OLED devices of the above examples and comparative examples were as follows:
the luminous efficiency C.E (cd/A) and color coordinates (CIEy) were tested by spectrum scanner PhotoResearch PR-635;
the current density and turn-on voltage were tested by digital SourceMeter Keithley 2400;
the luminous efficiency of the blue-light device was greatly influenced by chromaticity, and for blue-light devices, the BI value was generally used in the industry as a basis for the efficiency of blue-light devices, wherein BI (Blue index) was obtained by dividing the luminous efficiency C.E (cd/A) by the color coordinates (CIEy); and
the lifetime test was carried out by using a silicon photoelectric OLED device lifetime test system.

The test results are as shown in Table 2.

TABLE 2

| | BD | | BI | |
|---|---|---|---|---|
| Device No. | material | Volt (V) | (cd/A/CIEy) | LT95 (h) |
| Device | B1 | 3.30 | 248 | 350 |
| Example 1 | | | | |
| Device | B2 | 3.25 | 260 | 369 |
| Example 2 | | | | |
| Device | B3 | 3.31 | 245 | 360 |
| Example 3 | | | | |
| Device | B4 | 3.24 | 255 | 365 |
| Example 4 | | | | |
| Device | B5 | 3.20 | 258 | 366 |
| Example 5 | | | | |
| Device | B6 | 3.28 | 239 | 359 |
| Example 6 | | | | |
| Device | B7 | 3.24 | 255 | 370 |
| Example 7 | | | | |
| Device | B8 | 3.27 | 240 | 361 |
| Example 8 | | | | |
| Device | B9 | 3.23 | 258 | 370 |
| Example 9 | | | | |
| Device | B10 | 3.24 | 259 | 375 |
| Example 10 | | | | |
| Device | B11 | 3.25 | 260 | 366 |
| Example 11 | | | | |
| Device | B12 | 3.22 | 258 | 373 |
| Example 12 | | | | |
| Device | B13 | 3.26 | 258 | 373 |
| Example 13 | | | | |
| Device | B14 | 3.21 | 262 | 376 |
| Example 14 | | | | |
| Device | B15 | 3.30 | 238 | 340 |
| Example 15 | | | | |
| Device | B16 | 3.31 | 263 | 371 |
| Example 16 | | | | |
| Device | B17 | 3.28 | 265 | 374 |
| Example 17 | | | | |
| Comparative | H1 | 3.37 | 100 | 120 |
| Device | | | | |
| Example 1 | | | | |
| Comparative | H2 | 3.42 | 194 | 243 |
| Device | | | | |
| Example 2 | | | | |
| Comparative | H3 | 3.36 | 190 | 187 |
| Device | | | | |
| Example 3 | | | | |
| Comparative | H4 | 3.35 | 200 | 170 |
| Device | | | | |
| Example 4 | | | | |
| Comparative | H5 | 3.35 | 210 | 220 |
| Device | | | | |
| Example 5 | | | | |
| Comparative | H6 | 3.31 | 220 | 240 |
| Device | | | | |
| Example 6 | | | | |

The following conclusions can be drawn from the above-mentioned Device Examples 1-17 and Comparative Device Examples 1-6: the organic electroluminescent devices provided by the present invention have significant advantages in luminous performance and generally exhibit higher BI values, longer lifetimes, and more importantly, higher thermal stabilities. This is because the BD compounds provided in the present invention all have the cyclohexyl-fused dibenzofuranyl structure. Due to the action of mutual repulsion of lone-pair electrons of the oxygen atom in the cyclohexyl-fused dibenzofuranyl structure, the intermolecular distance is increased, thereby improving the fluorescence quantum yield, facilitating enhanced device efficiency and prolonged lifetime. In addition, by means of the structural design of this non-planar cyclohexyl-fused dibenzofuranyl, the thermal stability of the molecules is increased, and the rigidity of the BD molecules is increased, thereby indirectly reducing the problem of device performance degradation caused by heating, achieving improved device efficiency and lifetime.

Apparently, the above examples of the present invention are only examples provided to clearly illustrate the present invention, rather than limitations on the embodiments of the present invention. For those of ordinary skill in the art, other variations or changes in various forms can also be made on the basis of the above description. It is impossible to enumerate all embodiments here. Any obvious variations or changes arising from the technical solutions of the present invention still fall within the scope of protection of the present invention.

1. A blue luminescent compound containing a cyclohexyl-fused dibenzofuranyl structure, characterized in that the general structural formula of the blue luminescent compound is as shown in Formula I or II: 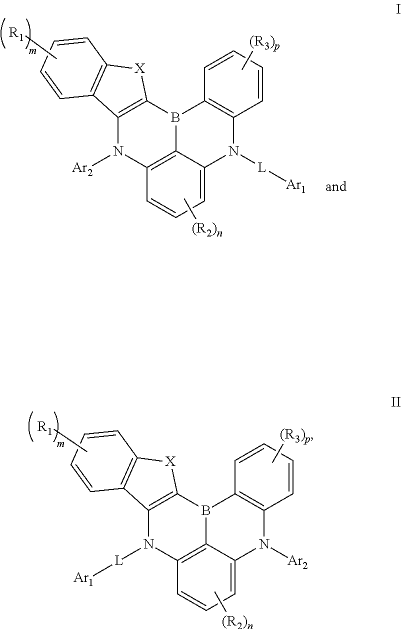
wherein
X represents O or S;
Ar₁ represents cyclohexyl-fused dibenzofuranyl;
Ar₂ represents any one of a substituted or unsubstituted aryl group having a carbon atom number of C6-C60, a substituted or unsubstituted heteroaryl group having a carbon atom number of C5-C60, a substituted or unsubstituted fused aryl group having a carbon atom number of C6-C60, and a substituted or unsubstituted heterocyclic fused aryl group having a carbon atom number of C5-C60;
L represents any one of a single bond and a substituted or unsubstituted arylene group having a carbon atom number of C6-C12;
R₁, R₂, and R₃ each independently represent any one of hydrogen, deuterium, halogen, a substituted or unsubstituted alkyl group having a carbon atom number of C1-C30, a substituted or unsubstituted alkenyl group having a carbon atom number of C2-C30, a substituted or unsubstituted cycloalkyl group having a carbon atom number of C3-C30, a substituted or unsubstituted aryl group having a carbon atom number of C6-C60, a substituted or unsubstituted heteroaryl group having a carbon atom number of C5-C60, a substituted or unsubstituted fused aryl group having a carbon atom number of C6-C60, and a substituted or unsubstituted heterocyclic fused aryl group having a carbon atom number of C5-C60, wherein two or more R₁, R₂, or R₃ can be connected to each other to form an aliphatic ring, an aromatic ring, or a fused ring;
when Ar₂, R₁, R₂, and R₃ contain a substituent, the substituent is selected from any one of an alkyl group having a carbon atom number of C1-C10, a cycloalkyl group having a carbon atom number of C3-C10, an aryl group having a carbon atom number of C6-C20, and a substituted or unsubstituted heteroaryl group having a carbon atom number of C5-C20;
m and p each independently represent 0, 1, 2, 3, or 4, and n represents 0, 1, 2, or 3; and
in Formulas I and II, any hydrogen can be replaced by deuterium, any nitrogen can be replaced by nitrogen-15, any sulfur can be replaced by sulfur-33, sulfur-34, or sulfur-36, any oxygen can be replaced by oxygen-17 or oxygen-18, any carbon can be replaced by carbon-13, and any boron can be replaced by boron-11.

2. The blue luminescent compound according to claim 1, characterized in that X represents O; and
L represents any one of a single bond, a substituted or unsubstituted phenylene group, and a substituted or unsubstituted naphthylene group.

3. The blue luminescent compound according to claim 1, characterized in that Ar₁ represents one of the following structures:

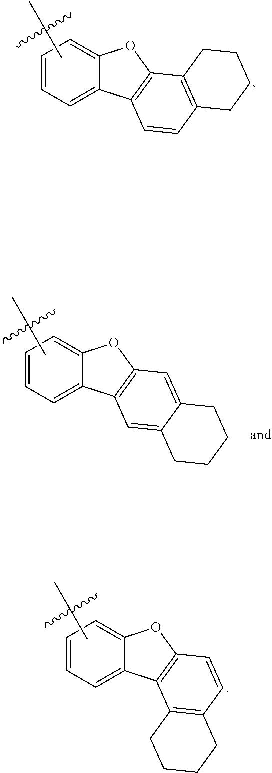

4. The blue luminescent compound according to claim 1, characterized in that the general structural formula of the blue luminescent compound is as shown in one of Formulas I-1 to I-5:

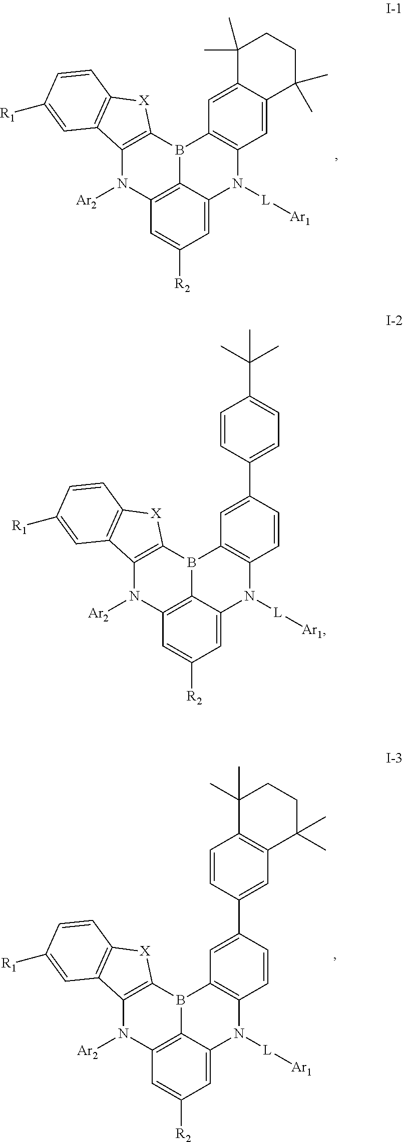

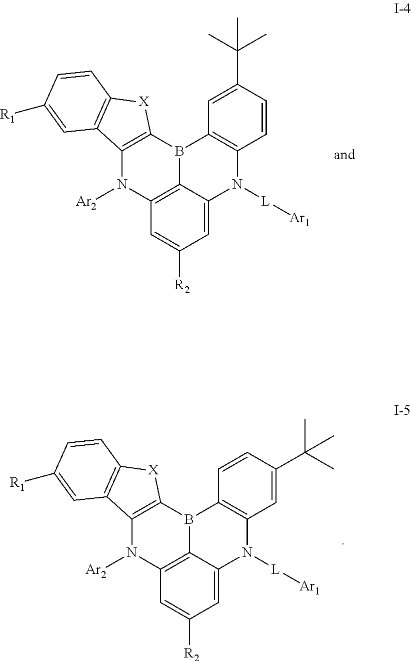

5. The blue luminescent compound according to claim 1, characterized in that R₁, R₂, and R₃ each independently represent any one of hydrogen, deuterium, halogen, a substituted or unsubstituted alkyl group having a carbon atom number of C1-C10, a substituted or unsubstituted cycloalkyl group having a carbon atom number of C3-C10, a substituted or unsubstituted aryl group having a carbon atom number of C6-C20, a substituted or unsubstituted heteroaryl group having a carbon atom number of C5-C20, a substituted or unsubstituted fused aryl group having a carbon atom number of C6-C20, and a substituted or unsubstituted heterocyclic fused aryl group having a carbon atom number of C5-C20, wherein two or more R₁, R₂, or R₃ can be connected to each other to form a five-membered ring or a six-membered ring; and
Ar₂ represents any one of a substituted or unsubstituted aryl group having a carbon atom number of C6-C20, a substituted or unsubstituted heteroaryl group having a carbon atom number of C5-C20, a substituted or unsubstituted fused aryl group having a carbon atom number of C6-C20, and a substituted or unsubstituted heterocyclic fused aryl group having a carbon atom number of C5-C20.

6. The blue luminescent compound according to claim 1, characterized in that R₁ and R₂ each independently represent any one of

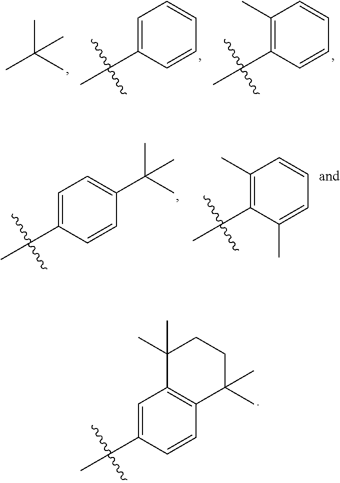

7. The blue luminescent compound according to claim 1, characterized in that L represents any one of

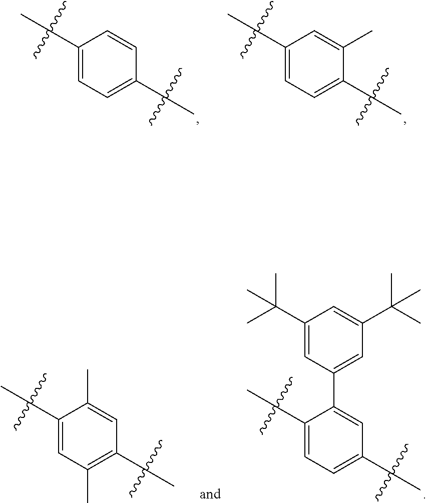

8. The blue luminescent compound according to claim 1, characterized in that Ar₂ represents one of the following structures: 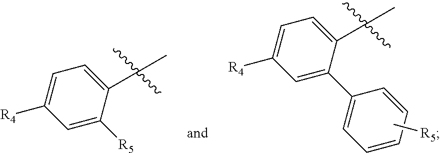
R₄ represents any one of an alkyl group having a carbon atom number of C1-C10 and a cycloalkyl group having a carbon atom number of C3-C10; and
R₅ represents a single substituent to the maximum permissible substituents and is selected from any one of an alkyl group having a carbon atom number of C1-C10 and a cycloalkyl group having a carbon atom number of C3-C10.

9. The blue luminescent compound according to claim 1, characterized in that the blue luminescent compound is selected from one of the following structures:

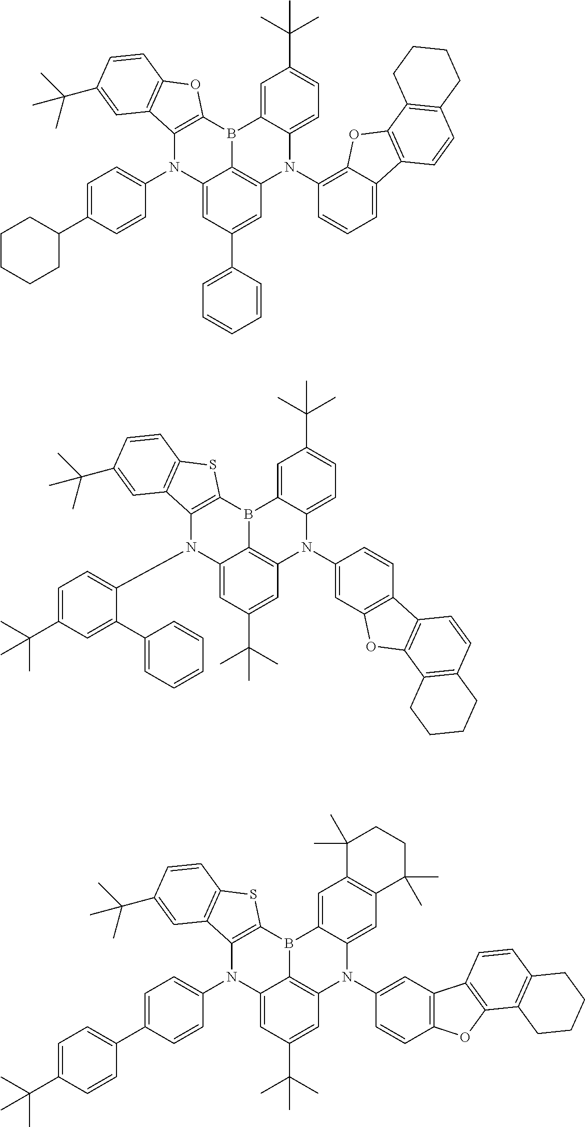 [SMILES: CC(C)(C)c1ccc2c(c1)B1c3oc4ccc(C(C)(C)C)cc4c3N(c3ccc(C4CCCCC4)cc3)c3cc(-c4ccccc4)cc(c31)N2c1cccc2c1oc1c3c(ccc12)CCCC3 ; CC(C)(C)c1ccc2c(c1)B1c3sc4ccc(C(C)(C)C)cc4c3N(c3ccc(C(C)(C)C)cc3-c3ccccc3)c3cc(C(C)(C)C)cc(c31)N2c1ccc2c(c1)oc1c3c(ccc12)CCCC3 ; CC(C)(C)c1ccc(-c2ccc(N3c4cc(C(C)(C)C)cc5c4B(c4cc6c(cc4N5c4ccc5oc7c8c(ccc7c5c4)CCCC8)C(C)(C)CCC6(C)C)c4sc5ccc(C(C)(C)C)cc5c43)cc2)cc1]

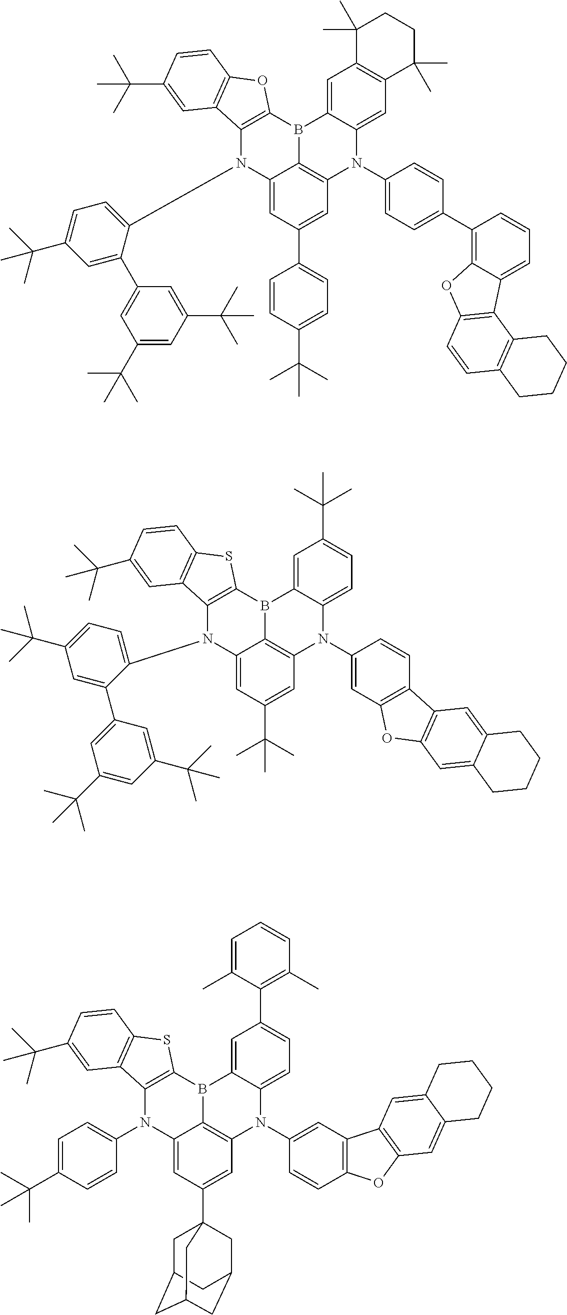 [SMILES: CC(C)(C)c1ccc(-c2cc3c4c(c2)N(c2ccc(C(C)(C)C)cc2-c2cc(C(C)(C)C)cc(C(C)(C)C)c2)c2c(oc5ccc(C(C)(C)C)cc25)B4c2cc4c(cc2N3c2ccc(-c3cccc5c3oc3ccc6c(c35)CCCC6)cc2)C(C)(C)CCC4(C)C)cc1 ; CC(C)(C)c1cc(-c2cc(C(C)(C)C)ccc2N2c3cc(C(C)(C)C)cc4c3B(c3cc(C(C)(C)C)ccc3N4c3ccc4c(c3)oc3cc5c(cc34)CCCC5)c3sc4ccc(C(C)(C)C)cc4c32)cc(C(C)(C)C)c1 ; Cc1cccc(C)c1-c1ccc2c(c1)B1c3sc4ccc(C(C)(C)C)cc4c3N(c3ccc(C(C)(C)C)cc3)c3cc(C45CC6CC(CC(C6)C4)C5)cc(c31)N2c1ccc2oc3cc4c(cc3c2c1)CCCC4]

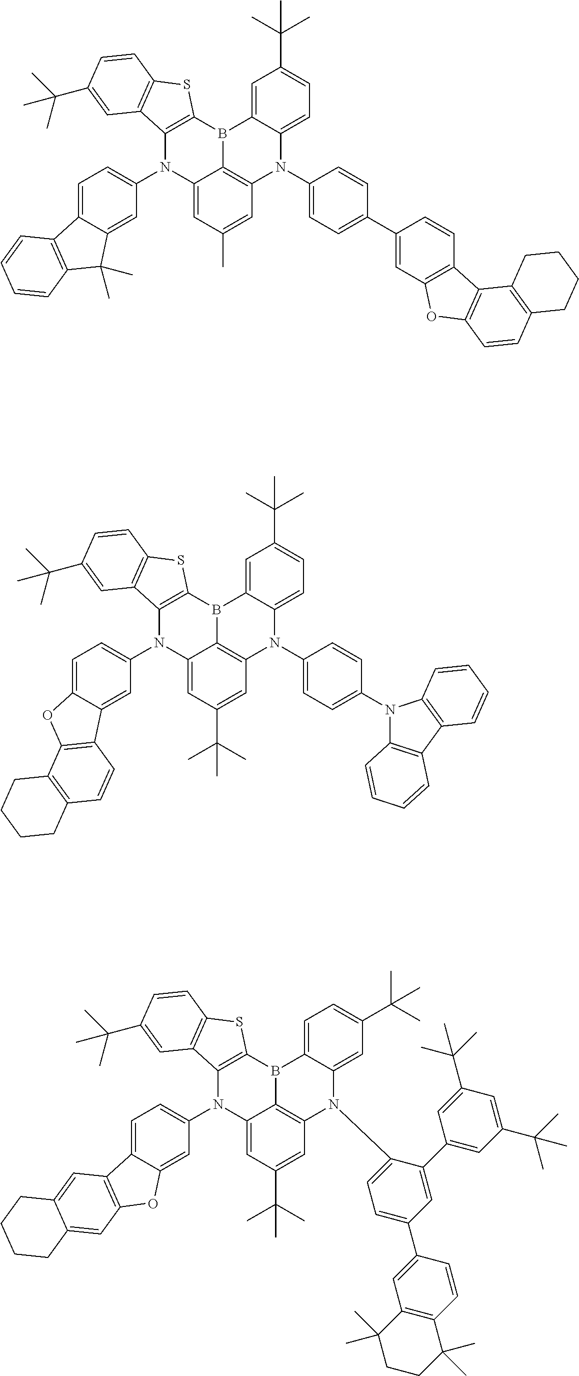 [SMILES: Cc1cc2c3c(c1)N(c1ccc4c(c1)C(C)(C)c1ccccc1-4)c1c(sc4ccc(C(C)(C)C)cc14)B3c1cc(C(C)(C)C)ccc1N2c1ccc(-c2ccc3c(c2)oc2ccc4c(c23)CCCC4)cc1 ; CC(C)(C)c1ccc2c(c1)B1c3sc4ccc(C(C)(C)C)cc4c3N(c3ccc4oc5c6c(ccc5c4c3)CCCC6)c3cc(C(C)(C)C)cc(c31)N2c1ccc(-n2c3ccccc3c3ccccc32)cc1 ; CC(C)(C)c1cc(-c2cc(-c3ccc4c(c3)C(C)(C)CCC4(C)C)ccc2N2c3cc(C(C)(C)C)ccc3B3c4sc5ccc(C(C)(C)C)cc5c4N(c4ccc5c(c4)oc4cc6c(cc45)CCCC6)c4cc(C(C)(C)C)cc2c43)cc(C(C)(C)C)c1]

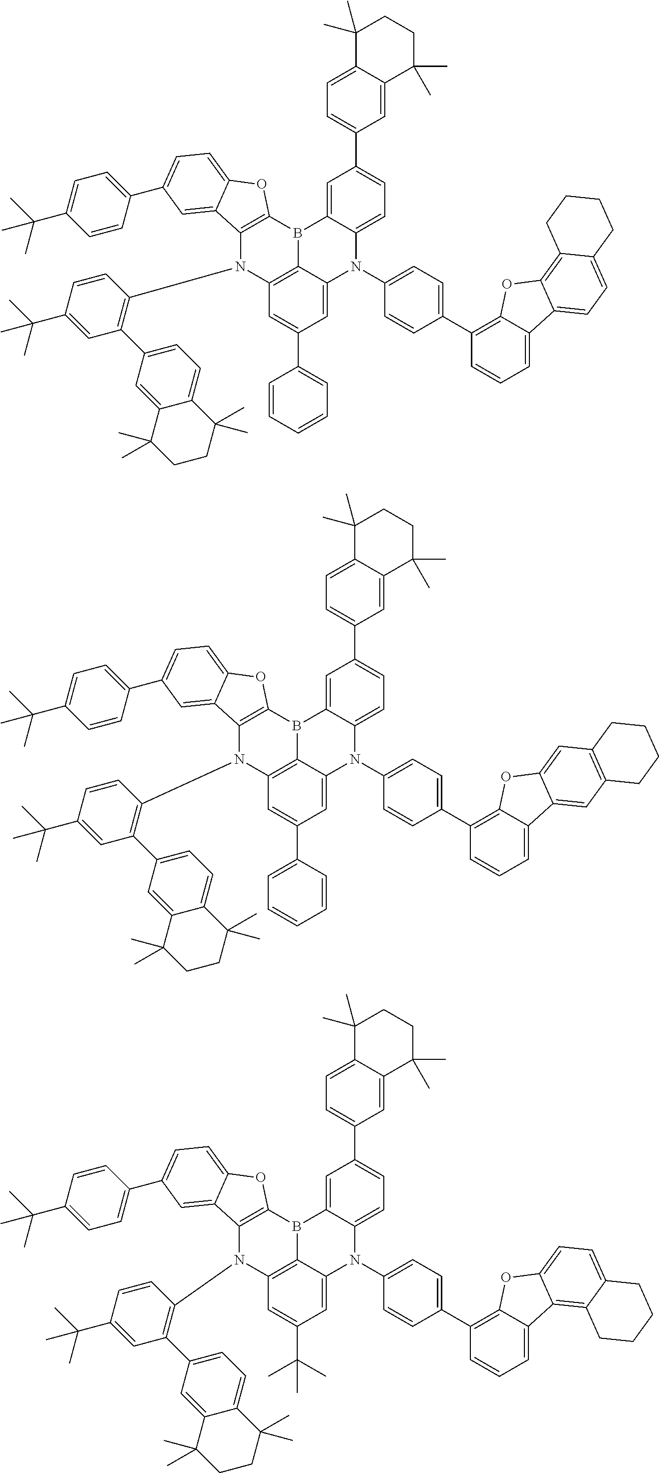

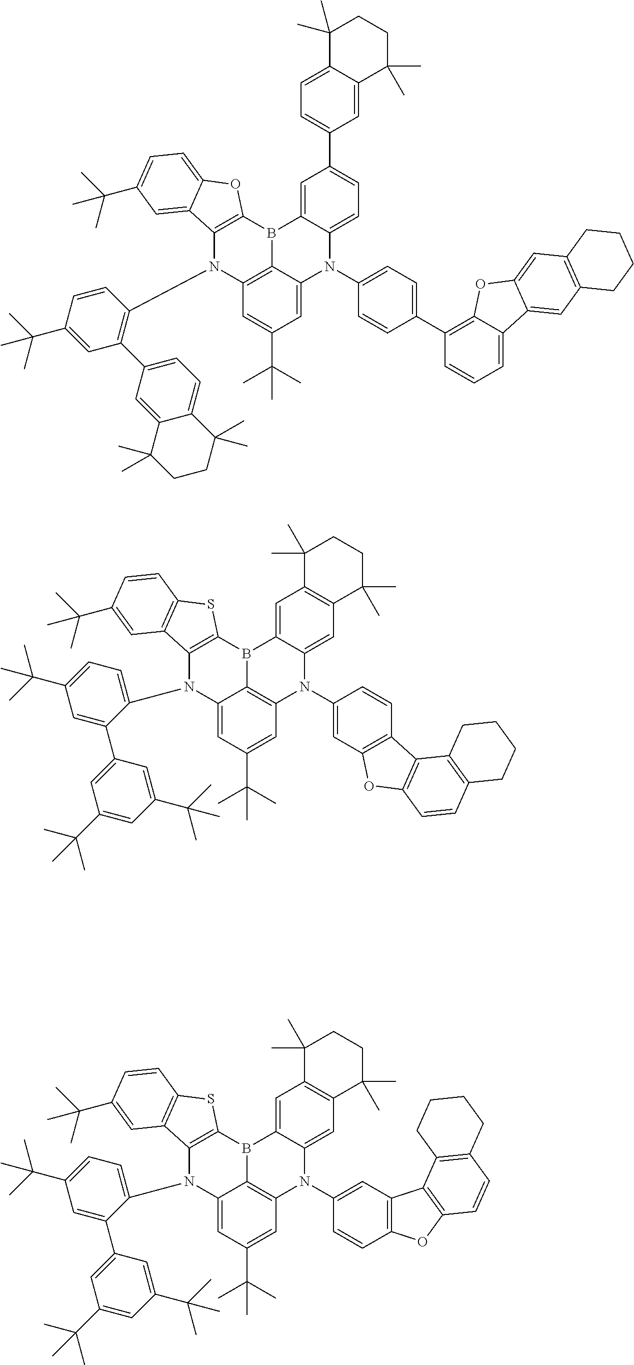 [SMILES: CC(C)(C)c1ccc(N2c3cc(C(C)(C)C)cc4c3B(c3cc(-c5ccc6c(c5)C(C)(C)CCC6(C)C)ccc3N4c3ccc(-c4cccc5c4oc4cc6c(cc45)CCCC6)cc3)c3oc4ccc(C(C)(C)C)cc4c32)c(-c2ccc3c(c2)C(C)(C)CCC3(C)C)c1 ; CC(C)(C)c1cc(-c2cc(C(C)(C)C)ccc2N2c3cc(C(C)(C)C)cc4c3B(c3cc5c(cc3N4c3ccc4c(c3)oc3ccc6c(c34)CCCC6)C(C)(C)CCC5(C)C)c3sc4ccc(C(C)(C)C)cc4c32)cc(C(C)(C)C)c1 ; CC(C)(C)c1cc(-c2cc(C(C)(C)C)ccc2N2c3cc(C(C)(C)C)cc4c3B(c3cc5c(cc3N4c3ccc4oc6ccc7c(c6c4c3)CCCC7)C(C)(C)CCC5(C)C)c3sc4ccc(C(C)(C)C)cc4c32)cc(C(C)(C)C)c1]

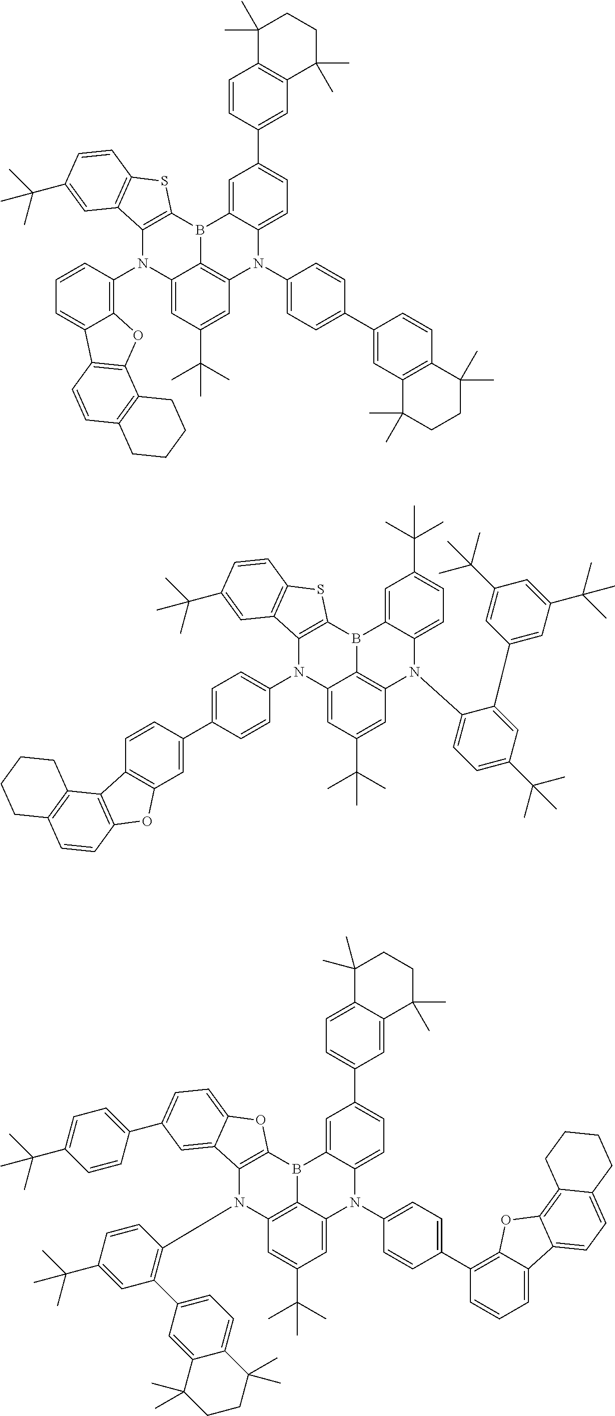

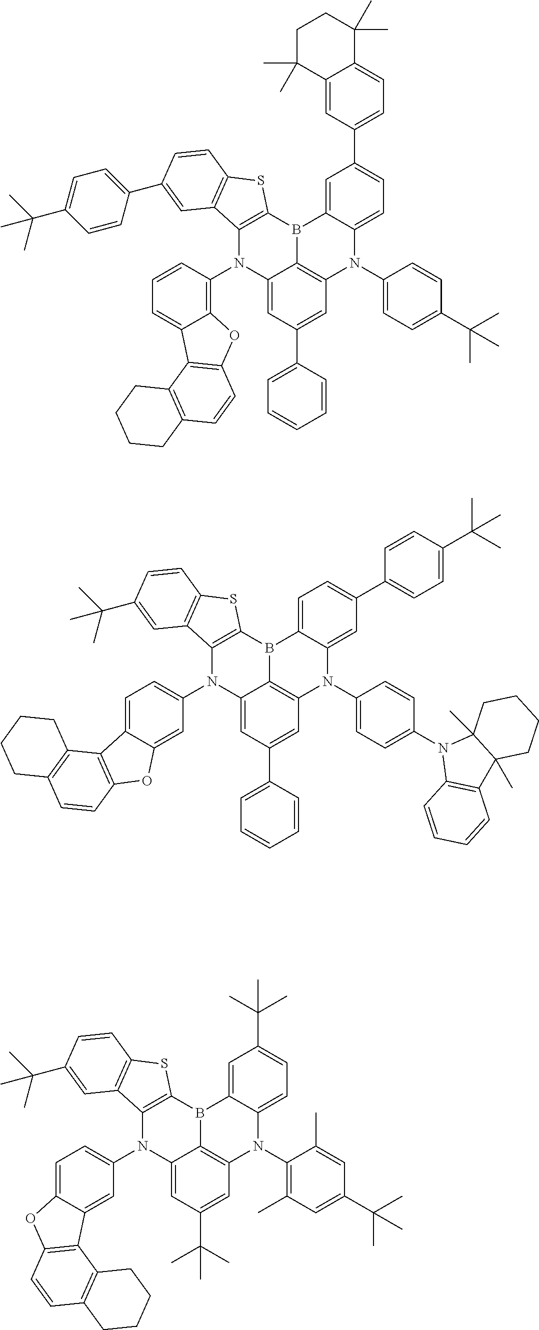

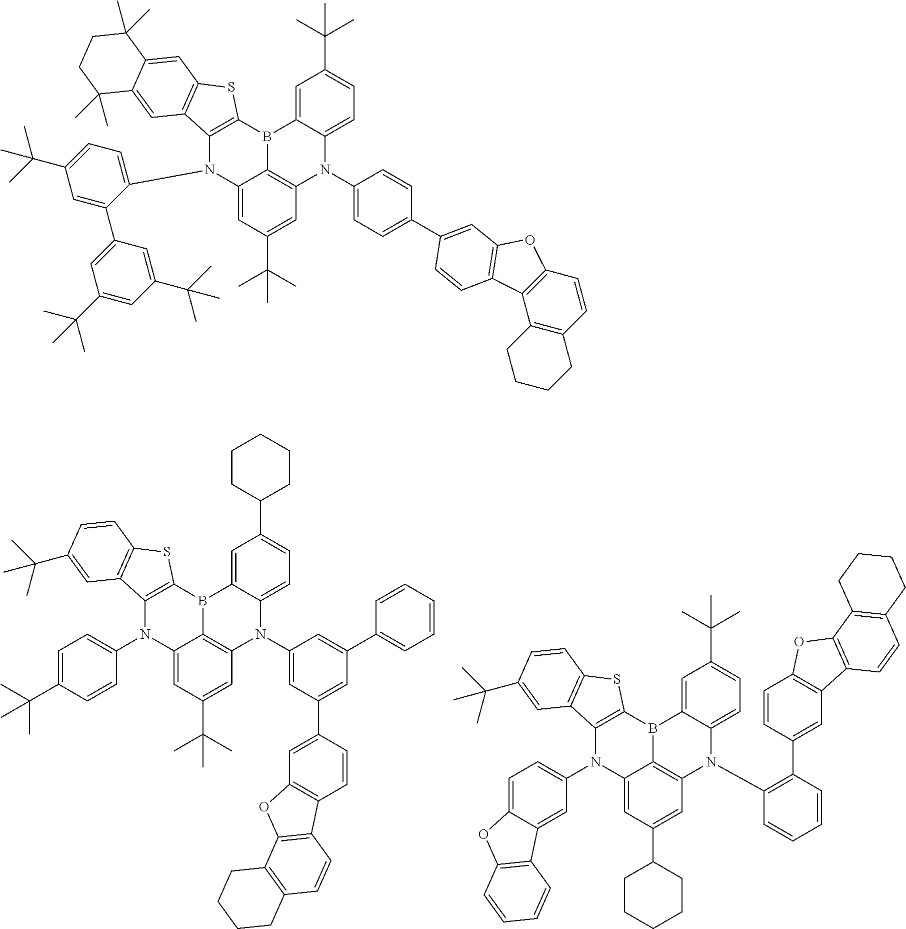

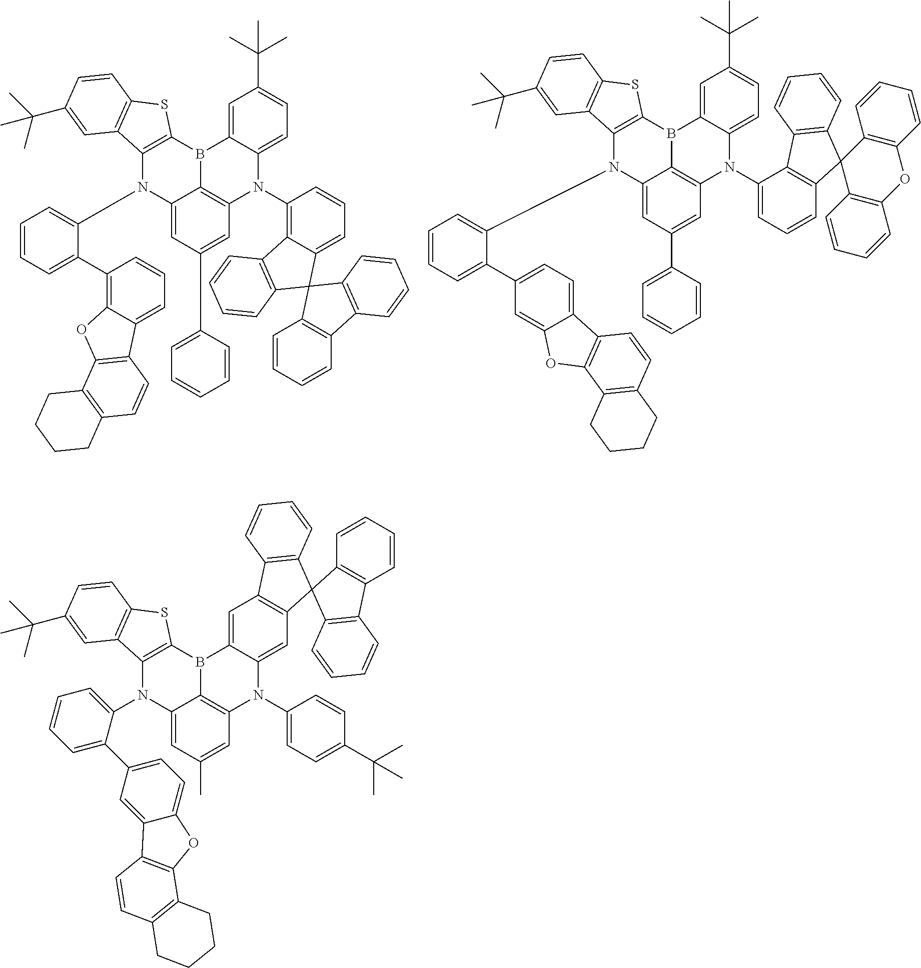

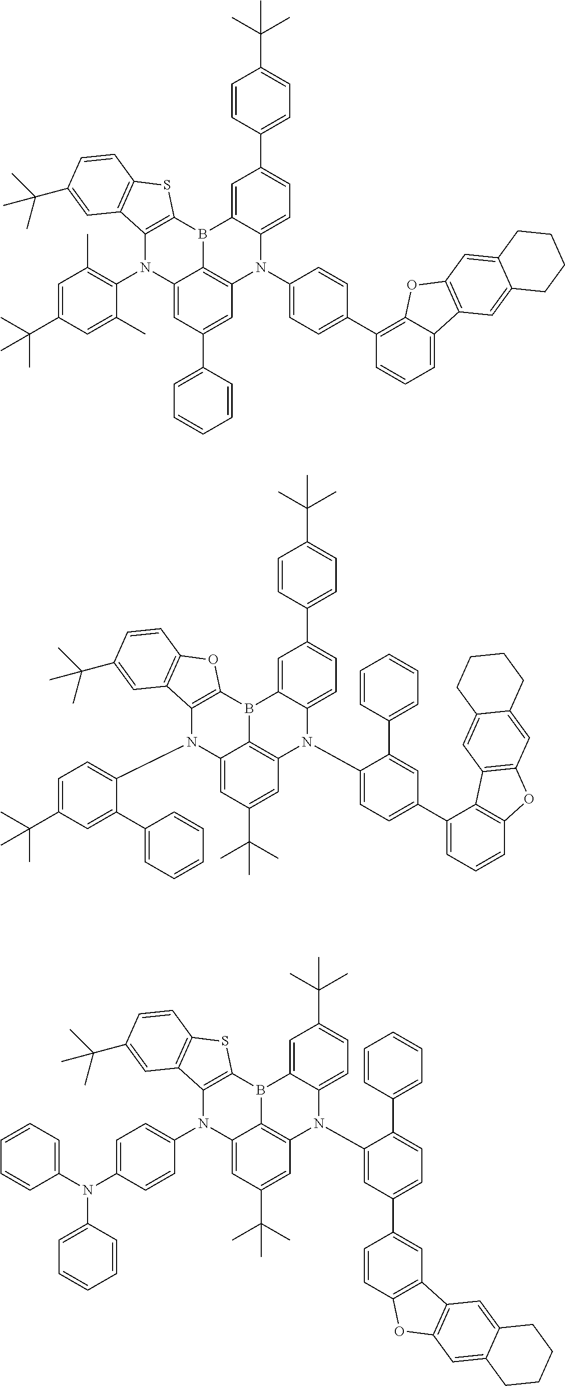 [SMILES: Cc1cc(C(C)(C)C)cc(C)c1N1c2cc(-c3ccccc3)cc3c2B(c2cc(-c4ccc(C(C)(C)C)cc4)ccc2N3c2ccc(-c3cccc4c3oc3cc5c(cc34)CCCC5)cc2)c2sc3ccc(C(C)(C)C)cc3c21 ; CC(C)(C)c1ccc(-c2ccc3c(c2)B2c4oc5ccc(C(C)(C)C)cc5c4N(c4ccc(C(C)(C)C)cc4-c4ccccc4)c4cc(C(C)(C)C)cc(c42)N3c2ccc(-c3cccc4oc5cc6c(cc5c34)CCCC6)cc2-c2ccccc2)cc1 ; CC(C)(C)c1ccc2c(c1)B1c3sc4ccc(C(C)(C)C)cc4c3N(c3ccc(N(c4ccccc4)c4ccccc4)cc3)c3cc(C(C)(C)C)cc(c31)N2c1cc(-c2ccc3oc4cc5c(cc4c3c2)CCCC5)ccc1-c1ccccc1]

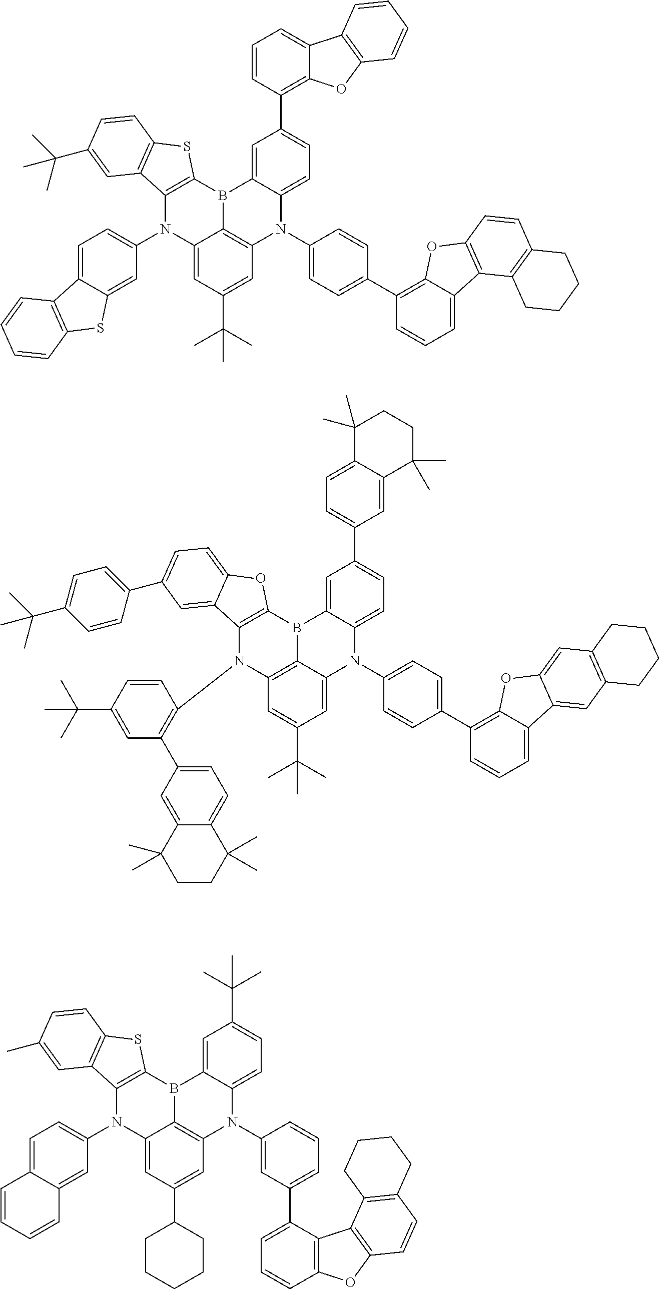 [SMILES: CC(C)(C)c1cc2c3c(c1)N(c1ccc4c(c1)sc1ccccc14)c1c(sc4ccc(C(C)(C)C)cc14)B3c1cc(-c3cccc4c3oc3ccccc34)ccc1N2c1ccc(-c2cccc3c2oc2ccc4c(c23)CCCC4)cc1 ; CC(C)(C)c1ccc(-c2ccc3oc4c(c3c2)N(c2ccc(C(C)(C)C)cc2-c2ccc3c(c2)C(C)(C)CCC3(C)C)c2cc(C(C)(C)C)cc3c2B4c2cc(-c4ccc5c(c4)C(C)(C)CCC5(C)C)ccc2N3c2ccc(-c3cccc4c3oc3cc5c(cc34)CCCC5)cc2)cc1 ; Cc1ccc2sc3c(c2c1)N(c1ccc2ccccc2c1)c1cc(C2CCCCC2)cc2c1B3c1cc(C(C)(C)C)ccc1N2c1cccc(-c2cccc3oc4ccc5c(c4c23)CCCC5)c1]

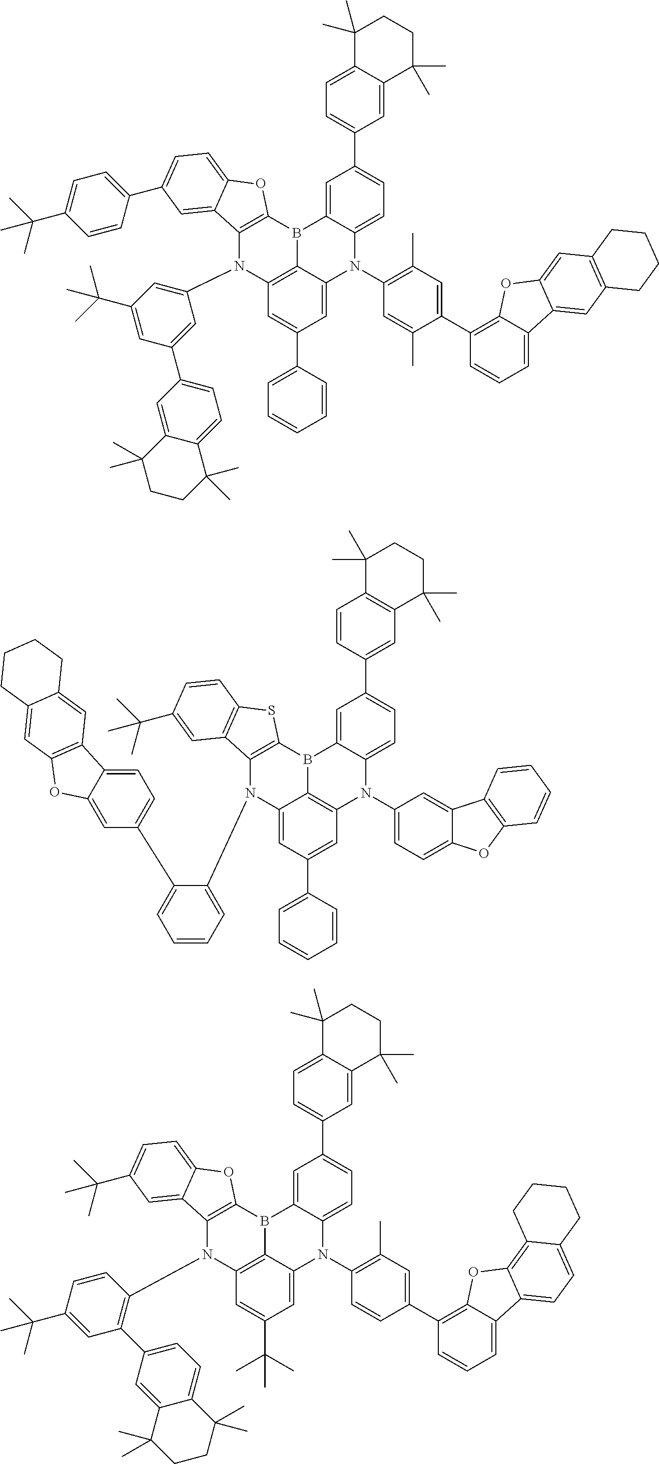

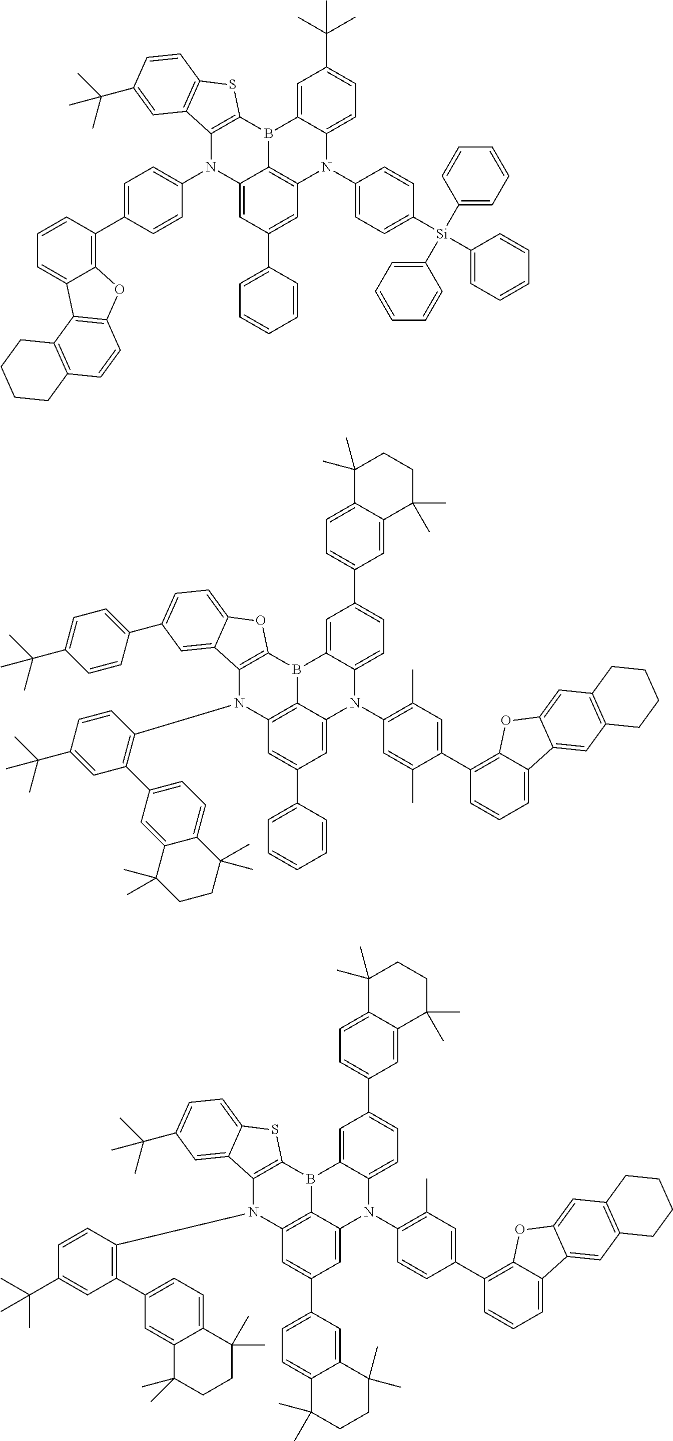

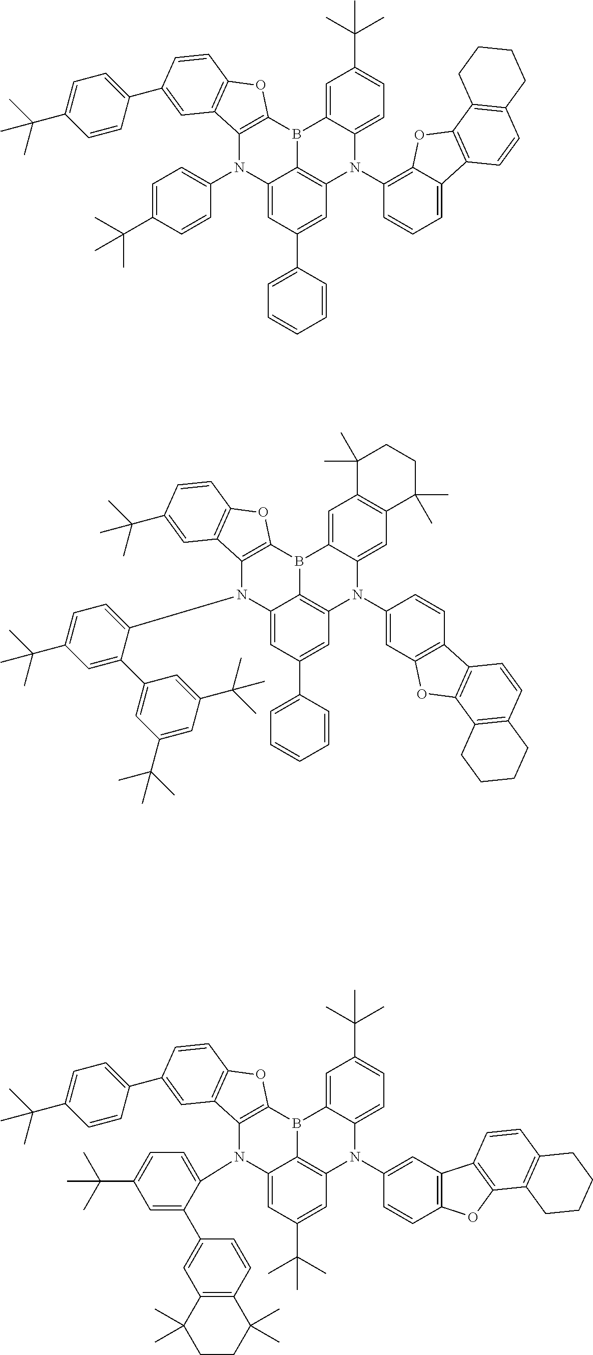 [SMILES: CC(C)(C)c1ccc(-c2ccc3oc4c(c3c2)N(c2ccc(C(C)(C)C)cc2)c2cc(-c3ccccc3)cc3c2B4c2cc(C(C)(C)C)ccc2N3c2cccc3c2oc2c4c(ccc23)CCCC4)cc1 ; CC(C)(C)c1cc(-c2cc(C(C)(C)C)ccc2N2c3cc(-c4ccccc4)cc4c3B(c3cc5c(cc3N4c3ccc4c(c3)oc3c6c(ccc34)CCCC6)C(C)(C)CCC5(C)C)c3oc4ccc(C(C)(C)C)cc4c32)cc(C(C)(C)C)c1 ; CC(C)(C)c1ccc(-c2ccc3oc4c(c3c2)N(c2ccc(C(C)(C)C)cc2-c2ccc3c(c2)C(C)(C)CCC3(C)C)c2cc(C(C)(C)C)cc3c2B4c2cc(C(C)(C)C)ccc2N3c2ccc3oc4c5c(ccc4c3c2)CCCC5)cc1]

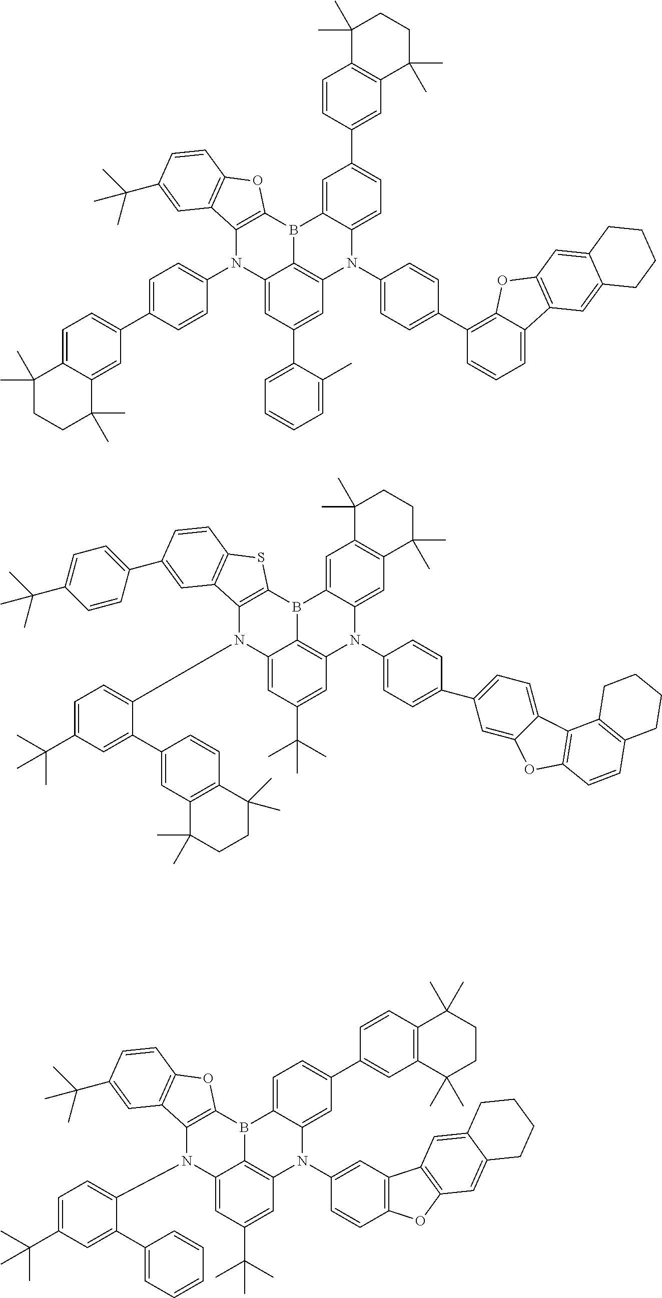 [SMILES: Cc1ccccc1-c1cc2c3c(c1)N(c1ccc(-c4ccc5c(c4)C(C)(C)CCC5(C)C)cc1)c1c(oc4ccc(C(C)(C)C)cc14)B3c1cc(-c3ccc4c(c3)C(C)(C)CCC4(C)C)ccc1N2c1ccc(-c2cccc3c2oc2cc4c(cc23)CCCC4)cc1 ; CC(C)(C)c1ccc(-c2ccc3sc4c(c3c2)N(c2ccc(C(C)(C)C)cc2-c2ccc3c(c2)C(C)(C)CCC3(C)C)c2cc(C(C)(C)C)cc3c2B4c2cc4c(cc2N3c2ccc(-c3ccc5c(c3)oc3ccc6c(c35)CCCC6)cc2)C(C)(C)CCC4(C)C)cc1 ; CC(C)(C)c1ccc(N2c3cc(C(C)(C)C)cc4c3B(c3ccc(-c5ccc6c(c5)C(C)(C)CCC6(C)C)cc3N4c3ccc4oc5cc6c(cc5c4c3)CCCC6)c3oc4ccc(C(C)(C)C)cc4c32)c(-c2ccccc2)c1]

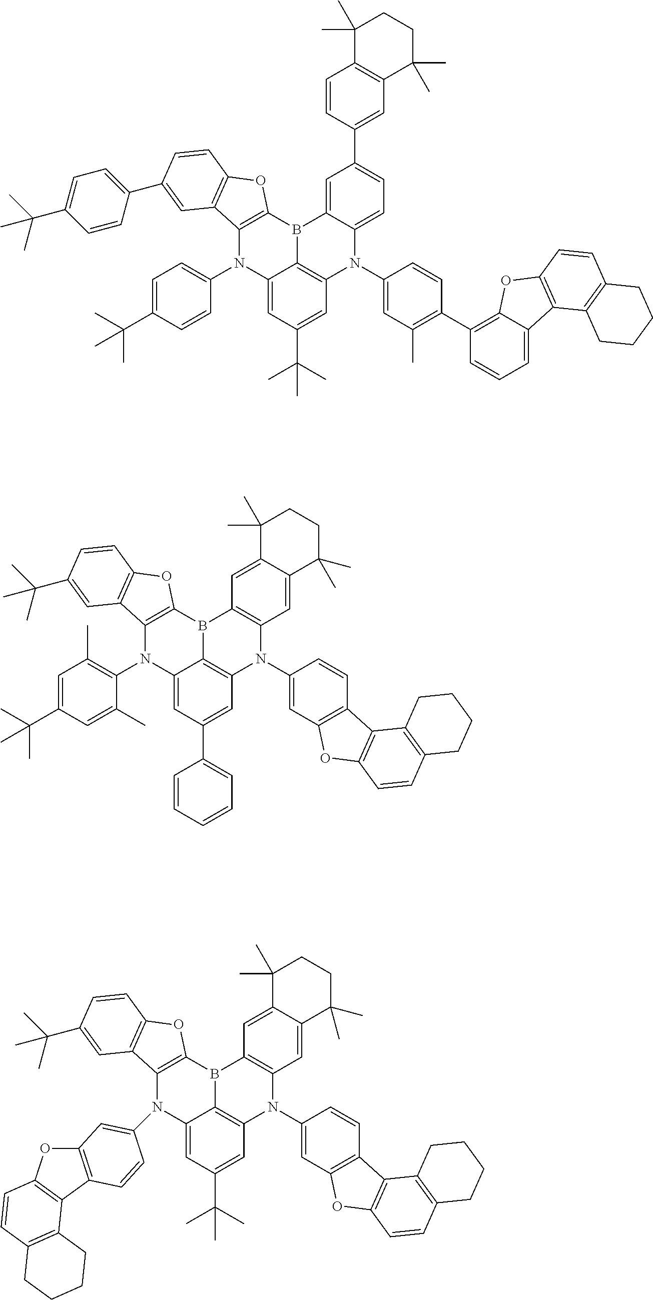 [SMILES: Cc1cc(N2c3ccc(-c4ccc5c(c4)C(C)(C)CCC5(C)C)cc3B3c4oc5ccc(-c6ccc(C(C)(C)C)cc6)cc5c4N(c4ccc(C(C)(C)C)cc4)c4cc(C(C)(C)C)cc2c43)ccc1-c1cccc2c1oc1ccc3c(c12)CCCC3 ; Cc1cc(C(C)(C)C)cc(C)c1N1c2cc(-c3ccccc3)cc3c2B(c2cc4c(cc2N3c2ccc3c(c2)oc2ccc5c(c23)CCCC5)C(C)(C)CCC4(C)C)c2oc3ccc(C(C)(C)C)cc3c21 ; CC(C)(C)c1cc2c3c(c1)N(c1ccc4c(c1)oc1ccc5c(c14)CCCC5)c1c(oc4ccc(C(C)(C)C)cc14)B3c1cc3c(cc1N2c1ccc2c(c1)oc1ccc4c(c12)CCCC4)C(C)(C)CCC3(C)C]

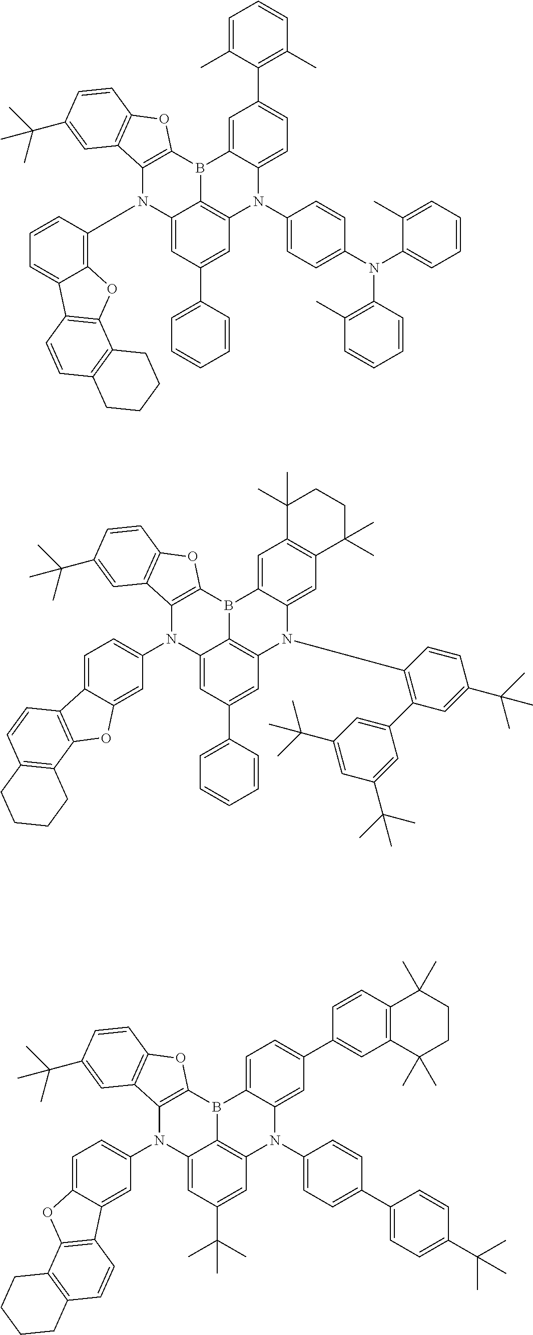 [SMILES: Cc1ccccc1N(c1ccc(N2c3ccc(-c4c(C)cccc4C)cc3B3c4oc5ccc(C(C)(C)C)cc5c4N(c4cccc5c4oc4c6c(ccc45)CCCC6)c4cc(-c5ccccc5)cc2c43)cc1)c1ccccc1C ; CC(C)(C)c1cc(-c2cc(C(C)(C)C)ccc2N2c3cc4c(cc3B3c5oc6ccc(C(C)(C)C)cc6c5N(c5ccc6c(c5)oc5c7c(ccc56)CCCC7)c5cc(-c6ccccc6)cc2c53)C(C)(C)CCC4(C)C)cc(C(C)(C)C)c1 ; CC(C)(C)c1ccc(-c2ccc(N3c4cc(-c5ccc6c(c5)C(C)(C)CCC6(C)C)ccc4B4c5oc6ccc(C(C)(C)C)cc6c5N(c5ccc6oc7c8c(ccc7c6c5)CCCC8)c5cc(C(C)(C)C)cc3c54)cc2)cc1]

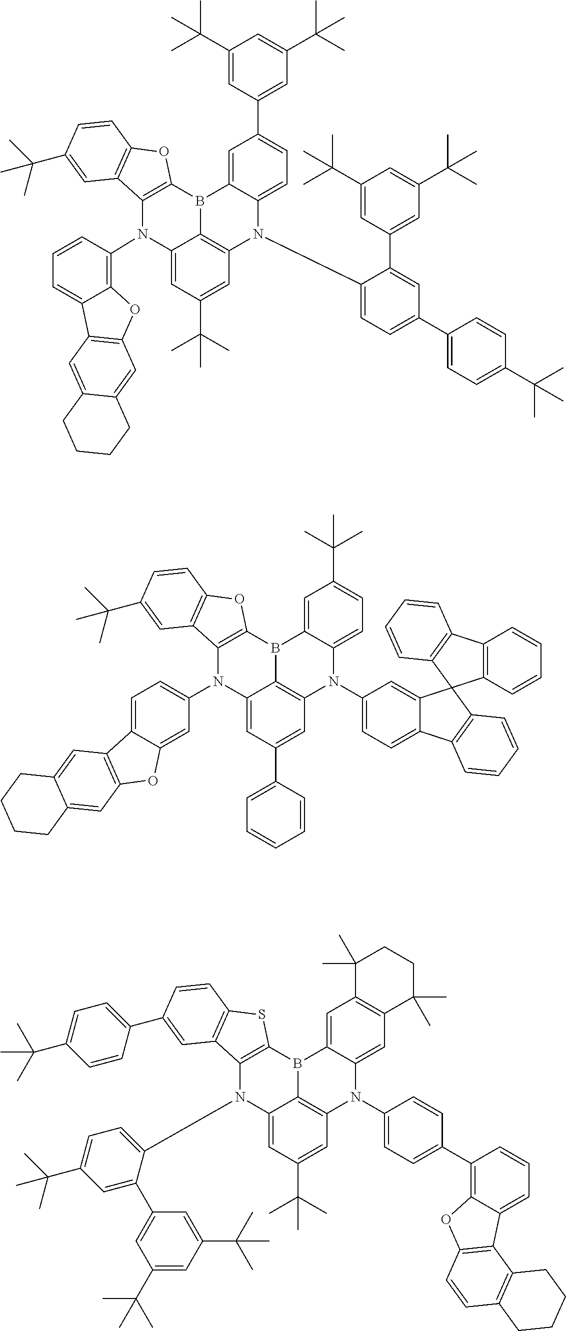

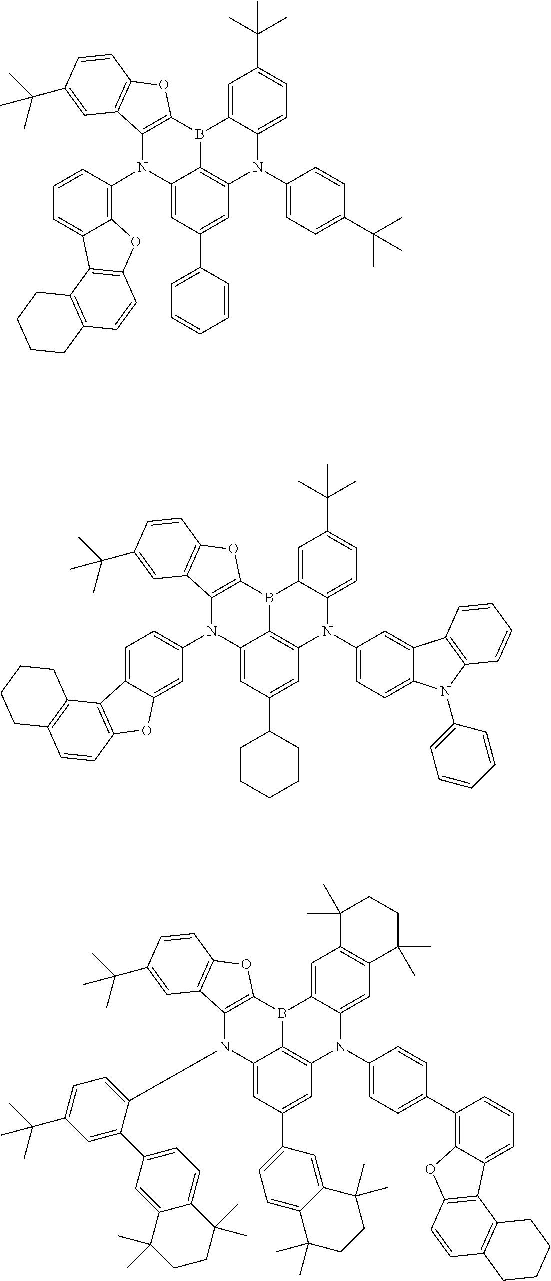

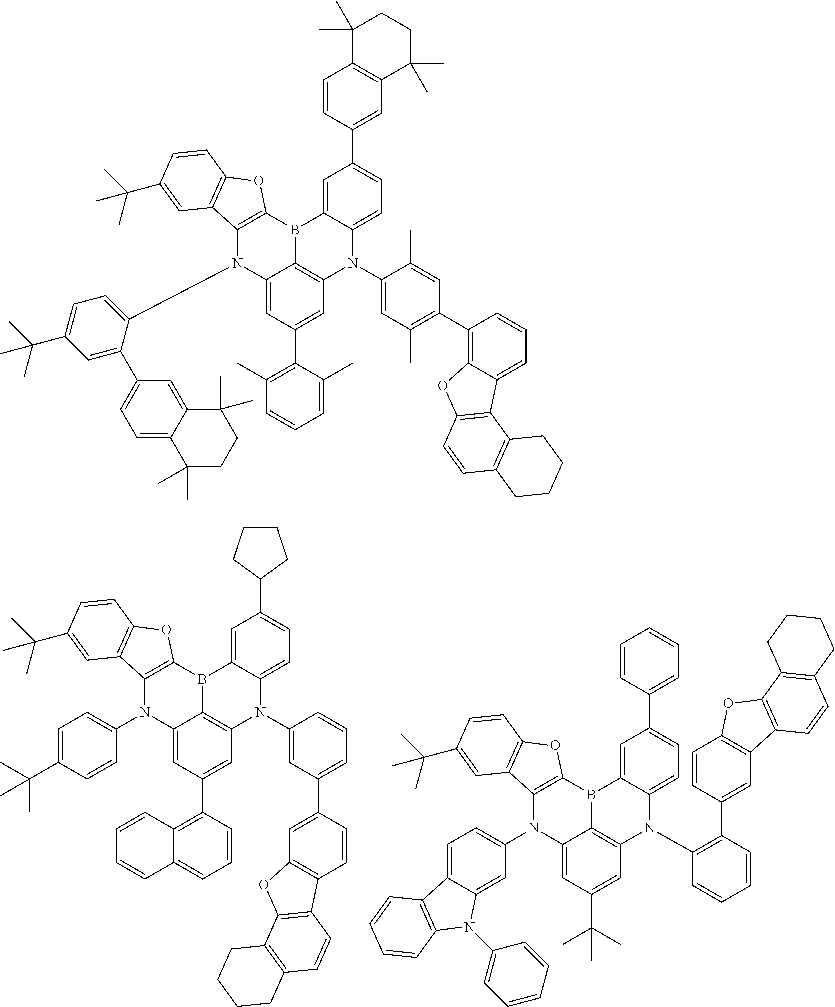

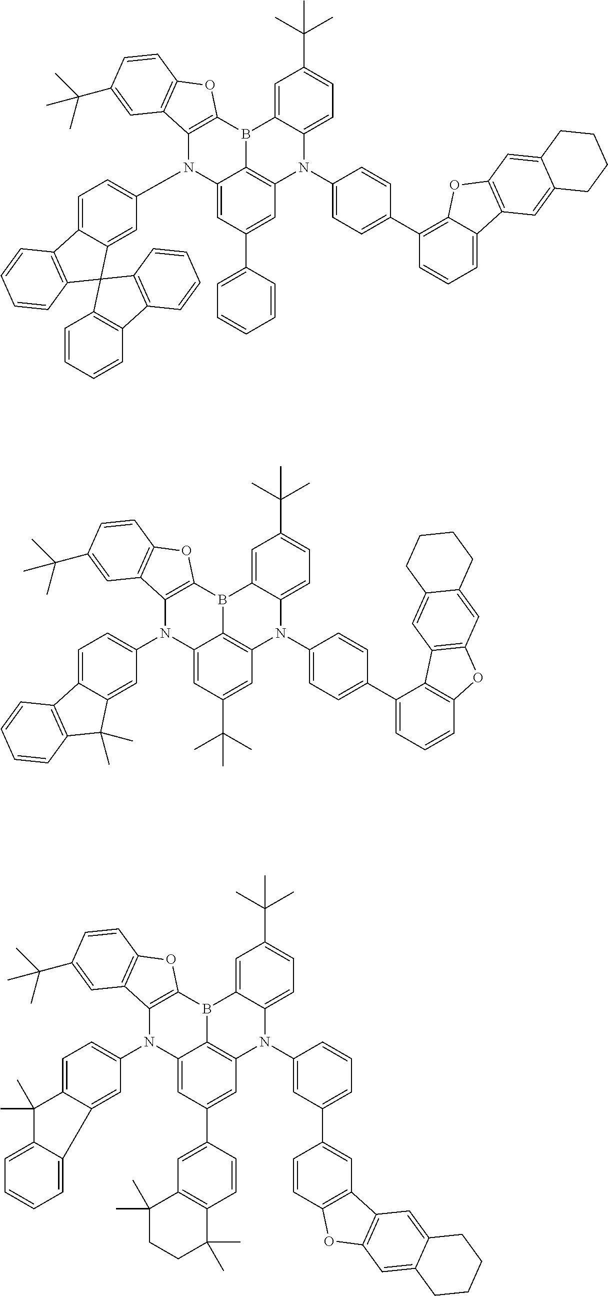 [SMILES: CC(C)(C)c1ccc2c(c1)B1c3oc4ccc(C(C)(C)C)cc4c3N(c3ccc4c(c3)C3(c5ccccc5-c5ccccc53)c3ccccc3-4)c3cc(-c4ccccc4)cc(c31)N2c1ccc(-c2cccc3c2oc2cc4c(cc23)CCCC4)cc1 ; CC(C)(C)c1ccc2c(c1)B1c3oc4ccc(C(C)(C)C)cc4c3N(c3ccc4c(c3)C(C)(C)c3ccccc3-4)c3cc(C(C)(C)C)cc(c31)N2c1ccc(-c2cccc3oc4cc5c(cc4c23)CCCC5)cc1 ; CC(C)(C)c1ccc2c(c1)B1c3oc4ccc(C(C)(C)C)cc4c3N(c3ccc4c(c3)-c3ccccc3C4(C)C)c3cc(-c4ccc5c(c4)C(C)(C)CCC5(C)C)cc(c31)N2c1cccc(-c2ccc3oc4cc5c(cc4c3c2)CCCC5)c1]

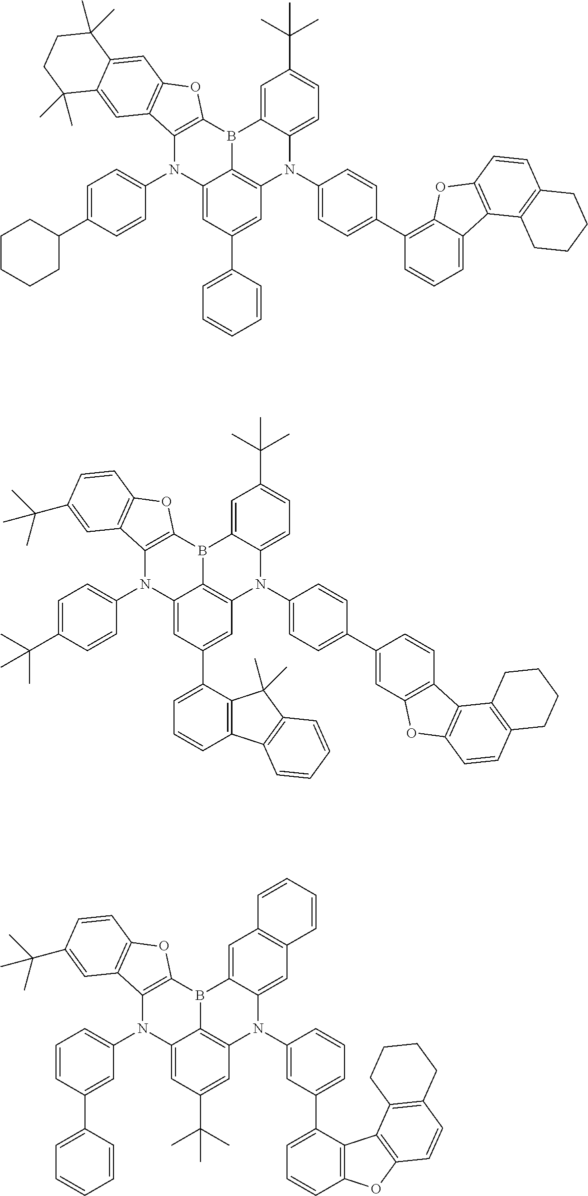 [SMILES: CC(C)(C)c1ccc2c(c1)B1c3oc4cc5c(cc4c3N(c3ccc(C4CCCCC4)cc3)c3cc(-c4ccccc4)cc(c31)N2c1ccc(-c2cccc3c2oc2ccc4c(c23)CCCC4)cc1)C(C)(C)CCC5(C)C ; CC(C)(C)c1ccc(N2c3cc(-c4cccc5c4C(C)(C)c4ccccc4-5)cc4c3B(c3cc(C(C)(C)C)ccc3N4c3ccc(-c4ccc5c(c4)oc4ccc6c(c45)CCCC6)cc3)c3oc4ccc(C(C)(C)C)cc4c32)cc1 ; CC(C)(C)c1cc2c3c(c1)N(c1cccc(-c4ccccc4)c1)c1c(oc4ccc(C(C)(C)C)cc14)B3c1cc3ccccc3cc1N2c1cccc(-c2cccc3oc4ccc5c(c4c23)CCCC5)c1]

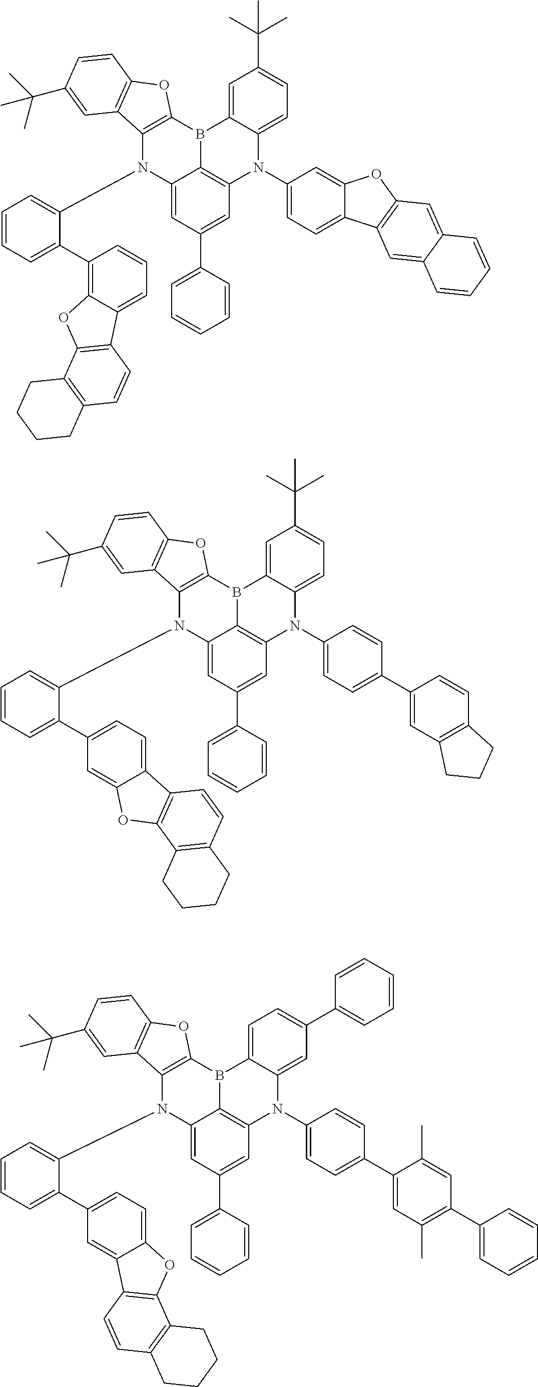 [SMILES: CC(C)(C)c1ccc2c(c1)B1c3oc4ccc(C(C)(C)C)cc4c3N(c3ccccc3-c3cccc4c3oc3c5c(ccc34)CCCC5)c3cc(-c4ccccc4)cc(c31)N2c1ccc2c(c1)oc1cc3ccccc3cc12 ; CC(C)(C)c1ccc2c(c1)B1c3oc4ccc(C(C)(C)C)cc4c3N(c3ccccc3-c3ccc4c(c3)oc3c5c(ccc34)CCCC5)c3cc(-c4ccccc4)cc(c31)N2c1ccc(-c2ccc3c(c2)CCC3)cc1 ; Cc1cc(-c2ccc(N3c4cc(-c5ccccc5)ccc4B4c5oc6ccc(C(C)(C)C)cc6c5N(c5ccccc5-c5ccc6oc7c8c(ccc7c6c5)CCCC8)c5cc(-c6ccccc6)cc3c54)cc2)c(C)cc1-c1ccccc1]

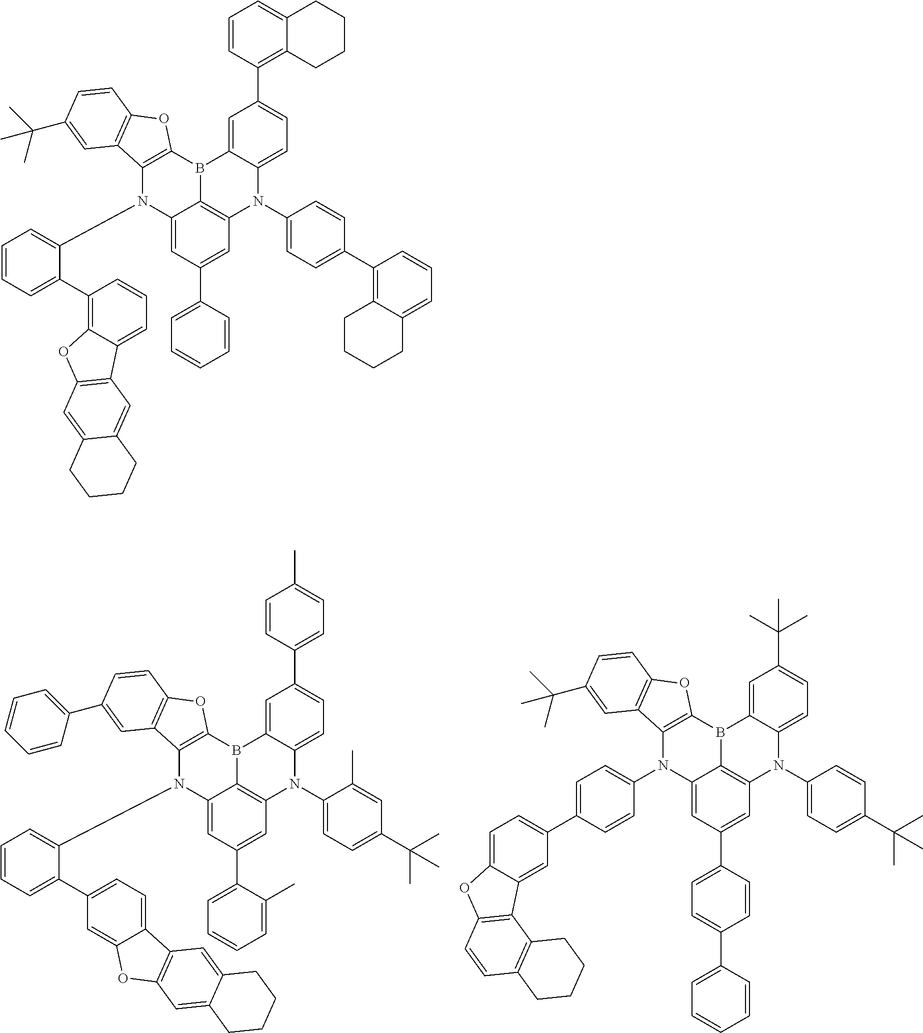

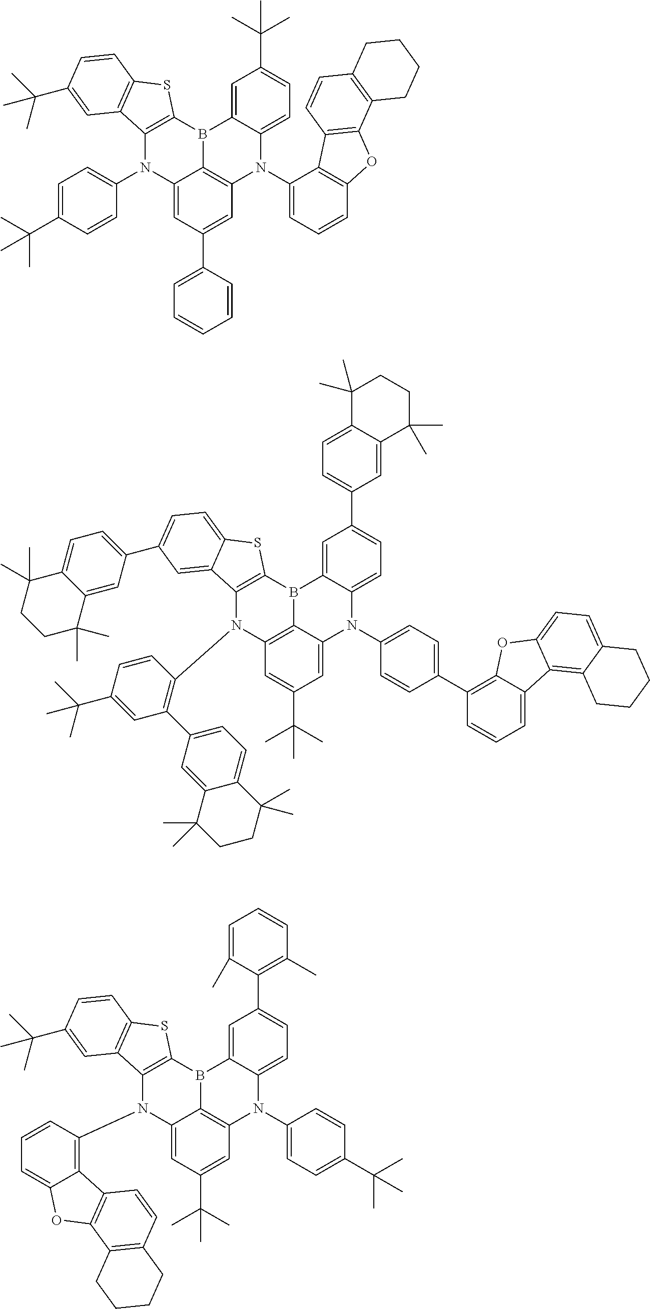 [SMILES: CC(C)(C)c1ccc(N2c3cc(-c4ccccc4)cc4c3B(c3cc(C(C)(C)C)ccc3N4c3cccc4oc5c6c(ccc5c34)CCCC6)c3sc4ccc(C(C)(C)C)cc4c32)cc1 ; CC(C)(C)c1ccc(N2c3cc(C(C)(C)C)cc4c3B(c3cc(-c5ccc6c(c5)C(C)(C)CCC6(C)C)ccc3N4c3ccc(-c4cccc5c4oc4ccc6c(c45)CCCC6)cc3)c3sc4ccc(-c5ccc6c(c5)C(C)(C)CCC6(C)C)cc4c32)c(-c2ccc3c(c2)C(C)(C)CCC3(C)C)c1 ; Cc1cccc(C)c1-c1ccc2c(c1)B1c3sc4ccc(C(C)(C)C)cc4c3N(c3cccc4oc5c6c(ccc5c34)CCCC6)c3cc(C(C)(C)C)cc(c31)N2c1ccc(C(C)(C)C)cc1]

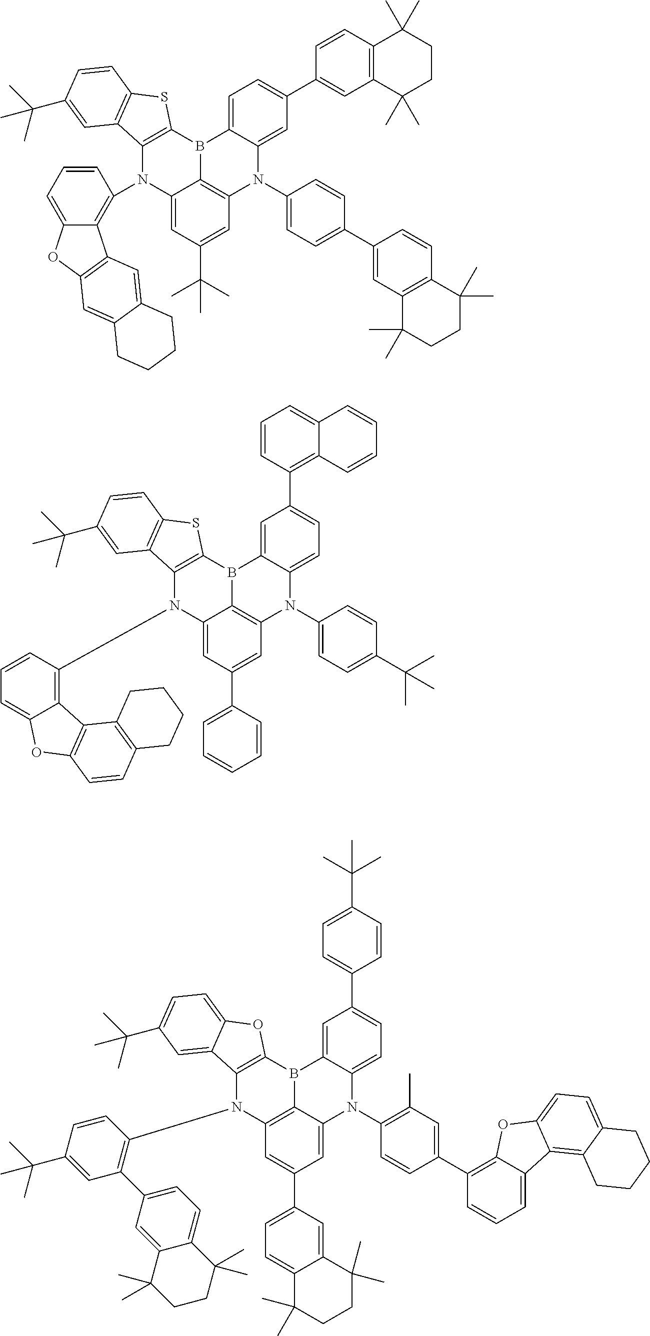

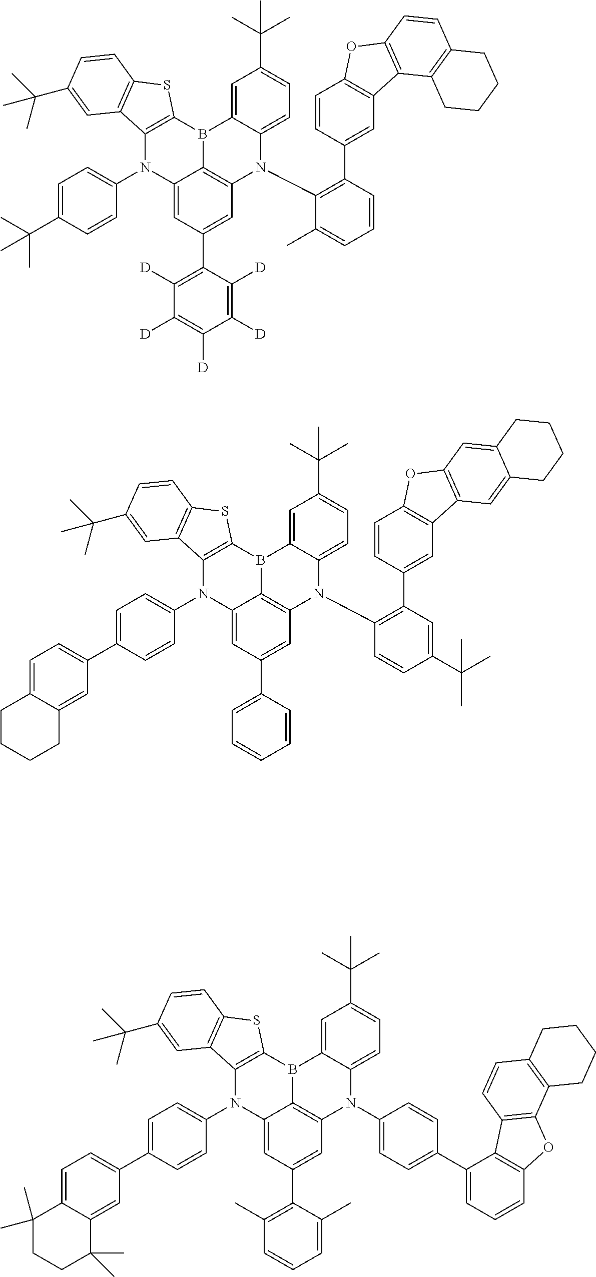 [SMILES: [2H]c1c([2H])c([2H])c(-c2cc3c4c(c2)N(c2ccc(C(C)(C)C)cc2)c2c(sc5ccc(C(C)(C)C)cc25)B4c2cc(C(C)(C)C)ccc2N3c2c(C)cccc2-c2ccc3oc4ccc5c(c4c3c2)CCCC5)c([2H])c1[2H] ; CC(C)(C)c1ccc2c(c1)B1c3sc4ccc(C(C)(C)C)cc4c3N(c3ccc(-c4ccc5c(c4)CCCC5)cc3)c3cc(-c4ccccc4)cc(c31)N2c1ccc(C(C)(C)C)cc1-c1ccc2oc3cc4c(cc3c2c1)CCCC4 ; Cc1cccc(C)c1-c1cc2c3c(c1)N(c1ccc(-c4ccc5c(c4)C(C)(C)CCC5(C)C)cc1)c1c(sc4ccc(C(C)(C)C)cc14)B3c1cc(C(C)(C)C)ccc1N2c1ccc(-c2cccc3oc4c5c(ccc4c23)CCCC5)cc1]

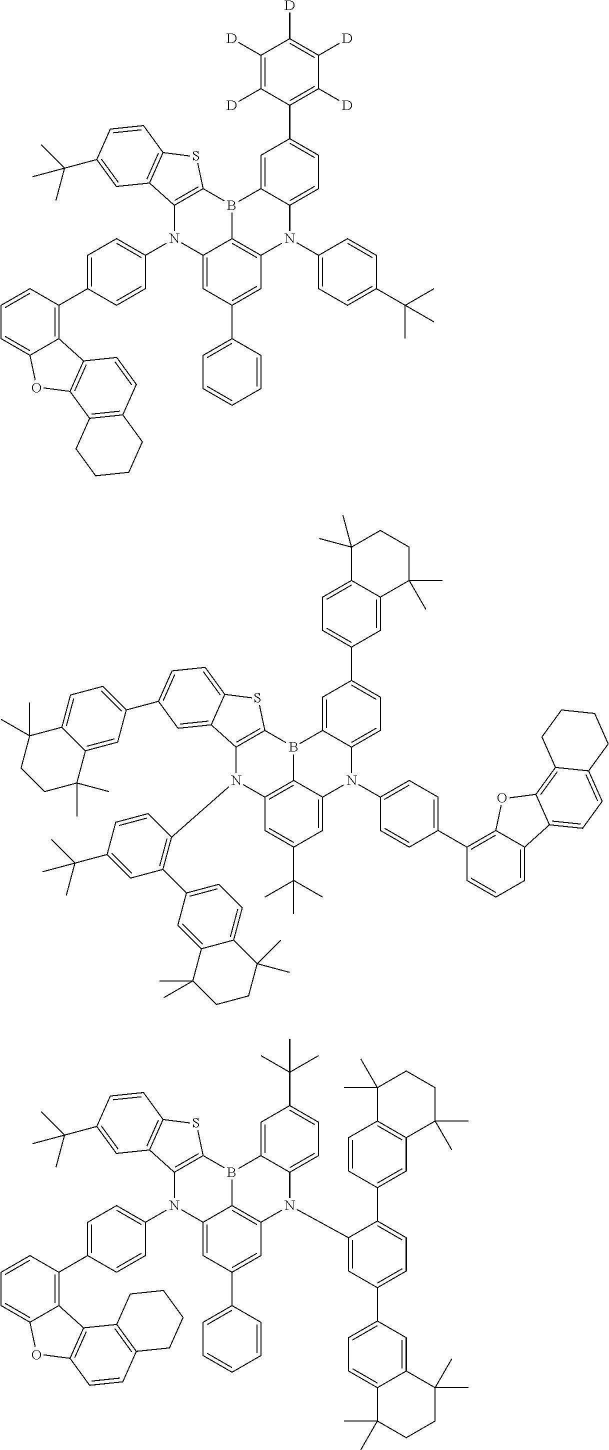

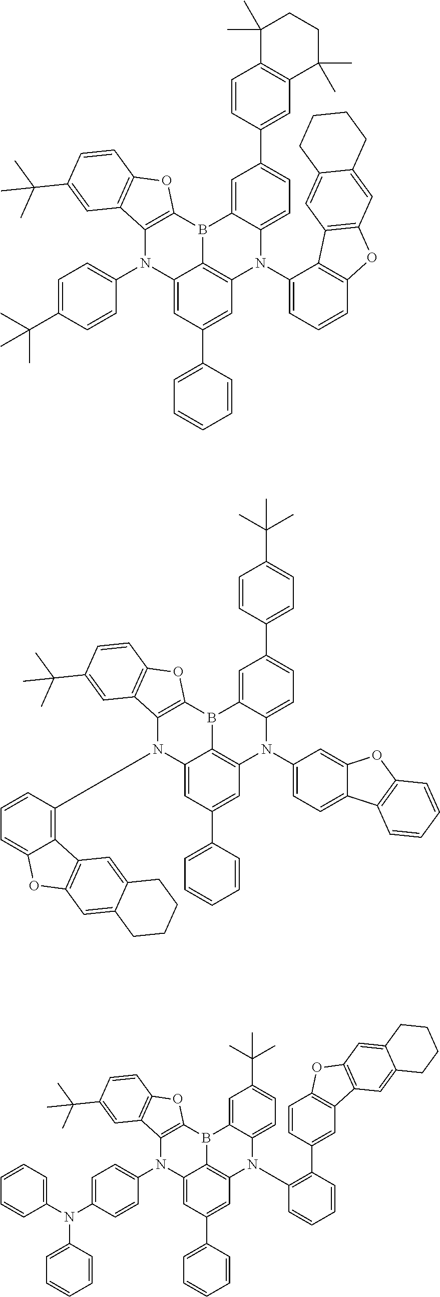 [SMILES: CC(C)(C)c1ccc(N2c3cc(-c4ccccc4)cc4c3B(c3cc(-c5ccc6c(c5)C(C)(C)CCC6(C)C)ccc3N4c3cccc4oc5cc6c(cc5c34)CCCC6)c3oc4ccc(C(C)(C)C)cc4c32)cc1 ; CC(C)(C)c1ccc(-c2ccc3c(c2)B2c4oc5ccc(C(C)(C)C)cc5c4N(c4cccc5oc6cc7c(cc6c45)CCCC7)c4cc(-c5ccccc5)cc(c42)N3c2ccc3c(c2)oc2ccccc23)cc1 ; CC(C)(C)c1ccc2c(c1)B1c3oc4ccc(C(C)(C)C)cc4c3N(c3ccc(N(c4ccccc4)c4ccccc4)cc3)c3cc(-c4ccccc4)cc(c31)N2c1ccccc1-c1ccc2oc3cc4c(cc3c2c1)CCCC4]

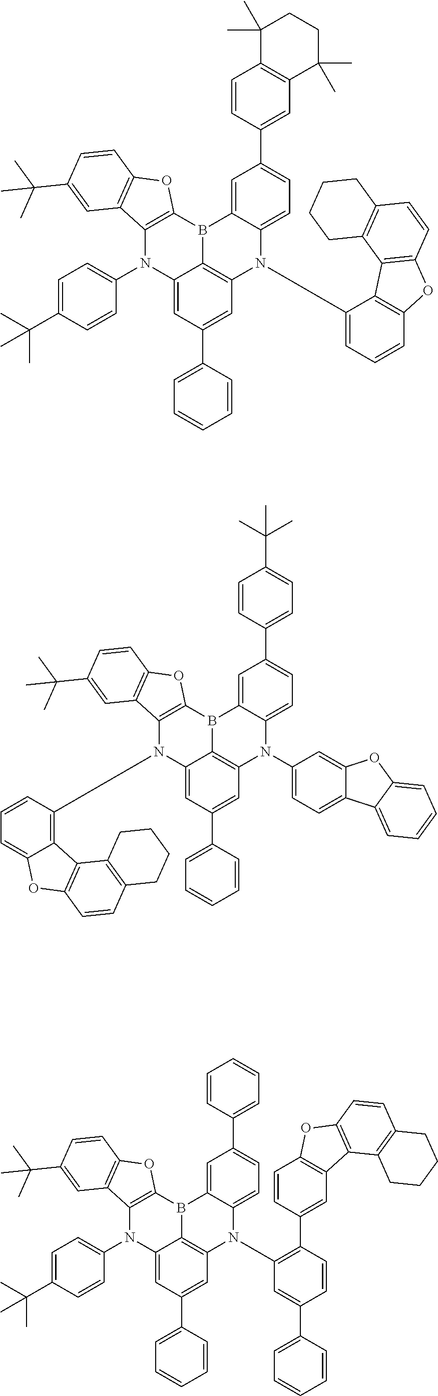 [SMILES: CC(C)(C)c1ccc(N2c3cc(-c4ccccc4)cc4c3B(c3cc(-c5ccc6c(c5)C(C)(C)CCC6(C)C)ccc3N4c3cccc4oc5ccc6c(c5c34)CCCC6)c3oc4ccc(C(C)(C)C)cc4c32)cc1 ; CC(C)(C)c1ccc(-c2ccc3c(c2)B2c4oc5ccc(C(C)(C)C)cc5c4N(c4cccc5oc6ccc7c(c6c45)CCCC7)c4cc(-c5ccccc5)cc(c42)N3c2ccc3c(c2)oc2ccccc23)cc1 ; CC(C)(C)c1ccc(N2c3cc(-c4ccccc4)cc4c3B(c3cc(-c5ccccc5)ccc3N4c3cc(-c4ccccc4)ccc3-c3ccc4oc5ccc6c(c5c4c3)CCCC6)c3oc4ccc(C(C)(C)C)cc4c32)cc1]

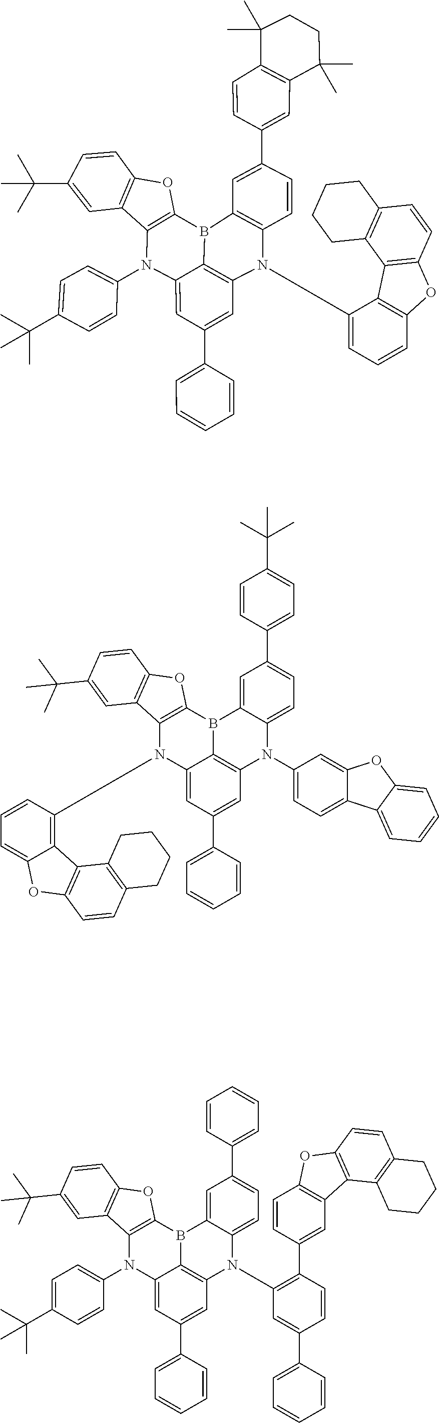

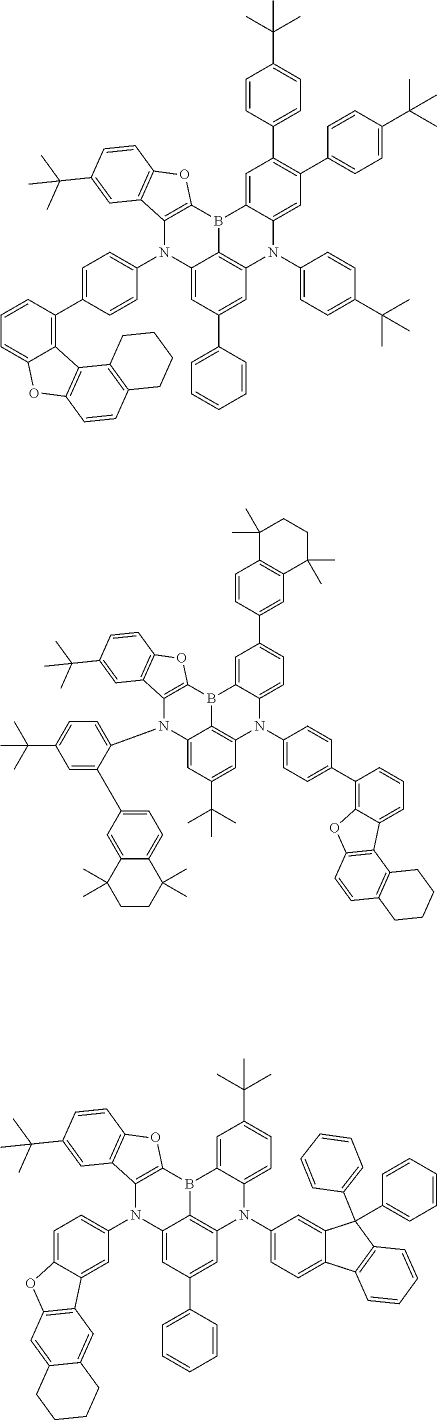

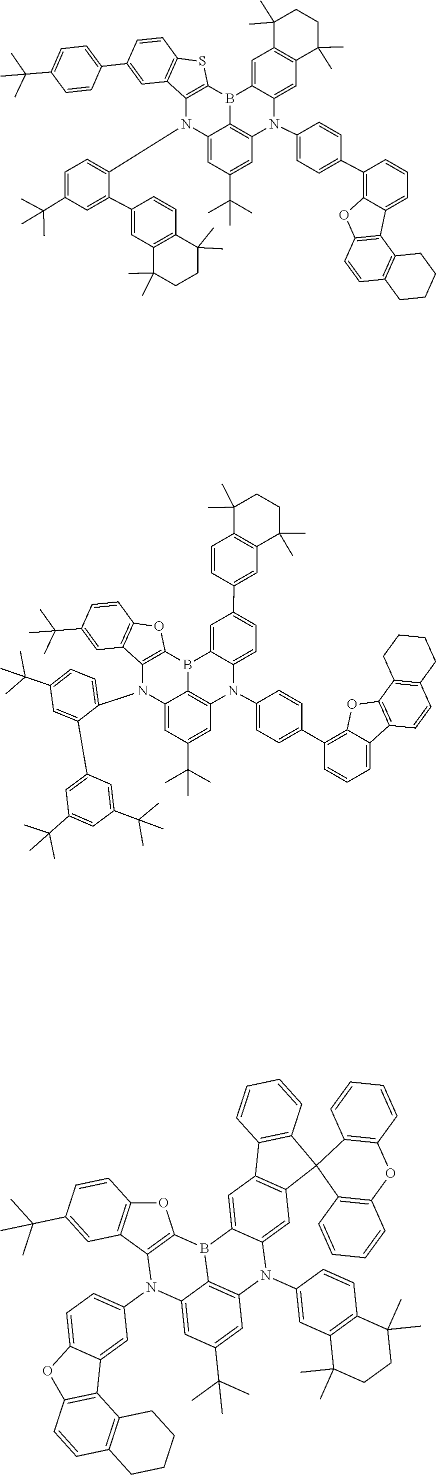 [SMILES: CC(C)(C)c1ccc(-c2ccc3sc4c(c3c2)N(c2ccc(C(C)(C)C)cc2-c2ccc3c(c2)C(C)(C)CCC3(C)C)c2cc(C(C)(C)C)cc3c2B4c2cc4c(cc2N3c2ccc(-c3cccc5c3oc3ccc6c(c35)CCCC6)cc2)C(C)(C)CCC4(C)C)cc1 ; CC(C)(C)c1cc(-c2cc(C(C)(C)C)ccc2N2c3cc(C(C)(C)C)cc4c3B(c3cc(-c5ccc6c(c5)C(C)(C)CCC6(C)C)ccc3N4c3ccc(-c4cccc5c4oc4c6c(ccc45)CCCC6)cc3)c3oc4ccc(C(C)(C)C)cc4c32)cc(C(C)(C)C)c1 ; CC(C)(C)c1cc2c3c(c1)N(c1ccc4oc5ccc6c(c5c4c1)CCCC6)c1c(oc4ccc(C(C)(C)C)cc14)B3c1cc3c(cc1N2c1ccc2c(c1)C(C)(C)CCC2(C)C)C1(c2ccccc2Oc2ccccc21)c1ccccc1-3]

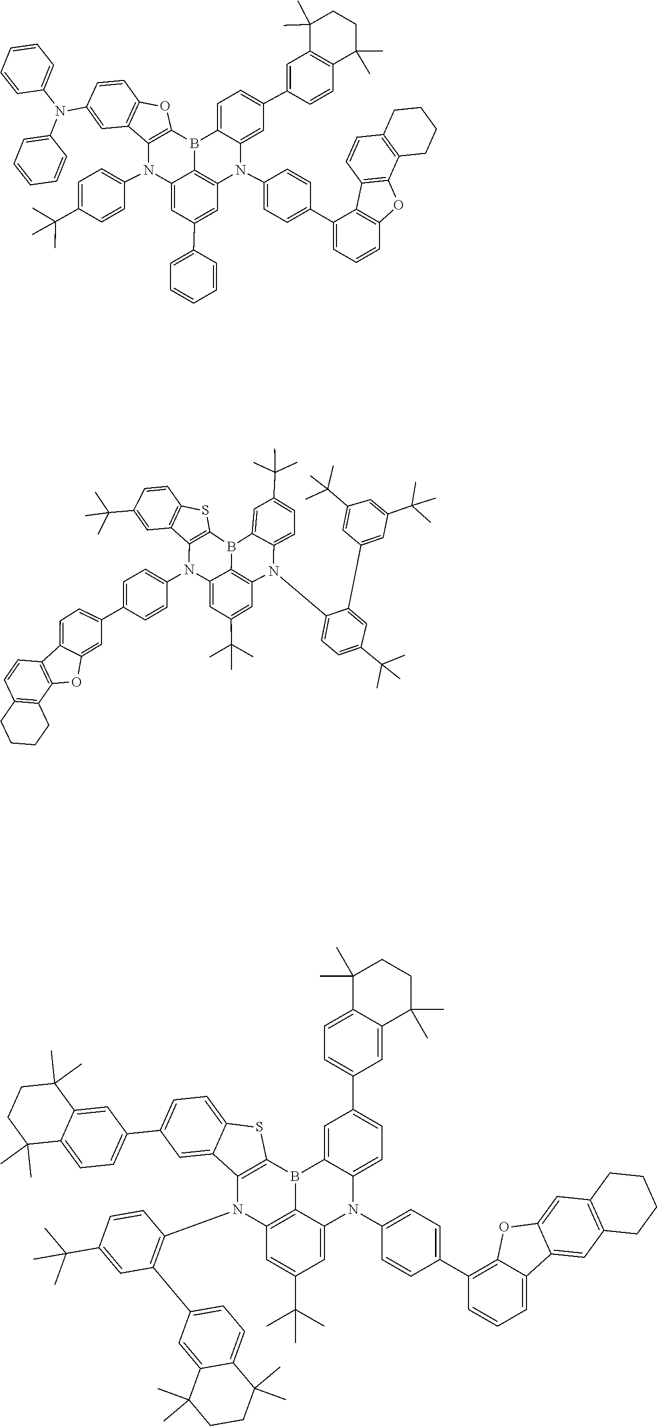

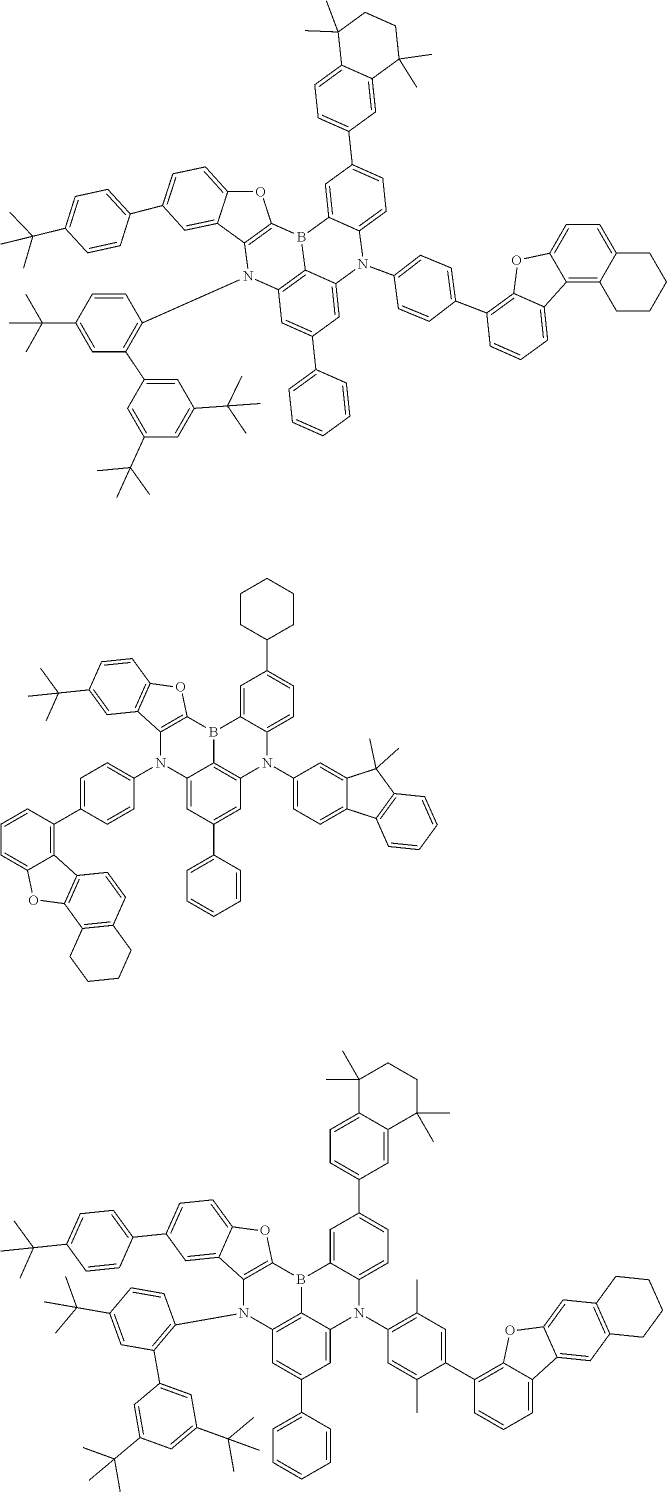

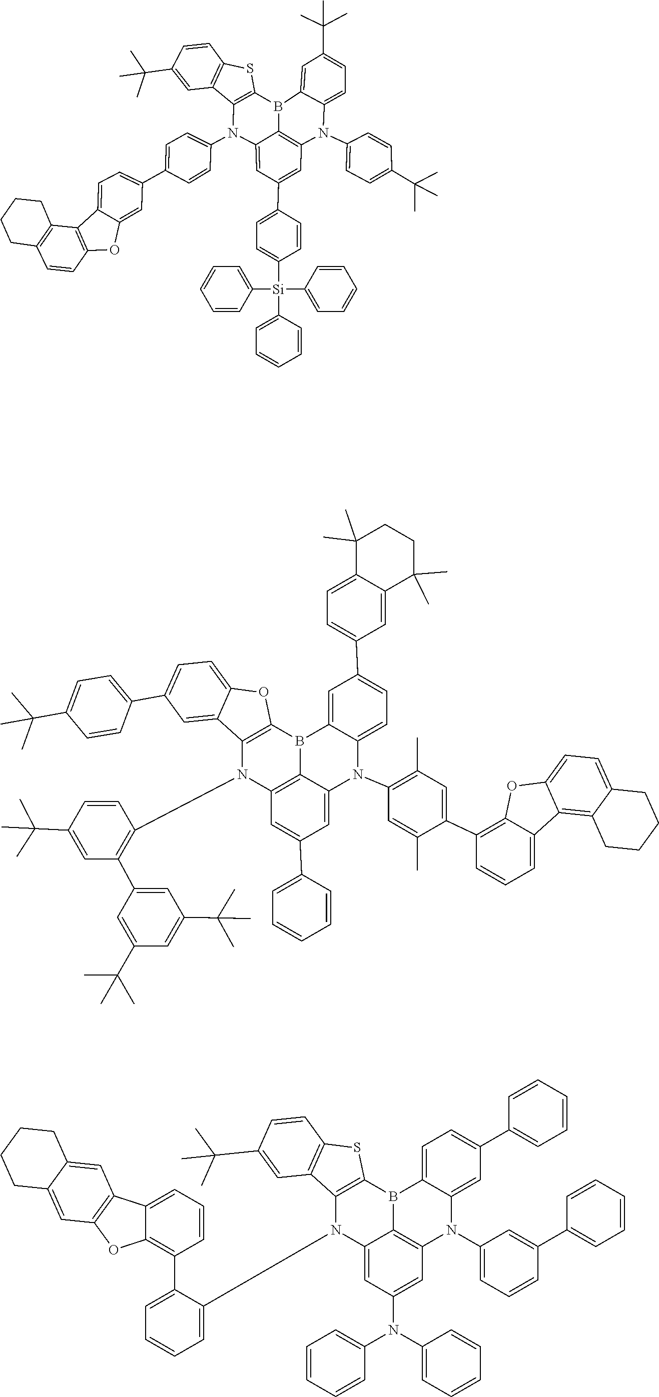

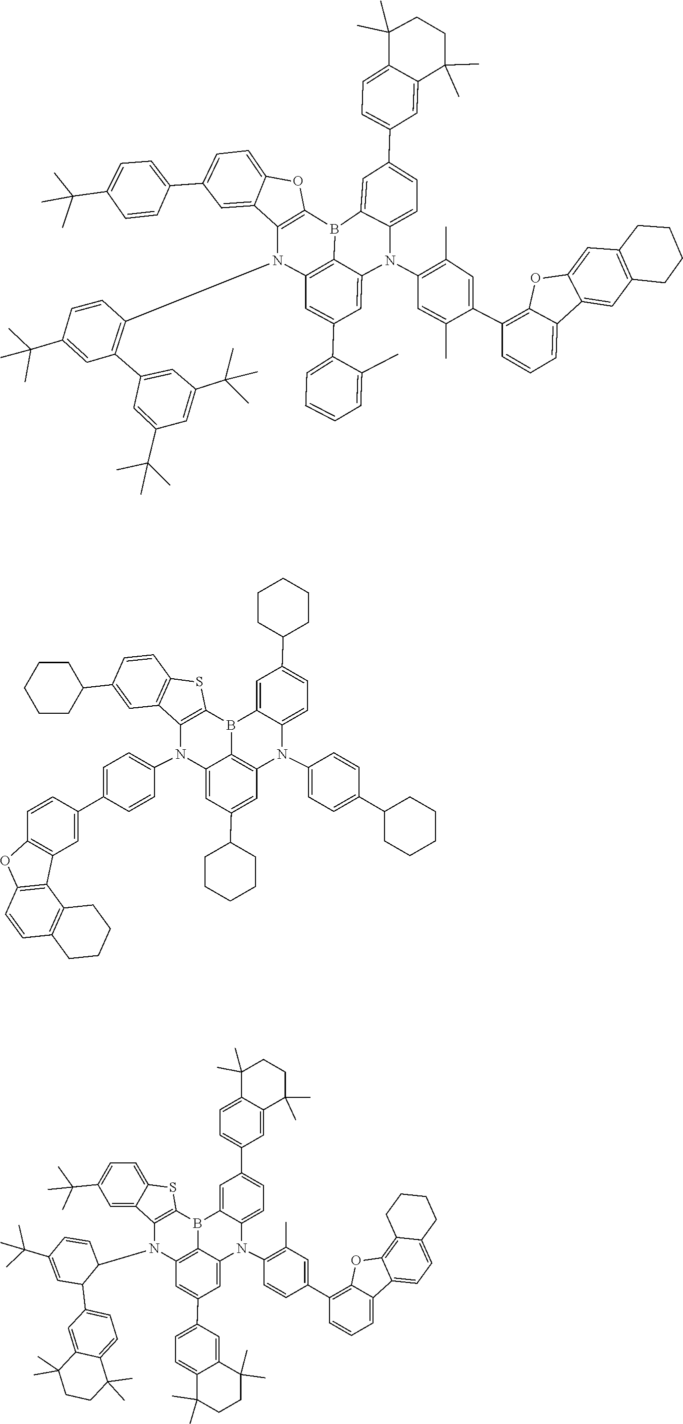

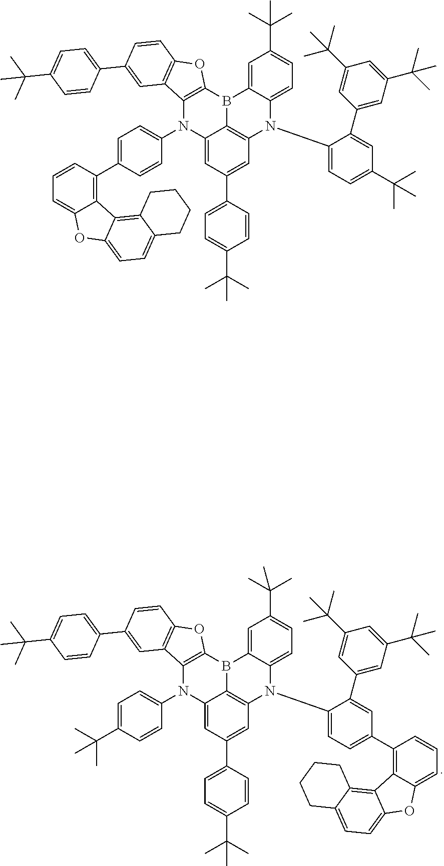

10. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 1.

11. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 2.

12. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 3.

13. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 4.

14. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 5.

15. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 6.

16. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 7.

17. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 8.

18. An organic electroluminescent device, characterized by comprising an anode, a hole transport region, a luminescent layer, an electron transport region, and a cathode, which are sequentially arranged on a substrate, wherein the luminescent layer comprises a host material and a guest material, and the guest material comprises one or more blue luminescent compounds according to claim 9.
